(19) United States
(12) Patent Application Publication
(10) Pub. No.: US 2011/0165521 A1
(43) Pub. Date: Jul. 7, 2011

(54) PROCESS FOR PRODUCING PHOTORESIST PATTERN

(75) Inventors: Mitsuhiro HATA, Delmar, NY (US); Jung Hwan HAH, Osaka (JP)

(73) Assignee: SUMITOMO CHEMICAL COMPANY, LIMITED, Tokyo (JP)

(21) Appl. No.: 12/978,952

(22) Filed: Dec. 27, 2010

(30) Foreign Application Priority Data
Jan. 7, 2010 (JP) 2010-001831

(51) Int. Cl. G03F 7/20

(52) U.S. Cl. 430/325

(57) ABSTRACT

Process for producing a photoresist pattern containing the steps: (A) applying a first photoresist composition containing a resin having a structural unit containing an acid-labile group in its side chain, an acid generator and a cross-linking agent on a substrate to form a first photoresist film, exposing the film to radiation followed by developing the film, to form a first photoresist pattern; (B) making the first photoresist pattern inactive to radiation, insoluble in an alkaline developer or insoluble in a second photoresist composition in step (C); (C) applying a second photoresist composition containing a resin having a structural unit containing an acid-labile group in its side chain and at least one acid generator of formula (I) or (II) defined in the specification, on the first photoresist pattern, to form a second photoresist film, exposing the film to radiation; and (D) developing the exposed film, to form a second photoresist pattern.

This nonprovisional application claims priority under 35 U.S.C. §119(a) on Patent Applications No. 2010-001831 filed in JAPAN on Jan. 7, 2010, the entire contents of which are hereby incorporated by reference.

### FIELD OF THE INVENTION

The present invention relates to a process for producing a photoresist pattern.

### BACKGROUND OF THE INVENTION

In recent years, a more miniaturized photoresist pattern has been demanded to produce in a process of production of a semiconductor using a lithography technology. As a process realizing to form a photoresist pattern having a line width of 32 nm or less, a double-patterning method has been proposed (e.g. WO09/084,515 A1), and the double-patterning method comprises the following steps (1) to (11):

(1) a step of applying a first photoresist composition comprising a resin comprising a structural unit having an acid-labile group in its side chain and being itself insoluble or poorly soluble in an alkali aqueous solution but becoming soluble in an alkali aqueous solution by the action of an acid, and an acid generator, on a substrate followed by conducting drying, thereby forming a first photoresist film,

(2) a step of baking the first photoresist film,

(3) a step of exposing the first photoresist film baked to radiation,

(4) a step of baking the first photoresist film exposed,

(5) a step of developing the first photoresist film baked in the step (4) with an alkaline developer, thereby forming a first photoresist pattern,

(6) a step of baking the first photoresist pattern,

(7) a step of applying a second photoresist composition on the first photoresist pattern followed by conducting drying, thereby forming a second photoresist film,

(8) a step of baking the second photoresist film,

(9) a step of exposing the second photoresist film baked to radiation,

(10) a step of baking the second photoresist film exposed, and

(11) a step of developing the second photoresist film baked in the step (10) with an alkaline developer, thereby forming a second photoresist pattern.

In the double-patterning method, the second photoresist composition comprises a resin having the following structural units and an acid generator represented by the following formula.

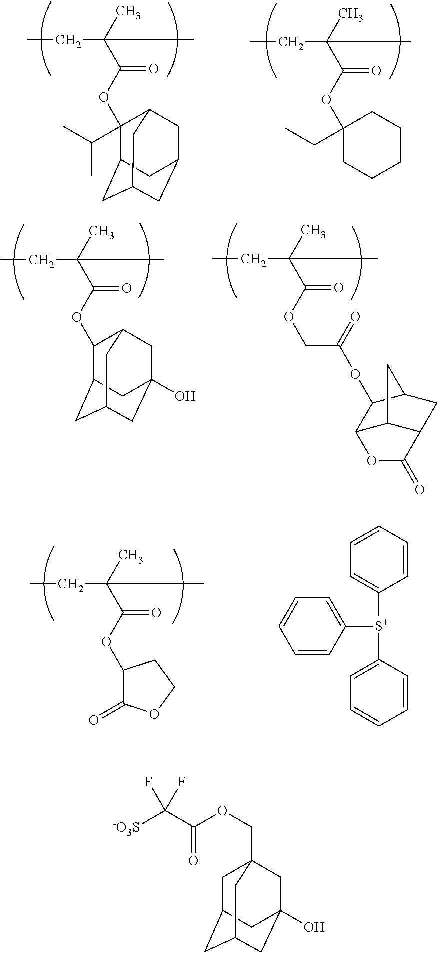

### SUMMARY OF THE INVENTION

An object of the present invention is to provide a process for producing a photoresist pattern.

The present invention relates to the followings:

<1> A process for producing a photoresist pattern comprising the following steps (A) to (D):

(A) a step of applying a first photoresist composition comprising a resin comprising a structural unit having an acid-labile group in its side chain, an acid generator and a cross-linking agent on a substrate to form a first photoresist film, exposing the first photoresist film to radiation followed by developing the first photoresist film exposed with an alkaline developer, thereby forming a first photoresist pattern,

(B) a step of making the first photoresist pattern inactive to radiation in the following step (C), making the first photoresist pattern insoluble in an alkaline developer or making the first photoresist pattern insoluble in a second photoresist composition used in the following step (C),

(C) a step of applying a second photoresist composition comprising a resin comprising a structural unit having an acid-labile group in its side chain and

at least one acid generator selected from the group consisting of a photoacid generator represented by the formula (I):

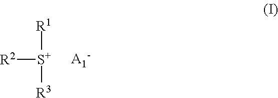

wherein R¹ and R² independently a C1-C12 alkyl group or a C6-C18 aromatic hydrocarbon group which can have one or more substituents, R³ represents a C1-C12 alkyl group, or R² and R³ are bonded each other to form a C3-C12 divalent acyclic hydrocarbon group which forms a ring together with S and one or more —CH₂— in the C3-C12 divalent acyclic hydrocarbon group can be replaced by —O—, and A₁⁻ represents an organic anion, and a photoacid generator represented by the formula (II):

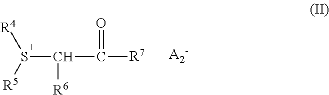

wherein R⁴ and R⁵ independently a C1-C12 alkyl group, a C3-C18 saturated cyclic hydrocarbon group or a C6-C18 aromatic hydrocarbon group, or R⁴ and R⁵ are bonded each other to form a C3-C12 divalent acyclic hydrocarbon group which forms a ring together with S and one or more —CH₂— in the C3-C12 divalent acyclic hydrocarbon group can be replaced by —O—, R⁶ represents a hydrogen atom, R⁷ represents a C1-C12 alkyl group, a C3-C18 saturated cyclic hydrocarbon group or a C6-C18 aromatic hydrocarbon group which can have one or more substituents, or R⁶ and R⁷ are bonded each other to form a C1-C10 divalent acyclic hydrocarbon group which forms a 2-oxocycloalkyl group together with —CHCO— to which R⁶ and R⁷ are bonded, and A₂⁻ represents an organic anion,
on the first photoresist pattern obtained in the step (B) to form a second photoresist film, exposing the second photoresist film to radiation, and

(D) a step of developing the second photoresist film exposed with an alkaline developer, thereby forming a second photoresist pattern;

<2> The process according to <1>, wherein the step (A) comprises the following steps (1a) to (5a):

(1a) a step of applying a first photoresist composition comprising a resin comprising a structural unit having an acid-labile group in its side chain and being itself insoluble or poorly soluble in an alkali aqueous solution but becoming soluble in an alkali aqueous solution by the action of an acid, an acid generator and a cross-linking agent on a substrate followed by conducting drying, thereby forming a first photoresist film,

(2a) a step of baking the first photoresist film formed,

(3a) a step of exposing the first photoresist film baked to radiation,

(4a) a step of baking the first photoresist film exposed, and

(5a) a step of developing the first photoresist film baked in the step (4a) with an alkaline developer, thereby forming a first photoresist pattern;

<3> The process according to <1> or <2>, wherein the step (B) comprises the following step (6a):

(6a) a step of baking a first photoresist pattern;

<4> The process according to <1>, <2> or <3>, wherein the step (C) comprises the following steps (7a) to (10a):

(7a) a step of applying a second photoresist composition comprising a resin comprising a structural unit having an acid-labile group in its side chain and being itself insoluble or poorly soluble in an alkali aqueous solution but becoming soluble in an alkali aqueous solution by the action of an acid, and at least one acid generator selected from the group consisting of a photoacid generator represented by the formula (I) and a photoacid generator represented by the formula (II) on the first photoresist pattern obtained in the step (B) followed by conducting drying, thereby forming a second photoresist film,

(8a) a step of baking the second photoresist film formed,

(9a) a step of exposing the second photoresist film baked to radiation, and

(10a) a step of baking the second photoresist film exposed;

<5> The process according to any one of <1> to <4>, wherein A₁⁻ and A₂⁻ independently represent an anion represented by the formula (III):

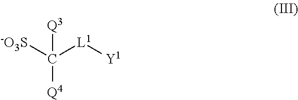

wherein Q³ and Q⁴ independently represent a fluorine atom or a C1-C6 perfluoroalkyl group, L¹ represents a single bond or a C1-C17 divalent saturated hydrocarbon group in which one or more —CH₂— can be replaced by —O— or —CO—, Y¹ represents a C1-C18 aliphatic hydrocarbon group which can have one or more substituents, a C3-C18 saturated cyclic hydrocarbon group which can have one or more substituents, and one or more —CH₂— in the aliphatic hydrocarbon group and the saturated cyclic hydrocarbon group can be replaced by —O—, —SO₂— or —CO—.

### DESCRIPTION OF PREFERRED EMBODIMENTS

The first photoresist composition used in the present invention comprises the following three components;

Component (a): a resin

Component (b): a photoacid generator

Component (c): a cross-linking agent.

First, Component (a) will be illustrated.

The resin becomes soluble in an alkali aqueous solution by the action of an acid. The resin usually has a structural unit having an acid-labile group in its side chain. The resin is itself insoluble or poorly soluble in an alkali aqueous solution but becomes soluble in an alkali aqueous solution by the action of an acid.

In this specification, “an acid-labile group” means a group capable of being eliminated by the action of an acid.

Examples of the acid-labile group include a group represented by the formula (10):

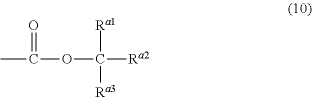

wherein R^{a1}, R^{a2} and R^{a3} independently represent an aliphatic hydrocarbon group or a saturated cyclic hydrocarbon group, and R^{a1} and R^{a2} can be bonded each other to form a ring.

Examples of the aliphatic hydrocarbon group include a C1-C8 aliphatic hydrocarbon group such as a C1-C8 alkyl group. Specific examples of the C1-C8 alkyl group include a methyl group, an ethyl group, a propyl group, an isopropyl group, a butyl group, a pentyl group, a hexyl group, a heptyl group and an octyl group. Examples of the saturated cyclic hydrocarbon group include a C3-C20 alicyclic hydrocarbon group. The alicyclic hydrocarbon group may be monocyclic or polycyclic, and examples thereof include a monocyclic alicyclic hydrocarbon group such as a C3-C20 cycloalkyl group (e.g. a cyclopentyl group, a cyclohexyl group, a methylcyclohexyl group, a dimethylcyclohexyl group, a cycloheptyl group and a cyclooctyl group) and a polycyclic alicyclic hydrocarbon group such as a decahydronaphthyl group, an adamantyl group, a norbornyl group, a methylnorbornyl group, and the followings:

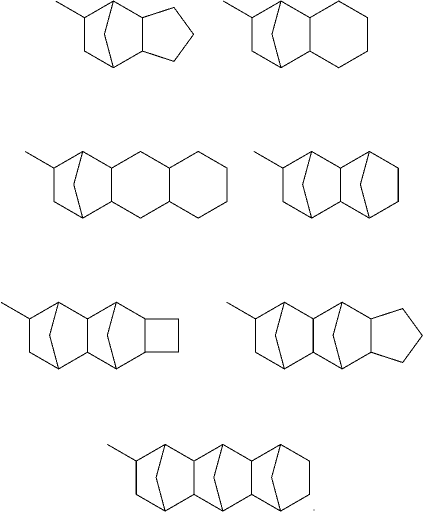

The alicyclic hydrocarbon group preferably has 5 to 20 carbon atoms.

Examples of the ring formed by bonding R^{a1} and R^{a2} each other include the following groups and the ring preferably has 5 to 20 carbon atoms.

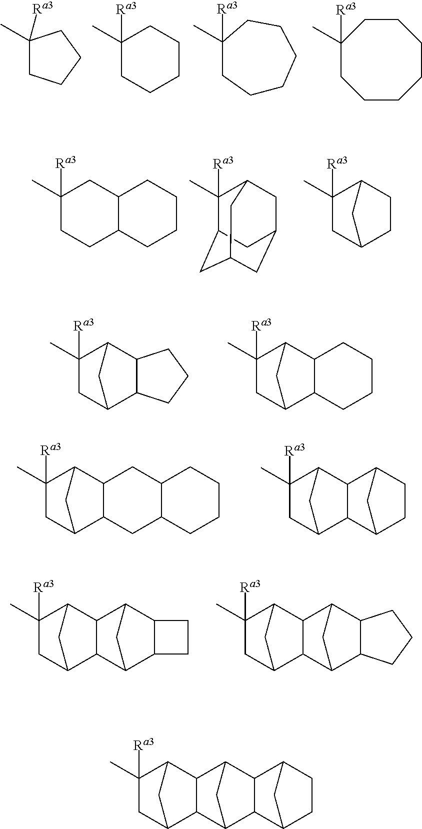

wherein R^{a3} is the same as defined above.

The group represented by the formula (10) wherein R^{a1}, R^{a2} and R^{a3} independently each represent a C1-C8 alkyl group such as a tert-butyl group, the group represented by the formula (10) wherein R^{a1} and R^{a2} are bonded each other to form an adamantyl ring and R^{a3} is a C1-C8 alkyl group such as a 2-alkyl-2-adamantyl group, and the group represented by the formula (10) wherein R^{a1} and R^{a2} are C1-C8 alkyl groups and R^{a3} is an adamantyl group such as a 1-(1-adamantyl)-1-alkylalkoxycarbonyl group are preferable.

The compound having an acid-labile group is preferably an acrylate monomer having an acid-labile group in its side chain or a methacryalte monomer having an acid-labile group in its side chain.

Preferable examples of the compound having an acid-labile group include a monomer represented by the formula (a1-1) and a monomer represented by the formula (a1-2):

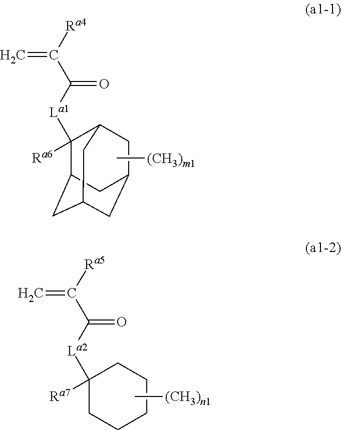

wherein R^{a4} and R^{a5} independently represents a hydrogen atom or a methyl group, R^{a6} and R^{a7} independently represents a C1-C8 aliphatic hydrocarbon group or a C3-C10 saturated cyclic hydrocarbon group, L^{a1} and L^{a2} independently represents *-O— or *-O—(CH₂)ₖ₁—CO—O— in which * represents a binding position to —CO—, and k1 represents an integer of 1 to 7, and m1 and n1 each independently represents an integer of 0 to 14, and the monomer represented by the formula (a1-1) is more preferable.

The aliphatic hydrocarbon group preferably has 1 to 6 carbon atoms, and the saturated cyclic hydrocarbon group preferably has 3 to 8 carbon atoms and more preferably 3 to 6 carbon atoms.

Examples of the aliphatic hydrocarbon group include a C1-C8 alkyl group such as a methyl group, an ethyl group, a propyl group, an isopropyl group, a butyl group, a tert-butyl group, a 2,2-dimethylethyl group, a 1-methylpropyl group, a 2,2-dimethylpropyl group, a 1-ethylpropyl group, a 1-methylbutyl group, a 2-methylbutyl group, a 3-methylbutyl group, a 1-propylbutyl group, a pentyl group, a 1-methylpentyl group, a hexyl group, a 1,4-dimethylhexyl group, a heptyl group, a 1-methylheptyl group and an octyl group. Examples of the saturated cyclic hydrocarbon group include a cyclohexyl group, a methylcyclohexyl group, a dimethylcyclohexyl group, a cycloheptyl group, a methylcycloheptyl group, a norbornyl group and a methylnorbornyl group.

L^{a1} is preferably *-O— or *-O— (CH₂)_{f1}—CO—O— in which * represents a binding position to —CO—, and f1 represents an integer of 1 to 4, and is more preferably *-O— or *-O—CH₂—CO—O—, and is especially preferably *-O—. L^{a2} is preferably *-O— or *-O—(CH₂)_{f1}—CO—O— in which * represents a binding position to —CO—, and f1 is the same as defined above, and is more preferably *-O— or *-O—CH₂—CO—O—, and is especially preferably *-O—.

In the formula (a1-1), m1 is preferably an integer of 0 to 3, and is more preferably 0 or 1. In the formula (a1-2), n1 is preferably an integer of 0 to 3, and is more preferably 0 or 1.

Particularly when the photoresist composition contains a resin derived from a monomer having a bulky structure such as a saturated cyclic hydrocarbon group, the photoresist composition having excellent resolution tends to be obtained.

Examples of the monomer represented by the formula (a1-1) include the followings.

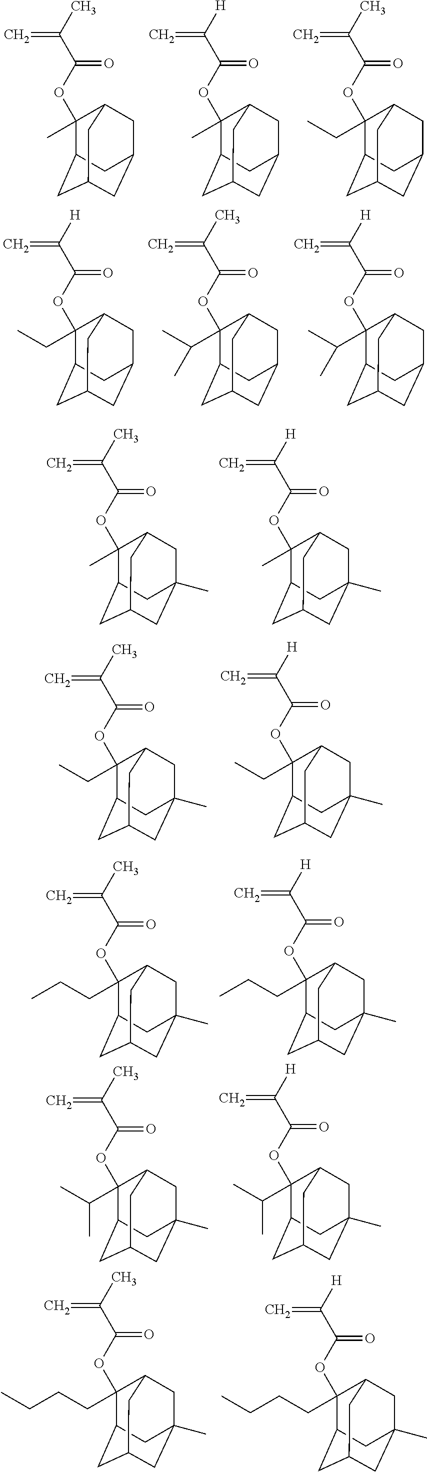

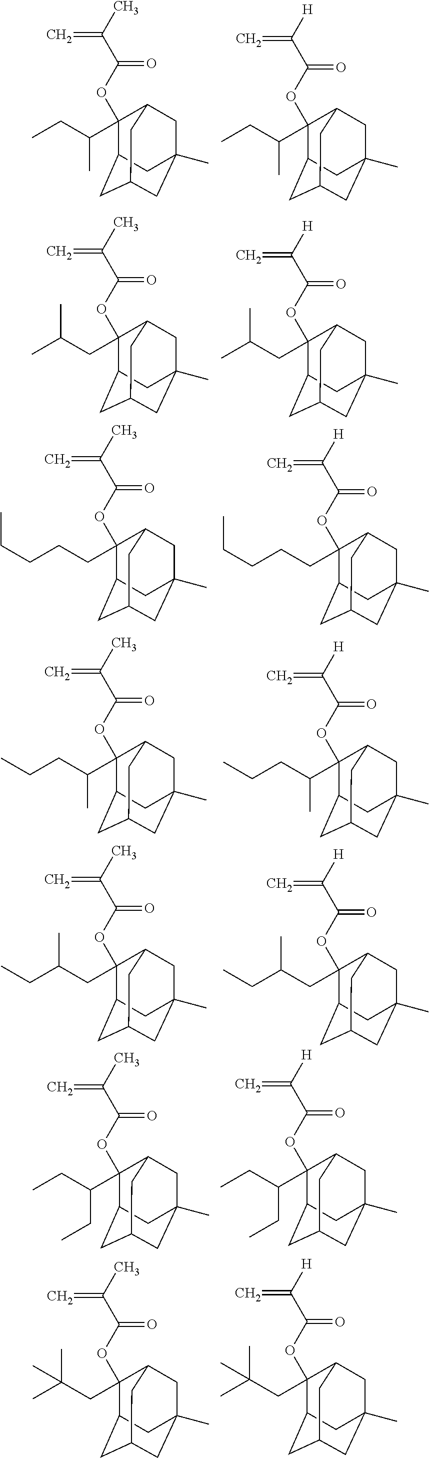

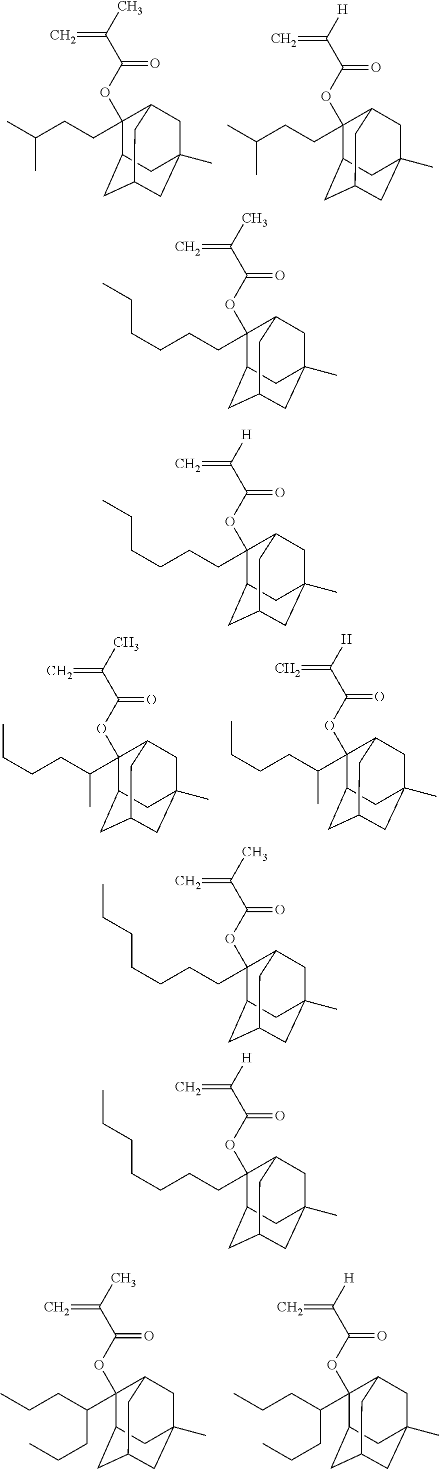

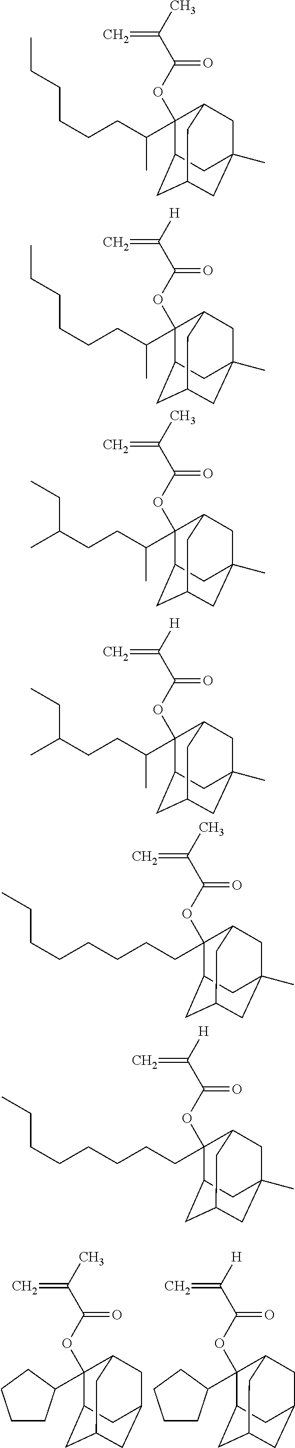

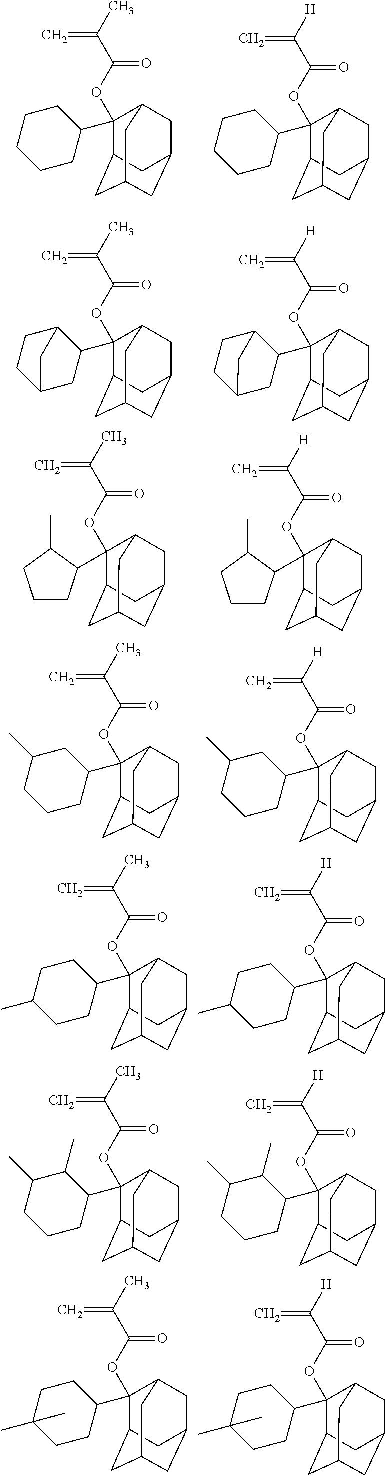

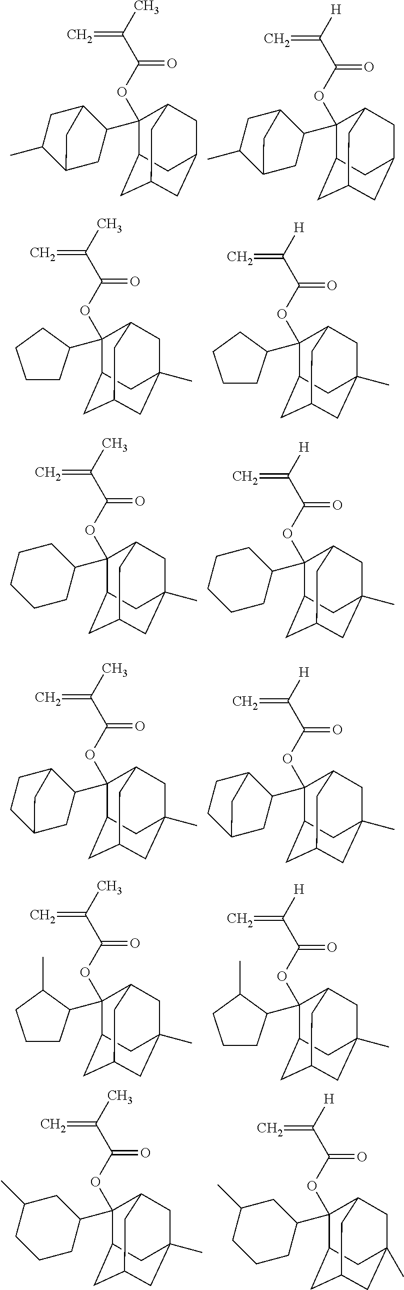

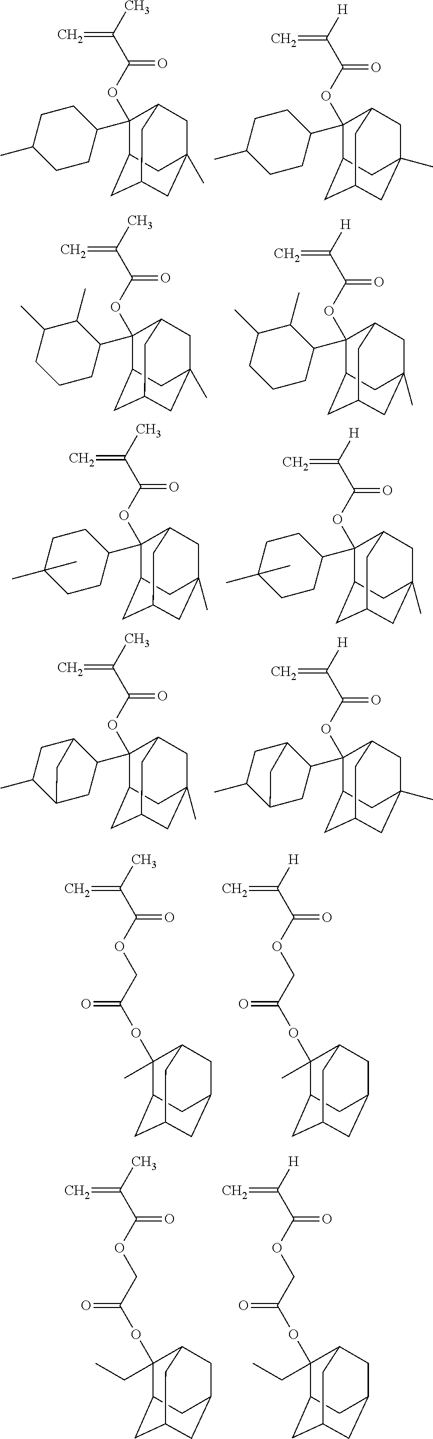

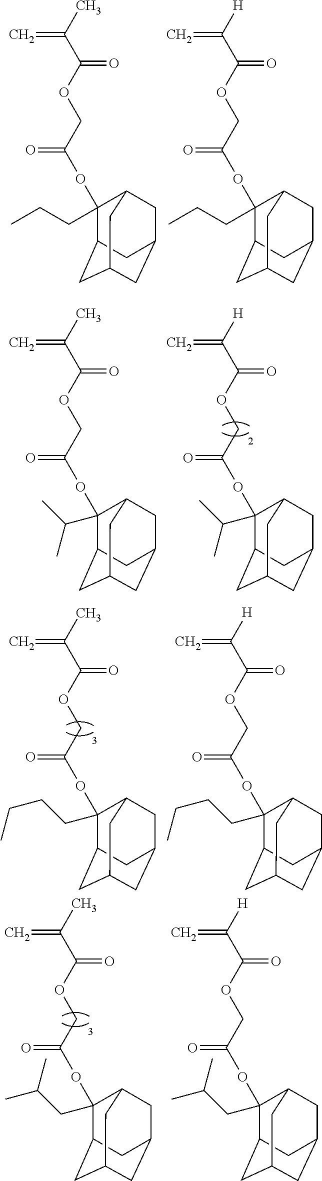

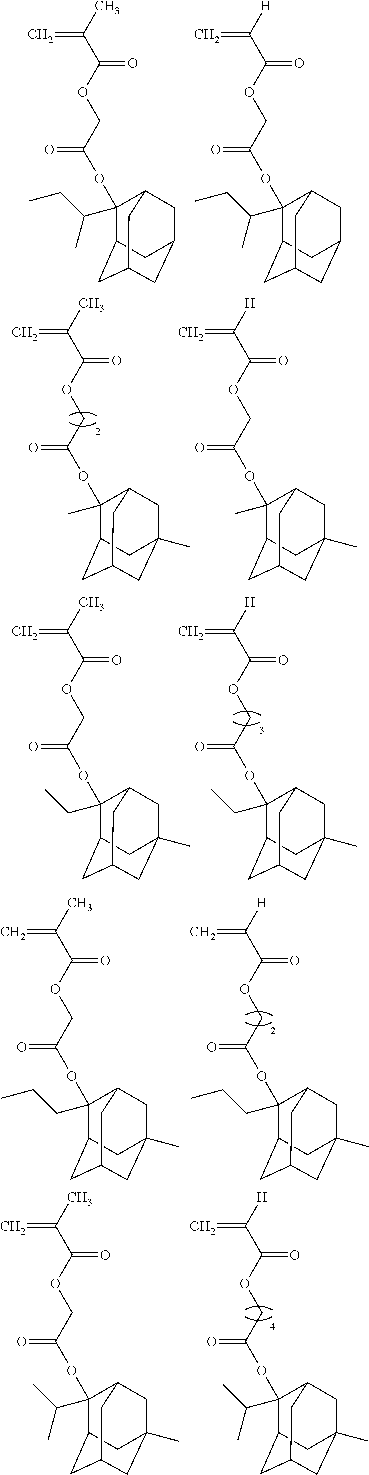

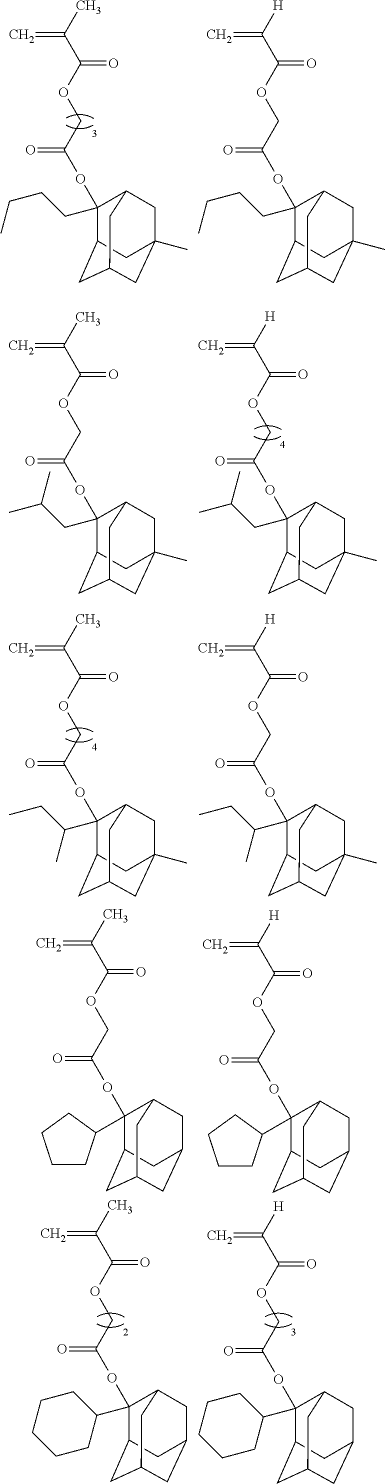

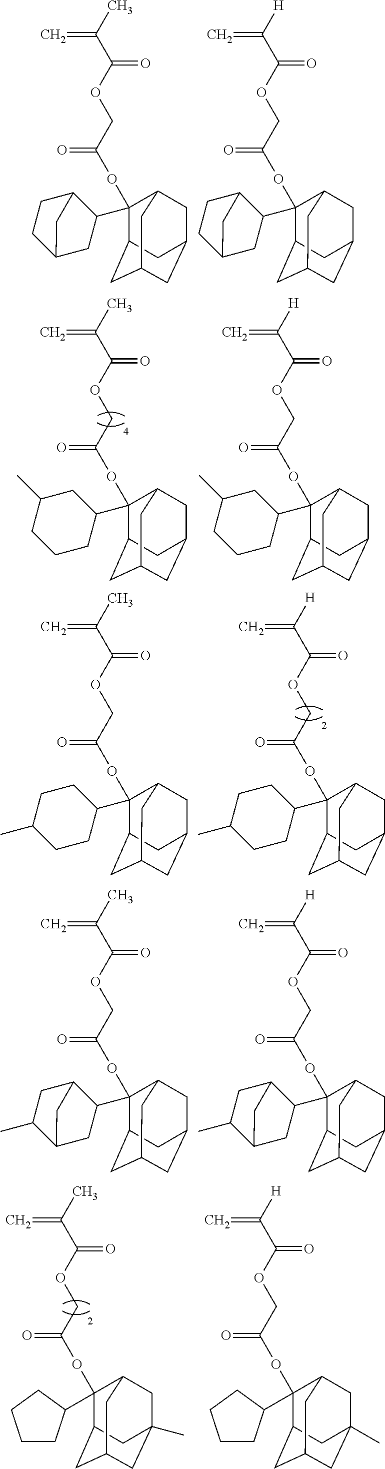

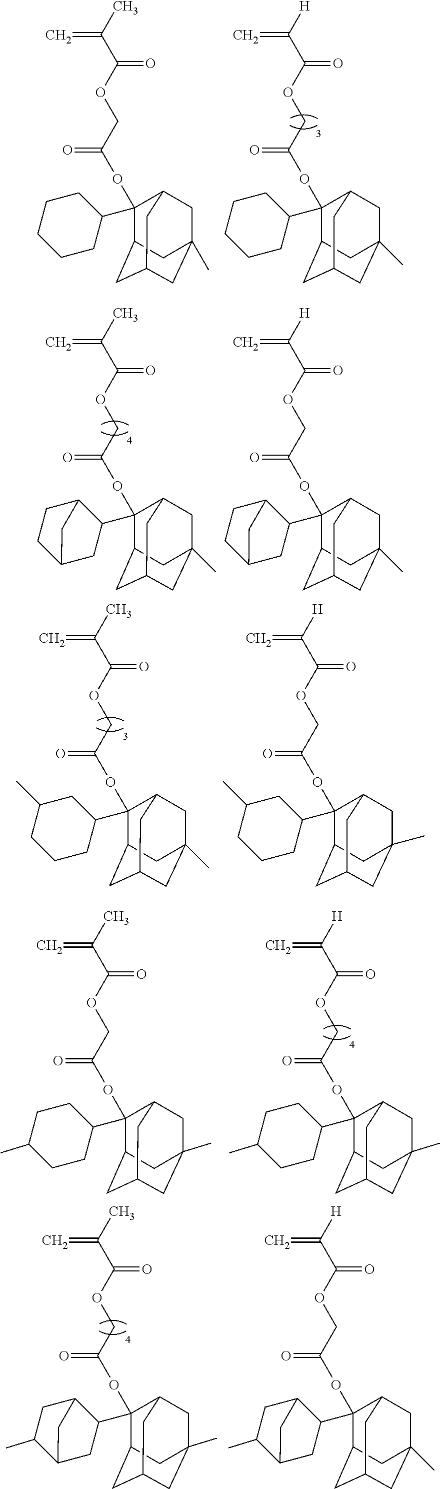

Among them, preferred are 2-methyl-2-adamantyl acrylate, 2-methyl-2-adamantyl methacrylate, 2-ethyl-2-adamantyl acrylate, 2-ethyl-2-adamantyl methacrylate, 2-isopropyl-2-adamantyl acrylate and 2-isopropyl-2-adamantyl methacrylate, and more preferred are 2-methyl-2-adamantyl methacrylate, 2-ethyl-2-adamantyl methacrylate, and 2-isopropyl-2-adamantyl methacrylate.

Examples of the monomer represented by the formula (a1-2) include the followings.

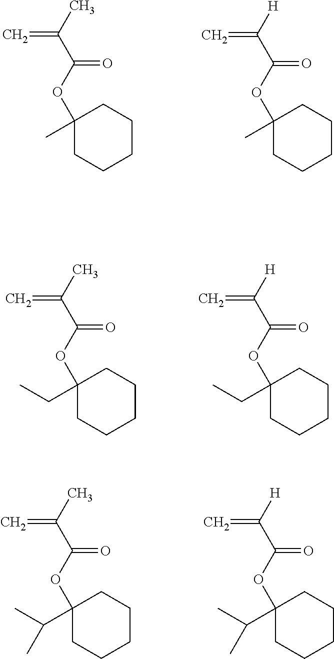

Among them, preferred are 1-ethyl-1-cyclohexyl acrylate and 1-ethyl-1-cyclohexyl methacrylate, and more preferred is 1-ethyl-1-cyclohexyl methacrylate.

The content of the structural unit having an acid-labile group in the resin is usually 10 to 95% by mole, preferably 15 to 90% by mole and more preferably 20 to 85% by mole based on total molar of all the structural units of the resin.

Examples of the compound having an acid-labile group also include a monomer represented by the formula (a1-3):

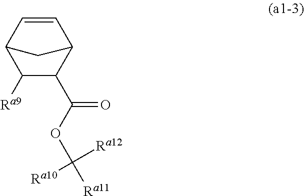

wherein R^{a9} represents a hydrogen atom, a C1-C3 aliphatic hydrocarbon group which can have one or more substituents, a carboxyl group, a cyano group or a —COOR^{a13} group in which R^{a13} represents a C1-C8 aliphatic hydrocarbon group or a C3-C8 saturated cyclic hydrocarbon group, and the C1-C8 aliphatic hydrocarbon group and the C3-C8 saturated cyclic hydrocarbon group can have one or more hydroxyl groups, and one or more —CH₂— in the C1-C8 aliphatic hydrocarbon group and the C3-C8 saturated cyclic hydrocarbon group can be replaced by —O— or —CO—, R^{a10}, R^{a11} and R^{a12} each independently represent a C1-C12 aliphatic hydrocarbon group or a C3-C12 saturated cyclic hydrocarbon group, and R^{a10} and R^{a11} can be bonded each other to form a ring together with the carbon atom to which R^{a10} and R^{a11} are bonded, and the C1-C12 aliphatic hydrocarbon group and the C3-C12 saturated cyclic hydrocarbon group can have one or more hydroxyl groups, and one or more —CH₂— in the C1-C12 aliphatic hydrocarbon group and the C3-C12 saturated cyclic hydrocarbon group can be replaced by —O— or —CO—.

Examples of the substituent include a hydroxyl group. Examples of the C1-C3 aliphatic hydrocarbon group which can have one or more substituents include a methyl group, an ethyl group, a propyl group, a hydroxymethyl group and a 2-hydroxyethyl group. Examples of R^{a13} include a methyl group, an ethyl group, a propyl group, a 2-oxo-oxolan-3-yl group and a 2-oxo-oxolan-4-yl group. Examples of R^{a10}, R^{a11} and R^{a12} include a methyl group, an ethyl group, a cyclohexyl group, a methylcyclohexyl group, a hydroxycyclohexyl group, an oxocyclohexyl group and an adamantyl group, and examples of the ring formed by bonding R^{a10} and R^{a11} each other together with the carbon atom to which R^{a10} and R^{a11} are bonded include a cyclohexane ring and an adamantane ring.

Examples of the monomer represented by the formula (a1-3) include tert-butyl 5-norbornene-2-carboxylate, 1-cyclohexyl-1-methylethyl 5-norbornene-2-carboxylate, 1-methylcyclohexyl 5-norbornene-2-carboxylate, 2-methyl-2-adamantyl 5-norbornene-2-carboxylate, 2-ethyl-2-adamantyl 5-norbornene-2-carboxylate, 1-(4-methylcyclohexyl)-1-methylethyl 5-norbornene-2-carboxylate, 1-(4-hydroxylcyclohexyl)-1-methylethyl 5-norbornene-2-carboxylate, 1-methyl-1-(4-oxocyclohexyl)ethyl 5-norbornene-2-carboxylate and 1-(1-adamantyl)-1-methylethyl 5-norbornene-2-carboxylate.

When the resin has a structural unit derived from the monomer represented by the formula (a1-3), the photoresist composition having excellent resolution and higher dry-etching resistance tends to be obtained.

When the resin contains the structural unit derived form the monomer represented by the formula (a1-3), the content of the structural unit derived from the monomer represented by the formula (a1-3) is usually 10 to 95% by mole and preferably 15 to 90% by mole and more preferably 20 to 85% by mole based on total molar of all the structural units of the resin.

Examples of the compound having an acid-labile group also include a monomer represented by the formula (a1-4):

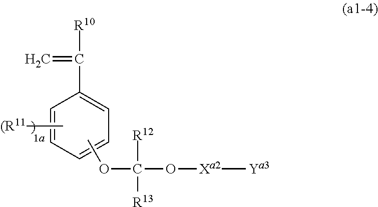

wherein R¹⁰ represents a hydrogen atom, a halogen atom, a C1-C6 alkyl group or a C1-C6 halogenated alkyl group, R¹¹ is independently in each occurrence a halogen atom, a hydroxyl group, a C1-C6 alkyl group, a C1-C6 alkoxy group, a C2-C4 acyl group, a C2-C4 acyloxy group, an acryloyl group or a methacryloyl group, 1a represents an integer of 0 to 4, R¹² and R¹³ each independently represent a hydrogen atom or a C1-C12 hydrocarbon group, X^{a2} represents a single bond or a C1-C17 divalent saturated hydrocarbon group in which one or more —CH₂— can be replaced by —O—, —CO—, —S—, —SO₂— or —N(R^{c})— wherein R^{c} represents a hydrogen atom or a C1-C6 alkyl group, and Y^{a3} represents a C1-C12 aliphatic hydrocarbon group, a C3-C18 saturated cyclic hydrocarbon group or a C6-C18 aromatic hydrocarbon group, and the C1-C12 aliphatic hydrocarbon group, the C2-C18 saturated cyclic hydrocarbon group and the C6-C18 aromatic hydrocarbon group can have one or more substituents.

Examples of the halogen atom include a fluorine atom.

Examples of the C1-C6 alkyl group include a methyl group, an ethyl group, a propyl group, an isopropyl group, a butyl group, an isobutyl group, a sec-butyl group, a tert-butyl group, a pentyl group and a hexyl group, and a C1-C4 alkyl group is preferable and a C1-C2 alkyl group is more preferable and a methyl group is especially preferable.

Examples of the C1-C6 halogenated alkyl group include a trifluoromethyl group, a pentafluoroethyl group, a heptafluoropropyl group, a heptafluoroisopropyl group, a nonafluorobutyl group, a nonafluoro-sec-butyl group, a nonafluoro-tert-butyl group, a perfluoropentyl group and a perfluorohexyl group.

Examples of the C1-C6 alkoxy group include a methoxy group, an ethoxy group, a propoxy group, an isopropoxy group, a butoxy group, an isobutoxy group, a sec-butoxy group, a tert-butoxy group, a pentyloxy group and a hexyloxy group, and a C1-C4 alkoxy group is preferable and a C1-C2 alkoxy group is more preferable and a methoxy group is especially preferable.

Examples of the C2-C4 acyl group include an acetyl group, a propionyl group and a butyryl group, and examples of the C2-C4 acyloxy group include an acetyloxy group, a propionyloxy group and a butyryloxy group.

Examples of the C1-C12 hydrocarbon group include a C1-C12 aliphatic hydrocarbon group such as a methyl group, an ethyl group, a propyl group, an isopropyl group, a butyl group, an isobutyl group, a sec-butyl group, a tert-butyl group, a pentyl group, a hexyl group, a heptyl group, an octyl group, a 2-ethylhexyl group, a nonyl group, a decyl group, an undecyl group and a dodecyl group, and a C3-C12 saturated cyclic hydrocarbon group such as a cyclohexyl group, an adamantyl group, a 2-alkyl-2-adamantyl group, a 1-(1-adamantyl)-1-alkyl group and an isobornyl group.

Examples of the C1-C17 divalent saturated hydrocarbon group include a C1-C17 alkanediyl group such as a methylene group, an ethylene group, a propane-1,3-diyl group, a butane-1,4-diyl group, a pentane-1,5-diyl group, a hexane-1,6-diyl group, a heptane-1,7-diyl group, an octane-1,8-diyl group, a nonane-1,9-diyl group, a decane-1,10-diyl group, a undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group and a heptadecane-1,17-diyl group.

Examples of the C1-C12 aliphatic hydrocarbon group include a methyl group, an ethyl group, a propyl group, an isopropyl group, a butyl group, an isobutyl group, a sec-butyl group, a tert-butyl group, a pentyl group, a hexyl group, a heptyl group, an octyl group, a 2-ethylhexyl group, a nonyl group, a decyl group, an undecyl group and a dodecyl group. Examples of the C3-C18 saturated cyclic hydrocarbon group include a cyclopropyl group, a cyclobutyl group, a cyclopentyl group, a cyclohexyl group, a cycloheptyl group, a cyclooctyl group, a cyclononyl group, a cyclodecyl group, a norbornyl group, a 1-adamantyl group, a 2-adamantyl group, an isobornyl group and the following groups:

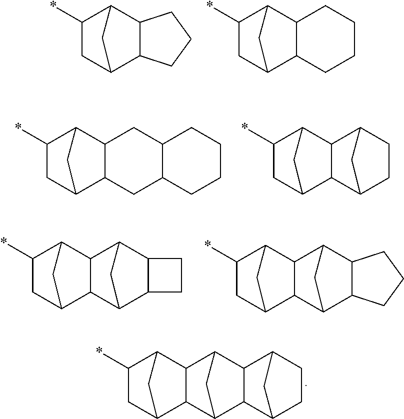

Examples of the C6-C18 aromatic hydrocarbon group include a phenyl group, a naphthyl group, an anthryl group, a p-methylphenyl group, a p-tert-butylphenyl group and a p-adamantylphenyl group.

Examples of the monomer represented by the formula (a1-4) include the followings.

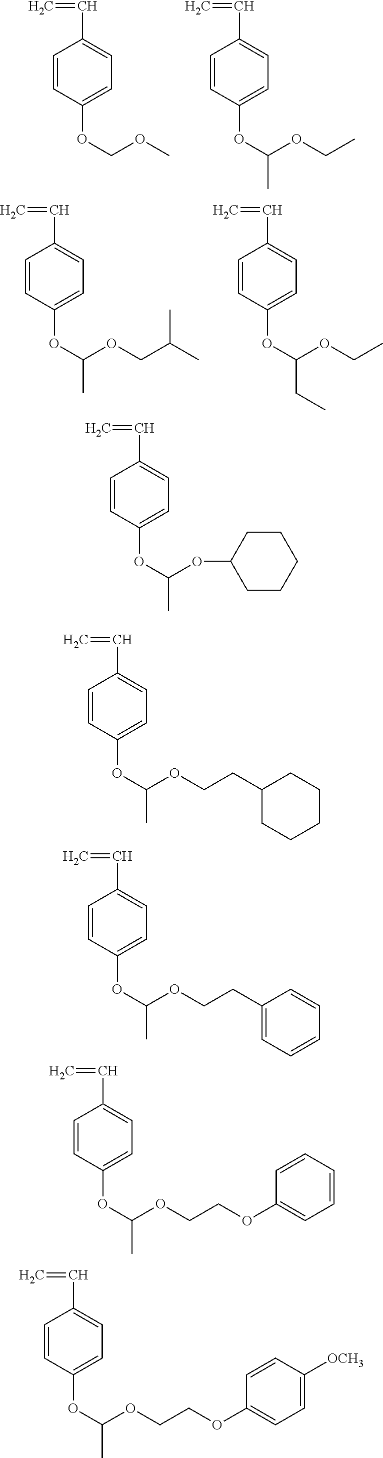

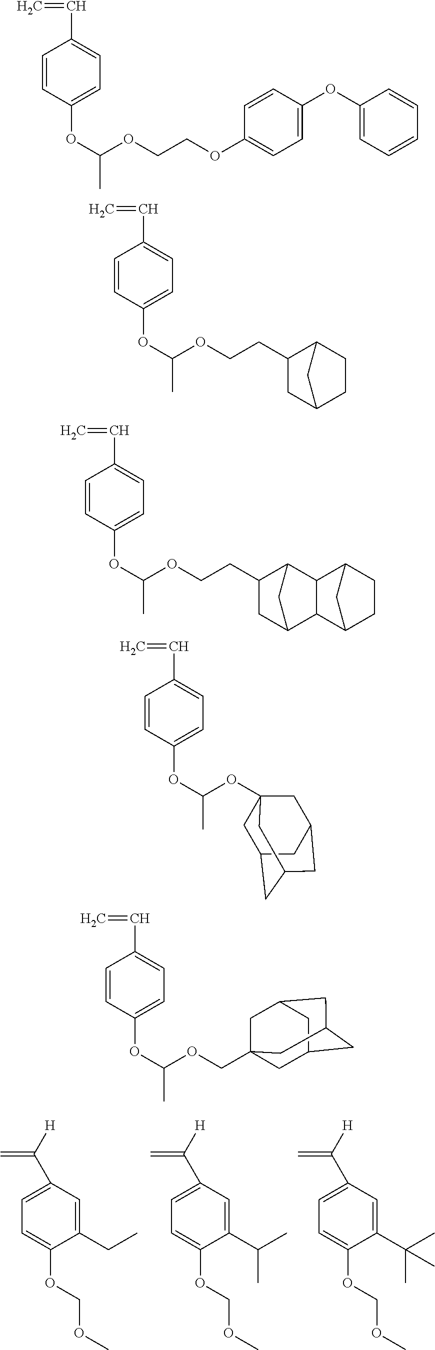

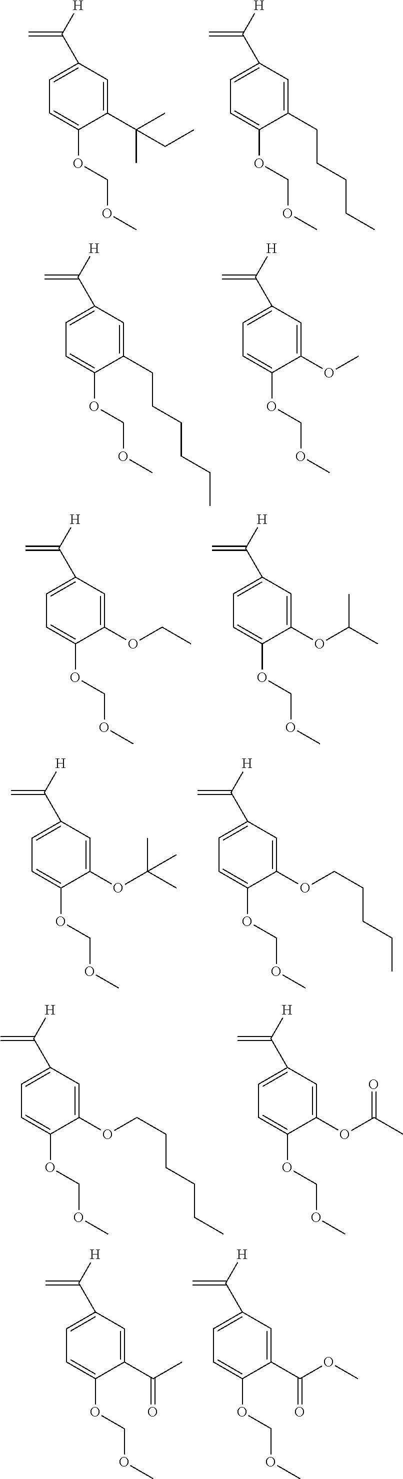

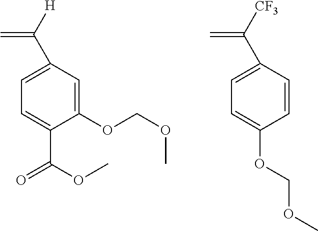

When the resin contains the structural unit derived form the monomer represented by the formula (a1-4), the content of the structural unit derived from the monomer represented by the formula (a1-4) is usually 10 to 95% by mole and preferably 15 to 90% by mole and more preferably 20 to 85% by mole based on total molar of all the structural units of the resin.

The resin can have two or more kinds of structural units derived from the compounds having an acid-labile group.

The resin preferably contains the structural unit derived from the compound having an acid-labile group and a structural unit derived from the compound having no acid-labile group. The resin can have two or more kinds of structural units derived from the compounds having no acid-labile group. When the resin contains the structural unit derived from the compound having an acid-labile group and the structural unit derived from the compound having no acid-labile group, the content of the structural unit derived from the compound having an acid-labile group is usually 10 to 80% by mole and preferably 20 to 60% by mole based on total molar of all the structural units of the resin. The content of the structural unit derived from a monomer having an adamantyl group, especially the monomer represented by the formula (a1-1) in the structural unit derived from the compound having no acid-labile group is preferably 15% by mole or more from the viewpoint of dry-etching resistance of the photoresist composition.

The compound having no acid-labile group preferably contains one or more hydroxyl groups or a lactone ring. When the resin contains the structural unit derived from the compound having no acid-labile group and having one or more hydroxyl groups or a lactone ring, a photoresist composition having good resolution and adhesiveness of photoresist to a substrate tends to be obtained.

Examples of the compound having no acid-labile group and having one or more hydroxyl groups include a monomer represented by the formula (a2-0):

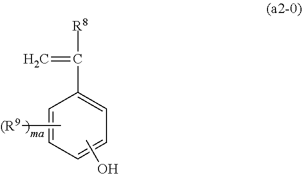

wherein R⁸ represents a hydrogen atom, a halogen atom, a C1-C6 alkyl group or a C1-C6 halogenated alkyl group, R⁹ is independently in each occurrence a halogen atom, a hydroxyl group, a C1-C6 alkyl group, a C1-C6 alkoxy group, a C2-C4 acyl group, a C2-C4 acyloxy group, an acryloyl group or a methacryloyl group, ma represents an integer of 0 to 4, and
a monomer represented by the formula (a2-1):

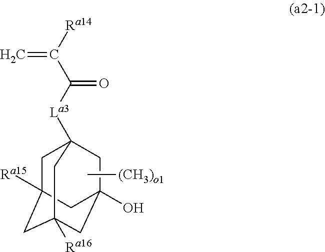

wherein R^{a14} represents a hydrogen atom or a methyl group, R^{a15} and R^{a16} each independently represent a hydrogen atom, a methyl group or a hydroxyl group, L^{a3} represents *-O— or *-O—(CH₂)ₖ₂—CO—O— in which * represents a binding position to —CO—, and k2 represents an integer of 1 to 7, and of represents an integer of 0 to 10.

When KrF excimer laser (wavelength: 248 nm) lithography system, or a high energy laser such as electron beam and extreme ultraviolet is used as an exposure system, the resin containing the structural unit derived from the monomer represented by the formula (a2-0) is preferable, and when ArF excimer laser (wavelength: 193 nm) is used as an exposure system, the resin containing the structural unit derived from the monomer represented by the formula (a2-1) is preferable.

In the formula (a2-0), examples of the halogen atom include a fluorine atom, examples of the C1-C6 alkyl group include a methyl group, an ethyl group, a propyl group, an isopropyl group, a butyl group, an isobutyl group, a sec-butyl group, a tert-butyl group, a pentyl group and a hexyl group, and a C1-C4 alkyl group is preferable and a C1-C2 alkyl group is more preferable and a methyl group is especially preferable. Examples of the C1-C6 halogenated alkyl group include a trifluoromethyl group, a pentafluoroethyl group, a heptafluoropropyl group, a heptafluoroisopropyl group, a nonafluorobutyl group, a nonafluoro-sec-butyl group, a nonafluoro-tert-butyl group, a perfluoropentyl group and a perfluorohexyl group. Examples of the C1-C6 alkoxy group include a methoxy group, an ethoxy group, a propoxy group, an isopropoxy group, a butoxy group, an isobutoxy group, a sec-butoxy group, a tert-butoxy group, a pentyloxy group and a hexyloxy group, and a C1-C4 alkoxy group is preferable and a C1-C2 alkoxy group is more preferable and a methoxy group is especially preferable. Examples of the C2-C4 acyl group include an acetyl group, a propionyl group and a butyryl group, and examples of the C2-C4 acyloxy group include an acetyloxy group, a propionyloxy group and a butyryloxy group. In the formula (a2-0), ma is preferably 0, 1 or 2, and is more preferably 0 or 1, and especially preferably 0.

The resin containing the structural unit derived from the monomer represented by the formula (a2-0) and the structural unit derived from the compound having an acid generator can be produced, for example, by polymerizing the compound having an acid generator and a monomer obtained by protecting a hydroxyl group of the monomer represented by the formula (a2-0) with an acetyl group followed by conducting deacetylation of the obtained polymer with a base.

Examples of the monomer represented by the formula (a2-0) include the followings.

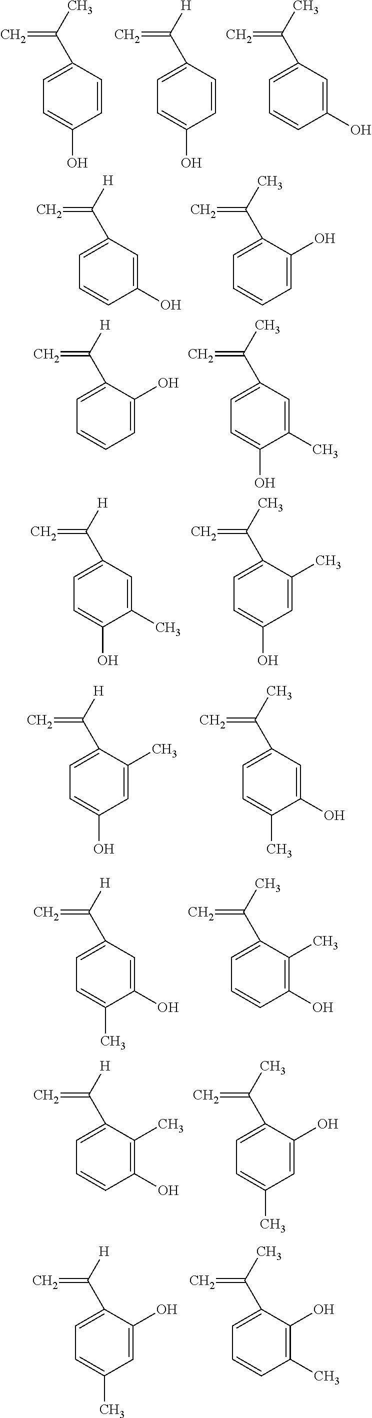

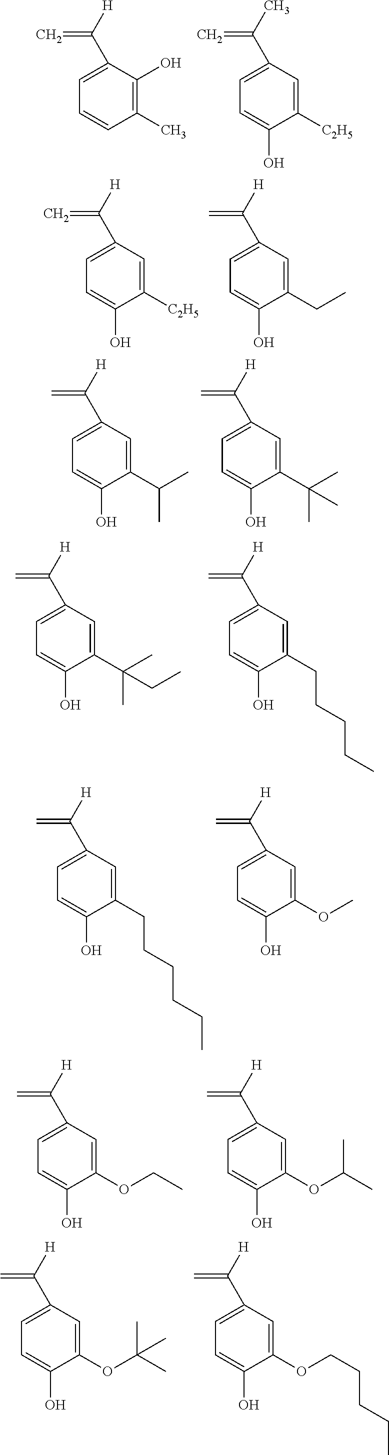

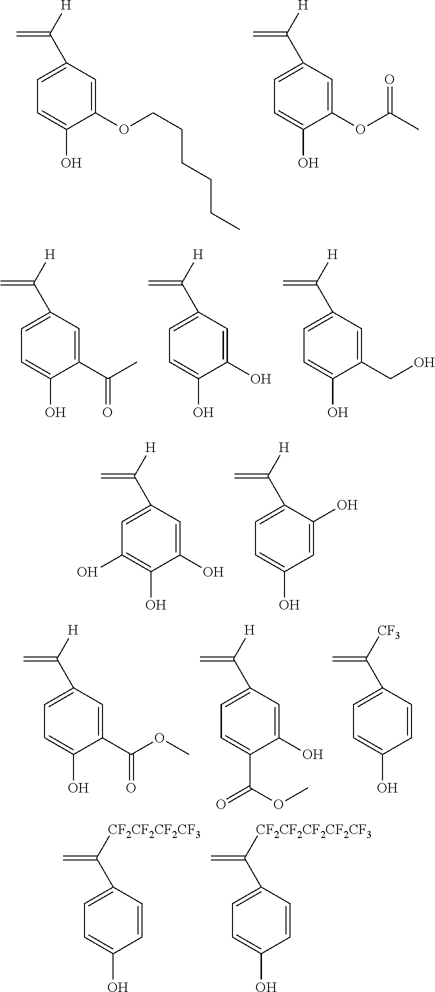

Among them, preferred are 4-hydroxystyrene and 4-hydroxy-α-methylstyrene.

When the resin contains the structural unit derived from the monomer represented by the formula (a2-0), the content of the structural unit derived from the monomer represented by the formula (a2-0) is usually 5 to 90% by mole and preferably 10 to 85% by mole and more preferably 15 to 80% by mole based on total molar of all the structural units of the resin.

In the formula (a2-1), R^{a14} is preferably a methyl group, R^{a15} is preferably a hydrogen atom, R^{a16} is preferably a hydrogen atom or a hydroxyl group, L^{a3} is preferably *-O— or *-O— (CH₂)_{f2}—CO—O— in which * represents a binding position to —CO—, and f2 represents an integer of 1 to 4, and is more preferably *-O—, and of is preferably 0, 1, 2 or 3 and is more preferably 0 or 1.

Examples of the monomer represented by the formula (a2-1) include the followings, and 3-hydroxy-1-adamantyl acrylate, 3-hydroxy-1-adamantyl methacrylate, 3,5-dihydroxy-1-adamantyl acrylate, 3,5-dihydroxy-1-adamantyl methacrylate, 1-(3,5-dihydroxy-1-adamantyloxycarbonyl)methyl acrylate and 1-(3,5-dihydroxy-1-adamantyloxycarbonyl)methyl methacrylate are preferable, and 3-hydroxy-1-adamantyl methacrylate and 3,5-dihydroxy-1-adamantyl methacrylate are more preferable.

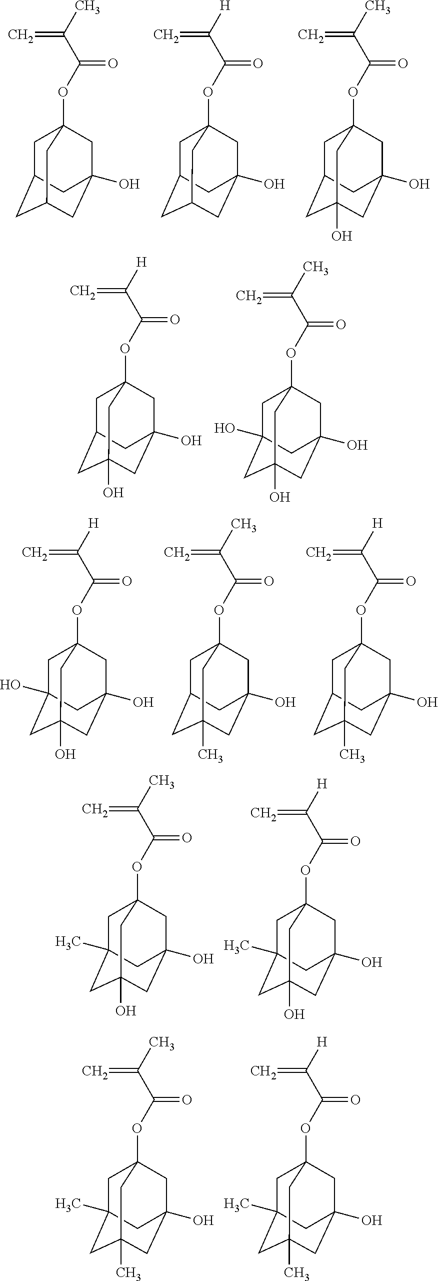

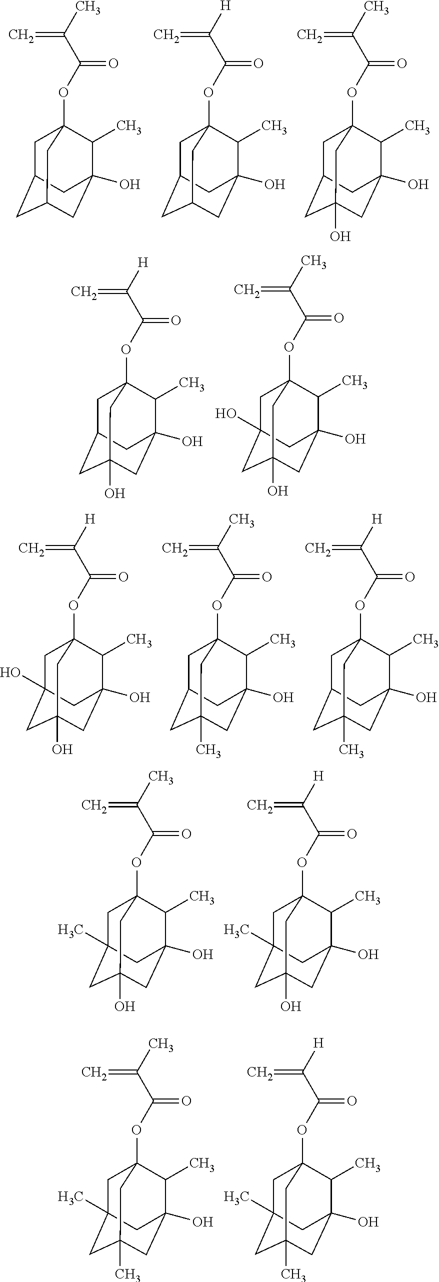

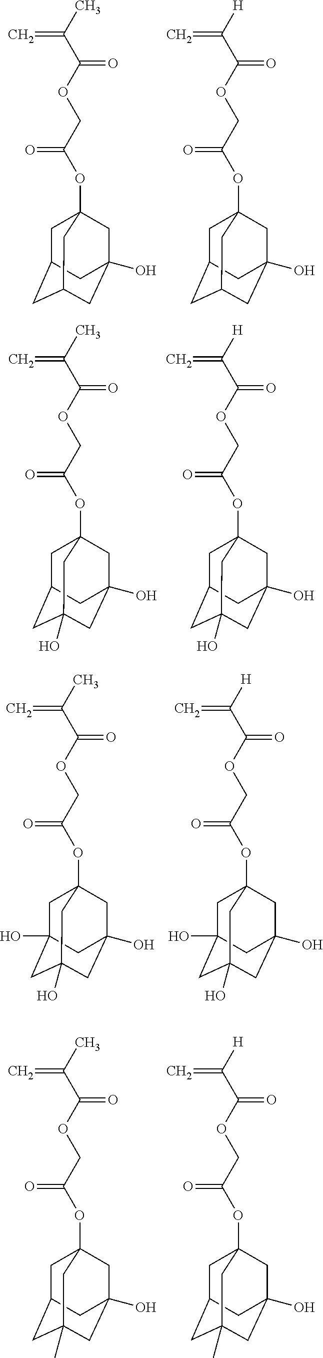

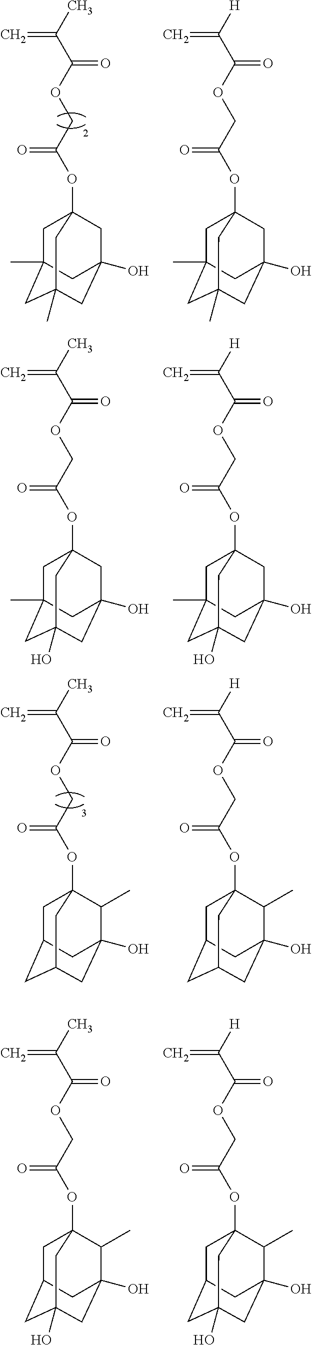

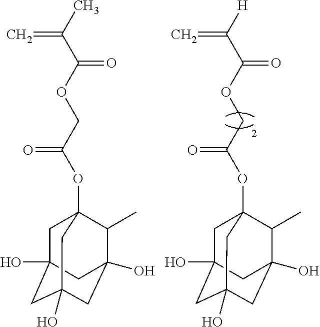

When the resin contains the structural unit derived from the monomer represented by the formula (a2-1), the content of the structural unit derived from the monomer represented by the formula (a2-1) is usually 3 to 40% by mole and preferably 5 to 35% by mole and more preferably 5 to 30% by mole based on total molar of all the structural units of the resin.

Examples of the lactone ring of the compound having no acid-labile group and a lactone ring include a monocyclic lactone ring such as β-propiolactone ring, γ-butyrolactone ring and γ-valerolactone ring, and a condensed ring formed from a monocyclic lactone ring and the other ring. Among them, preferred are γ-butyrolactone ring and a condensed lactone ring formed from γ-butyrolactone ring and the other ring.

Preferable examples of the monomer having no acid-labile group and a lactone ring include the monomers represented by the formulae (a3-1), (a3-2) and (a3-3):

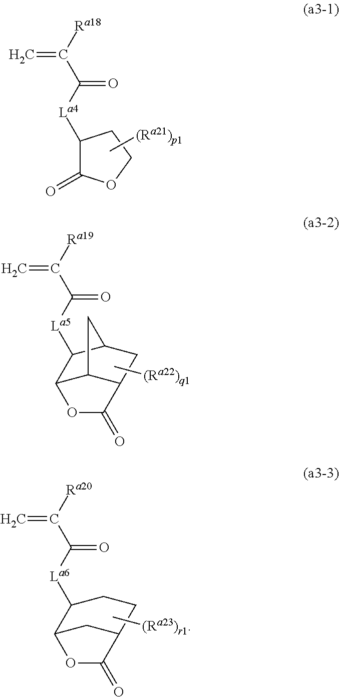

wherein L^{a4}, L^{a5} and L^{a6} each independently represent *-O— or *-O—(CH₂)ₖ₃—CO—O— in which * represents a binding position to —CO— and k3 represents an integer of 1 to 7, R^{a18}, R^{a19} and R^{a20} each independently represent a hydrogen atom or a methyl group, R^{a21} represents a C1-C4 aliphatic hydrocarbon group, R^{a22} and R^{a23} are independently in each occurrence a carboxyl group, a cyano group or a C1-C4 aliphatic hydrocarbon group, and p1 represents an integer of 0 to 5, q1 and r1 independently each represent an integer of 0 to 3.

It is preferred that L^{a4}, Lₐ₅ and L^{a6} each independently represent *-O— or *-O—(CH₂)_{d1}—CO—O— in which * represents a binding position to —CO— and d1 represents an integer of 1 to 4, and it is more preferred that L^{a4}, L^{a5} and L^{a6} are *-O—R^{a18}, R^{a19} and R^{a20} are preferably methyl groups. R^{a21} is preferably a methyl group. It is preferred that R^{a22} and R^{a23} are independently in each occurrence a carboxyl group, a cyano group or a methyl group. It is preferred that p1 is an integer of 0 to 2, and it is more preferred that p1 is 0 or 1. It is preferred that q1 and r1 independently each represent an integer of 0 to 2, and if is more preferred that q1 and r1 independently each represent 0 or 1.

Examples of the monomer represented by the formula (a3-1) include the followings.

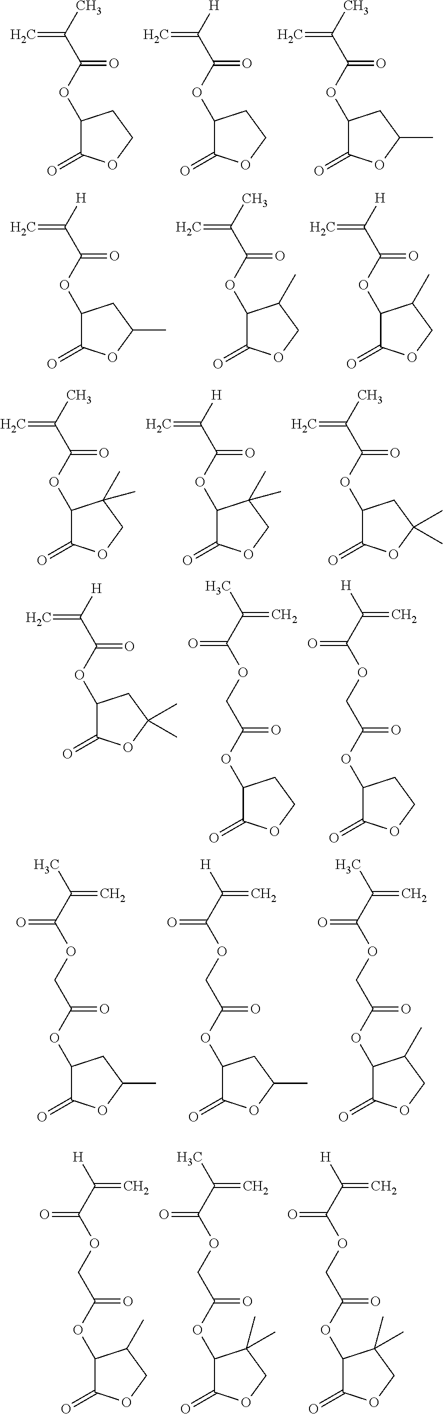

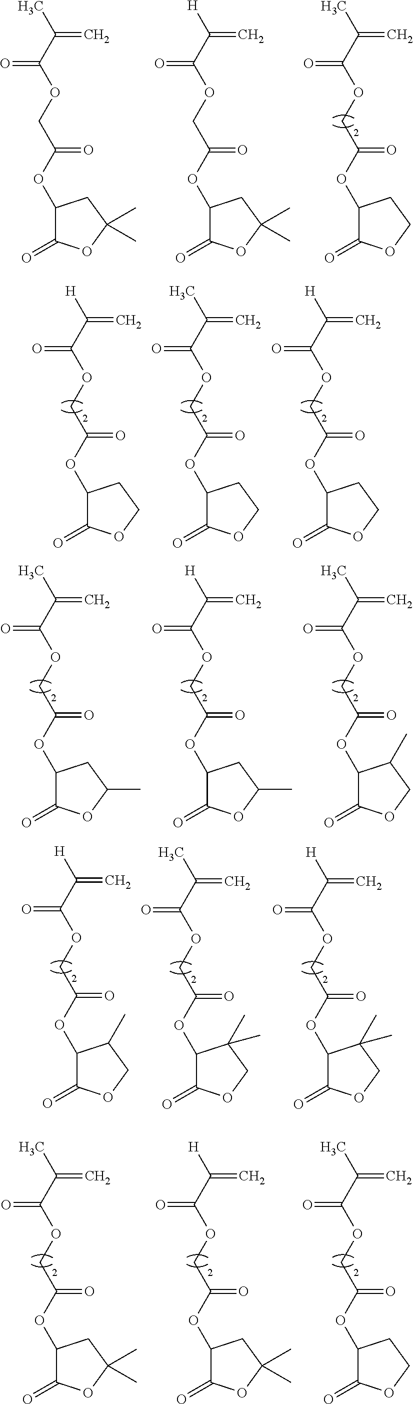

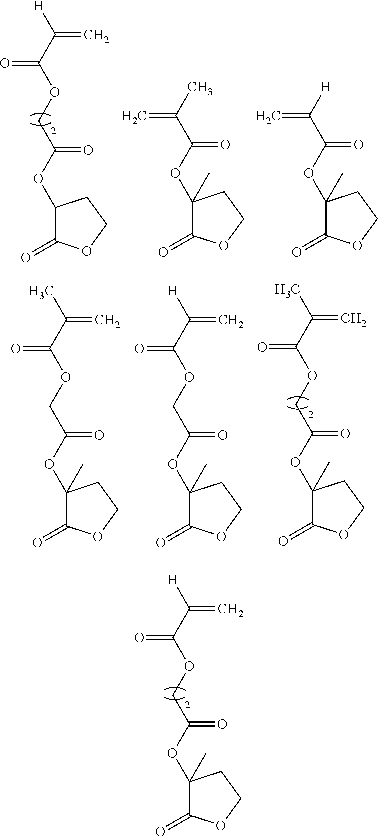

Examples of the monomer represented by the formula (a3-2) include the followings.

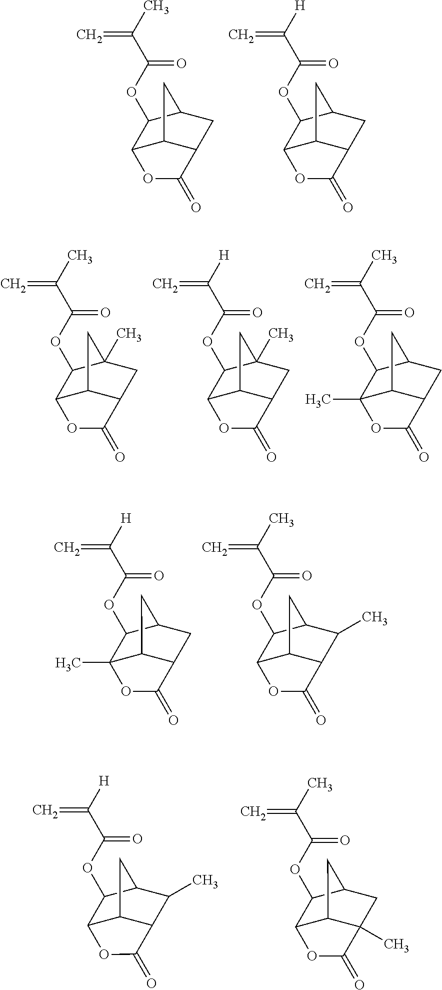

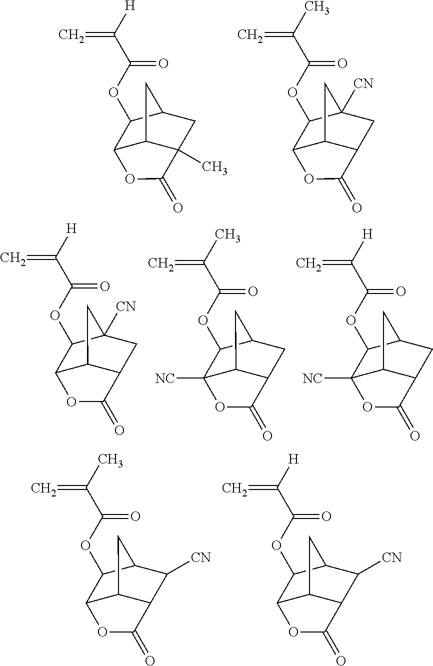

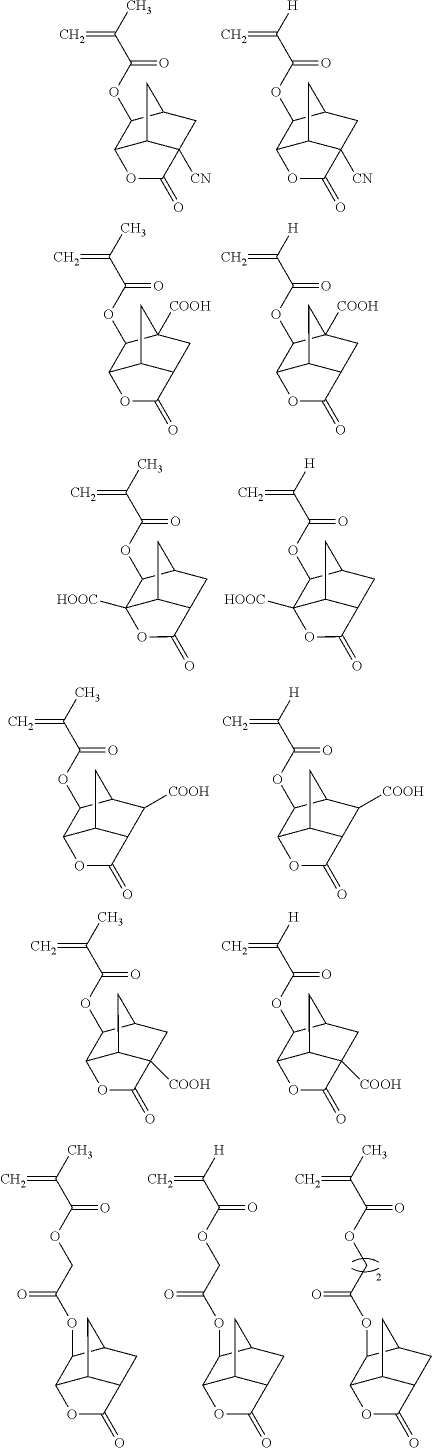

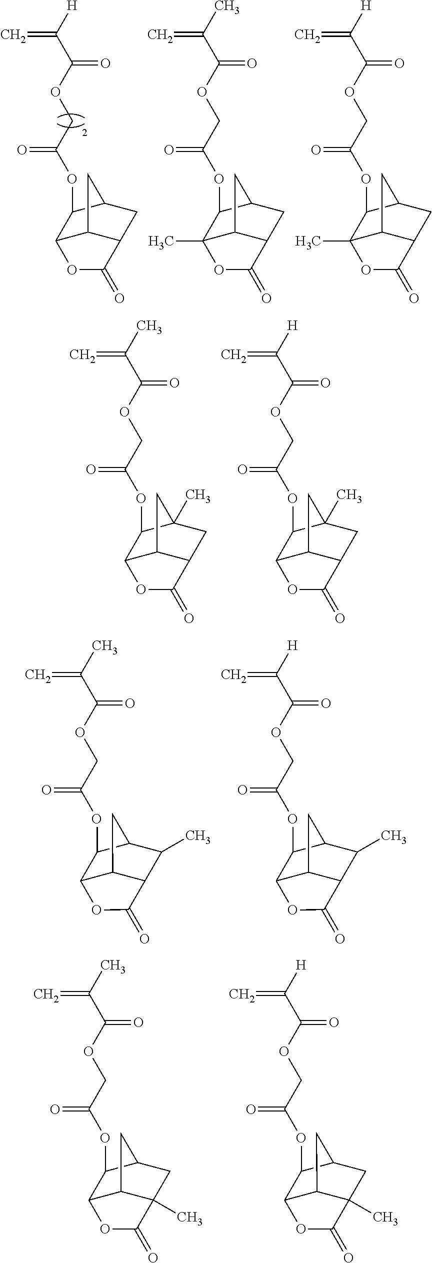

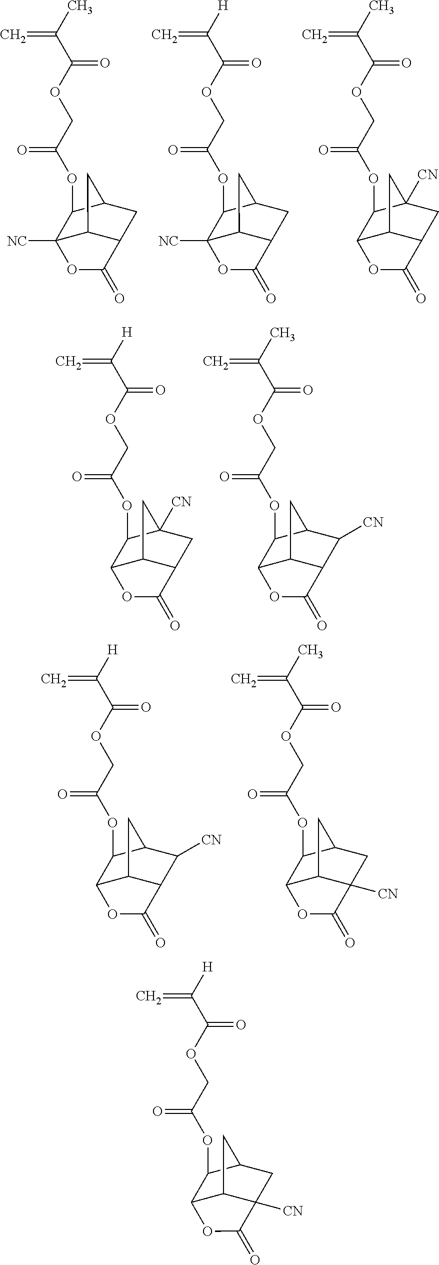

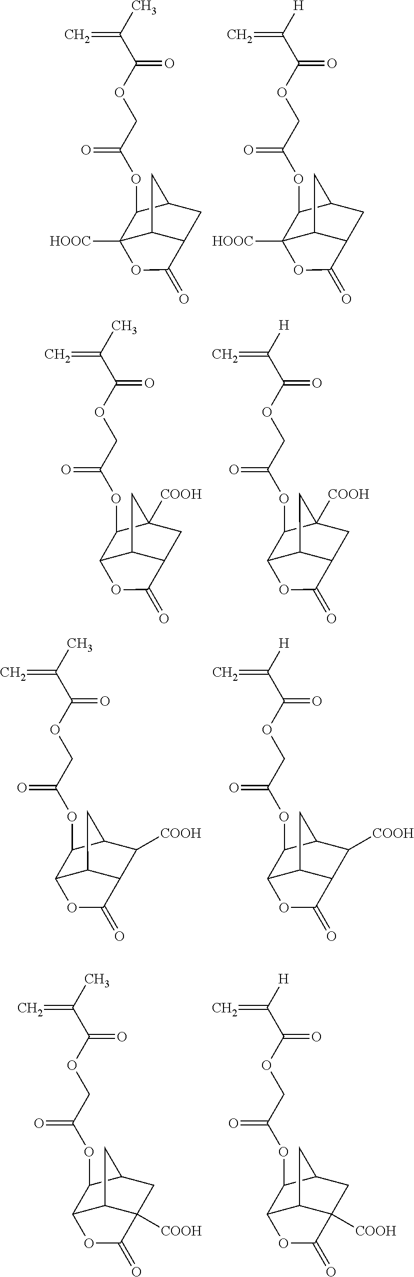

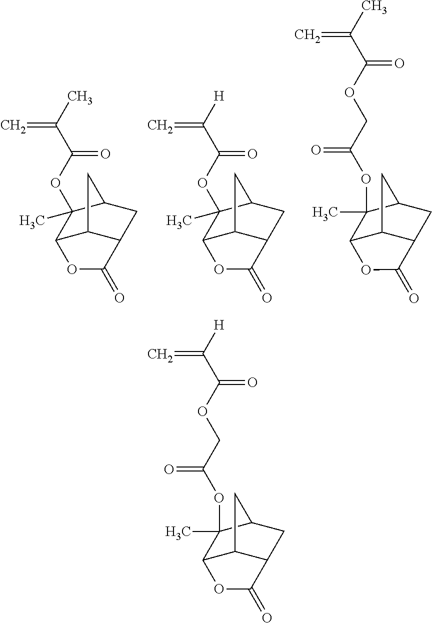

Examples of the monomer represented by the formula (a3-3) include the followings.

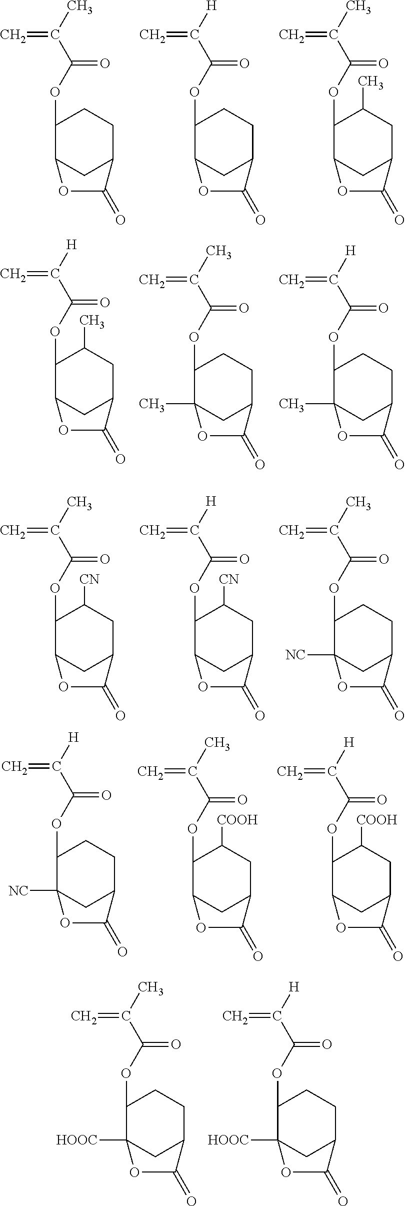

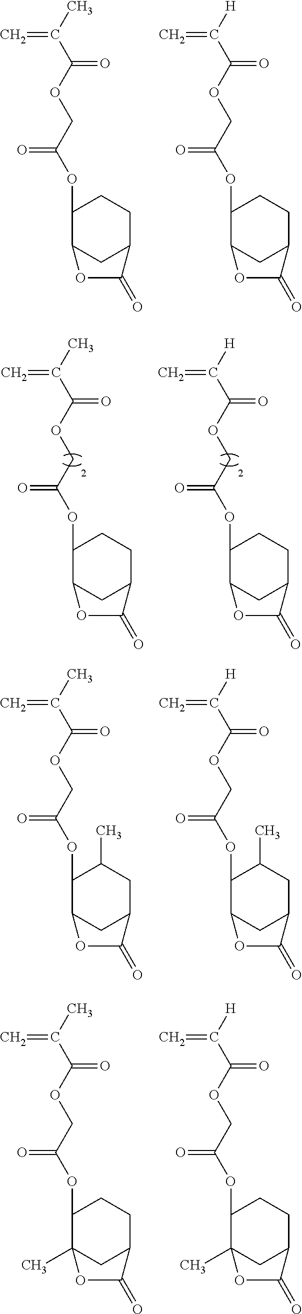

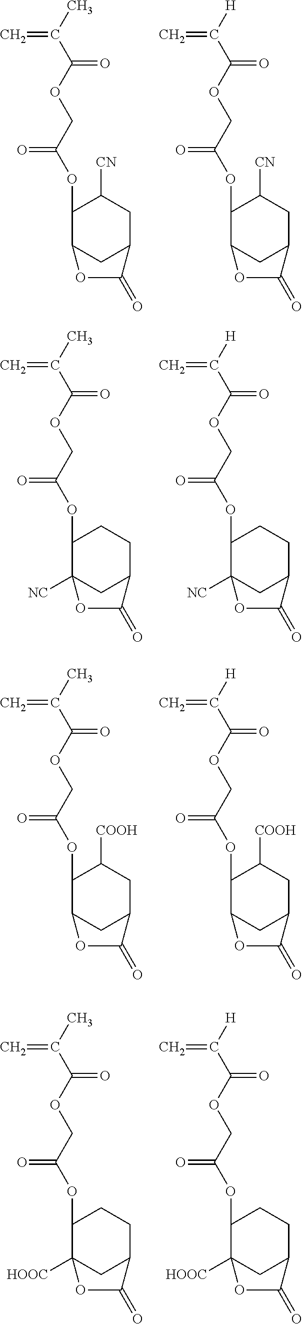

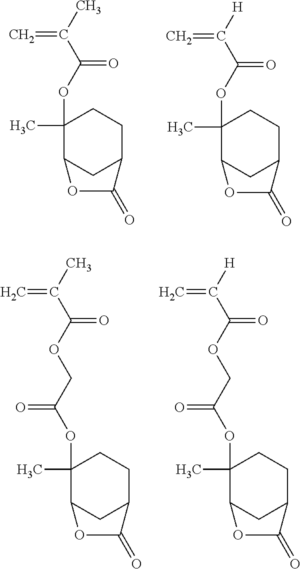

Among them, preferred are 5-oxo-4-oxatricyclo[4.2.1.0^{3,7}]nonan-2-yl acrylate, 5-oxo-4-oxatricyclo[4.2.1.0^{3,7}]nonan-2-yl methacrylate, tetrahydro-2-oxo-3-furyl acrylate, tetrahydro-2-oxo-3-furyl methacrylate, 2-(5-oxo-4-oxatricyclo[4.2.1.0^{3,7}]nonan-2-yloxy)-2-oxoethyl acrylate and 2-(5-oxo-4-oxatricyclo[4.2.1.0^{3,7}]nonan-2-yloxy)-2-oxoethyl methacrylate, and more preferred are 5-oxo-4-oxatricyclo[4.2.1.0^{3,7}]nonan-2-yl methacrylate, tetrahydro-2-oxo-3-furyl methacrylate and 2-(5-oxo-4-oxatricyclo[4.2.1.0^{3,7}]nonan-2-yloxy)-2-oxoethyl methacrylate.

When the resin contains the structural unit derived from the monomer having no acid-labile group and having a lactone ring, the content thereof is usually 5 to 50% by mole and preferably 10 to 45% by mole and more preferably 15 to 40% by mole based on total molar of all the structural units of the resin.

The resin can contain a structural unit derived from a monomer having an acid labile group containing a lactone ring. Examples of the monomer having an acid labile group containing a lactone ring include the followings.

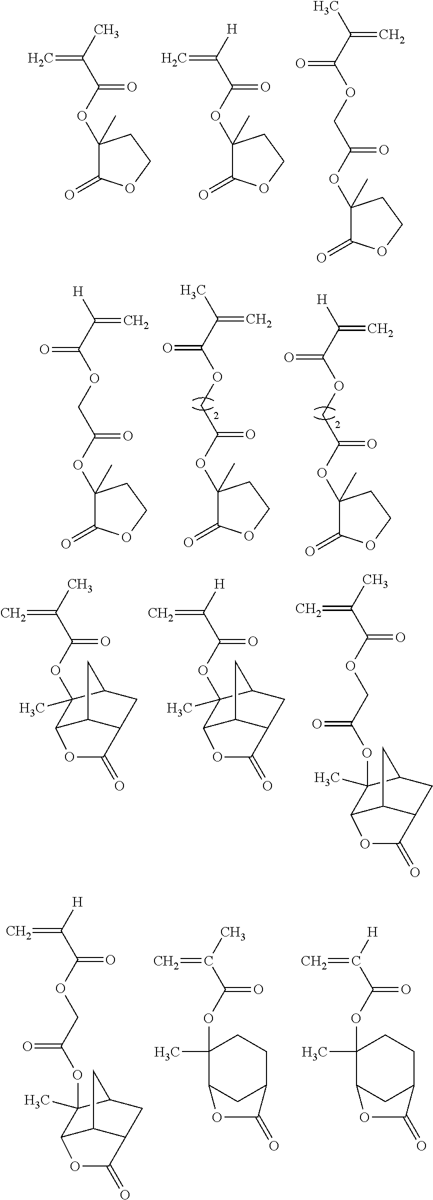

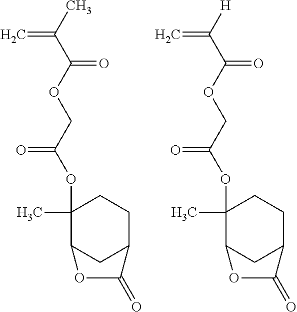

Examples of the other monomer having no acid-labile group include the monomers represented by the formulae (a-4-1), (a-4-2) and (a-4-3):

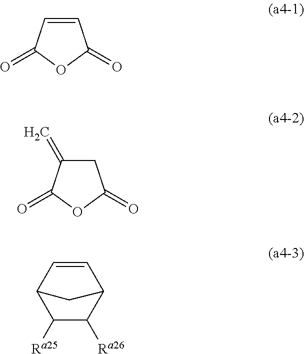

wherein R^{a25} and R^{a26} each independently represents a hydrogen atom, a C1-C3 aliphatic hydrocarbon group which can have one or more substituents, a carboxyl group, a cyano group or a —COOR^{a27} group in which R^{a27} represents a C1-C36 aliphatic hydrocarbon group or a C3-C36 saturated cyclic hydrocarbon group, and one or more —CH₂— in the C1-C36 aliphatic hydrocarbon group and the C3-C36 saturated cyclic hydrocarbon group can be replaced by —O— or —CO—, with the proviso that the carbon atom bonded to —O— of —COO— of R^{a27} is not a tertiary carbon atom, or R^{a25} and R^{a26} are bonded together to form a carboxylic anhydride residue represented by —C(═O)OC(═O)—.

Examples of the substituent of the C1-C3 aliphatic hydrocarbon group include a hydroxyl group. Examples of the C1-C3 aliphatic hydrocarbon group which can have one or more substituents include a C1-C3 alkyl group such as a methyl group, an ethyl group and a propyl group, and a C1-C3 hydroxyalkyl group such a hydroxymethyl group and a 2-hydroxyethyl group. The C1-C36 aliphatic hydrocarbon group represented by R^{a27} is preferably a C1-C8 aliphatic hydrocarbon group and is more preferably a C1-C6 aliphatic hydrocarbon group. The C3-C36 saturated cyclic hydrocarbon group represented by R^{a27} is preferably a C4-C36 saturated cyclic hydrocarbon group, and is more preferably C4-C12 saturated cyclic hydrocarbon group. Examples of R^{a27} include a methyl group, an ethyl group, a propyl group, a 2-oxo-oxolan-3-yl group and a 2-oxo-oxolan-4-yl group.

Examples of the monomer represented by the formula (a-4-3) include 2-norbornene, 2-hydroxy-5-norbornene, 5-norbornene-2-carboxylic acid, methyl 5-norbornene-2-carboxylate, 2-hydroxyethyl 5-norbornene-2-carboxylate, 5-norbornene-2-methanol and 5-norbornene-2,3-dicarboxylic anhydride.

When the resin contains a structural unit derived from a monomer represented by the formula (a-4-1), (a-4-2) or (a-4-3), the content thereof is usually 2 to 40% by mole and preferably 3 to 30% by mole and more preferably 5 to 20% by mole based on total molar of all the structural units of the resin.

The resin preferably also contains a structural unit derived from each of the following monomers.

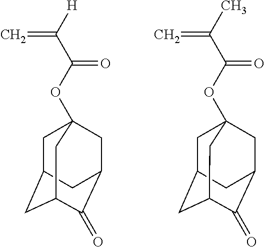

Preferable resin is a resin containing the structural units derived from the monomer having an acid-labile group, and the structural units derived from the monomer having one or more hydroxyl groups and/or the monomer having a lactone ring. The monomer having an acid-labile group is preferably the monomer represented by the formula (a1-1) or the monomer represented by the formula (a1-2), and is more preferably the monomer represented by the formula (a1-1). The monomer having one or more hydroxyl groups is preferably the monomer represented by the formula (a2-1), and the monomer having a lactone ring is preferably the monomer represented by the formula (a3-1) or (a3-2).

The resin can be produced according to known polymerization methods such as radical polymerization.

The resin usually has 2,500 or more of the weight-average molecular weight and preferably 3,000 or more of the weight-average molecular weight. The resin usually has 50,000 or less of the weight-average molecular weight and preferably has 30,000 or less of the weight-average molecular weight. The weight-average molecular weight can be measured with gel permeation chromatography.

The first photoresist composition used in the present invention usually includes 80% by weight or more of the resin based on sum of solid component. In this specification, “solid component” means components other than solvent in the photoresist composition.

Next, Component (b) will be illustrated.

The photoacid generator is a substance which is decomposed to generate an acid by applying a radiation such as a light, an electron beam or the like on the substance itself or on a photoresist composition containing the substance. The acid generated from the acid generator acts on the resin resulting in cleavage of the acid-labile group existing in the resin, and the resin becomes soluble in an aqueous alkali solution.

The photoacid generator may be nonionic or ionic. Examples of the nonionic photoacid generator include organic halides, sulfonate esters such as 2-nitrobenzyl ester, aromatic sulfonate, oxime sulfonate, N-sulfonyloxyimide, sulfonyloxyketone and DNQ 4-sulfonate, and sulfones such as disulfone, ketosulfone and sulfonyldiazomethane. Examples of the ionic photoacid generator include onium salts such as a diazonium salt, a phosphonium salt, a sulfonium salt and an iodonium salt, and examples of the anion of the onium salt include sulfonic acid anion, sulfonylimide anion and sulfonylmethide anion.

Other examples of the photoacid generator include photoacid generators described in JP 63-26653 A, JP 55-164824 A, JP 62-69263 A, JP 63-146038 A, JP 63-163452 A, JP 62-153853 A, JP 63-146029 A, U.S. Pat. No. 3,779,778, U.S. Pat. No. 3,849,137, DE Patent No. 3914407 and EP Patent No. 126,712.

A fluorine-containing photoacid generator is preferable.

Preferable examples of the acid generator include a salt represented by the formula (B1):

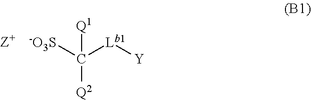

wherein Q¹ and Q² independently represent a fluorine atom or a C1-C6 perfluoroalkyl group,
L^{b1} represents a single bond or a C1-C17 saturated divalent hydrocarbon group which can have one or more substituents, and one or more —CH₂— in the saturated divalent hydrocarbon group can be replaced by —O— or —CO—,
Y represents a C1-C36 aliphatic hydrocarbon group or a C3-C36 saturated cyclic hydrocarbon group, and the aliphatic hydrocarbon group and the saturated cyclic hydrocarbon group can have one or more substituents, and one or more —CH₂— in the aliphatic hydrocarbon group and the saturated cyclic hydrocarbon group can be replaced by —O—, —CO— or —SO₂—, and
Z⁺ represents an organic cation.

Examples of the C1-C6 perfluoroalkyl group include a trifluoromethyl group, a pentafluoroethyl group, a heptafluoropropyl group, a nonafluorobutyl group, an undecafluoropentyl group and a tridecafluorohexyl group, and a trifluoromethyl group is preferable. Q¹ and Q² independently preferably represent a fluorine atom or a trifluoromethyl group, and Q¹ and Q² are more preferably fluorine atoms.

Examples of the C1-C17 saturated divalent hydrocarbon group include a C1-C17 alkylene group and a divalent group having an alicyclic divalent hydrocarbon group. Examples of the alkylene group include a linear alkanediyl group such as a methylene group, an ethylene group, a propane-1,3-diyl group, a butane-1,4-diyl group, a pentane-1,5-diyl, a hexane-1,6-diyl group, a heptane-1,7-diyl group, an octane-1,8-diyl group, a nonane-1,9-diyl group, a decane-1,10-diyl group, an undecane-1,11-diyl group, a dodecane-1,12-diyl group, a tridecane-1,13-diyl group, a tetradecane-1,14-diyl group, a pentadecane-1,15-diyl group, a hexadecane-1,16-diyl group and a heptadecane-1,17-diyl group, a branched chain alkanediyl group formed by replacing one or more hydrogen atom of the above-mentioned linear alkanediyl group by a C1-C4 alkyl group, and

a divalent group having an alicyclic divalent hydrocarbon group such as the following groups represented by the formulae (X¹-A) to (X¹-C):

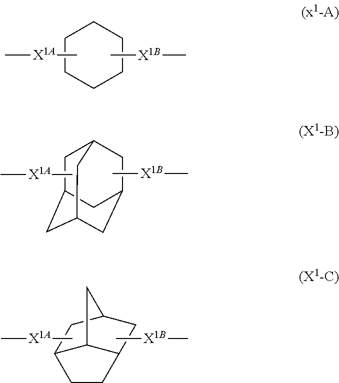

wherein X^{1A} and X^{1B} independently each represent a C1-C6 alkylene group which can have one or more substituents, with the proviso that total carbon number of the group represented by the formula (X¹-A), (X¹-B) or (X¹-C) is 1 to 17.

One or more —CH₂— in the C1-C6 alkylene group can be replaced by —O— or —CO—.

Examples of the C1-C17 saturated hydrocarbon group in which one or more —CH₂— are replaced by —O— or —CO— include *-CO—O-L^{b2}-, *-CO—O-L^{b4}-CO—O-L^{b3}-, *-L^{b5}-O—CO—, *-L^{b7}-O-L^{b6}-, *-CO—O-L^{b8}-O—, and *-CO—O-L^{b10}-O-L^{b9}-CO—O—, wherein L^{b2} represents a single bond or a C1-C15 alkanediyl group, L^{b3} represents a single bond or a C1-C12 alkanediyl group, L^{b4} represents a single bond or a C1-C13 alkanediyl group, with proviso that total carbon number of L^{b3} and L^{b4} is 1 to 13, L^{b5} represents a C1-C15 alkanediyl group, L^{b6} represents a C1-C15 alkanediyl group, L^{b7} represents a C1-C15 alkanediyl group, with proviso that total carbon number of L^{b6} and L^{b7} is 1 to 16, L^{b8} represents a C1-C14 alkanediyl group, L^{b9} represents a C1-C11 alkanediyl group, L^{b10} represents a C1-C11 alkanediyl group, with proviso that total carbon number of L^{b9} and L^{b10} is 1 to 12, and * represents a binding position to —C (Q¹)(Q²)-. Among them, preferred are *-CO—O-L^{b2}-, *-CO—O-L^{b4}-CO—O-L^{b3}-, *-L^{b5}-O—CO— and *-L^{b7}-O-L^{b6}-, and more preferred are *-CO—O-L^{b2}- and *-CO—O-L^{b4}-CO—O-L^{b3}-, and much more preferred is *-CO—O-L^{b2}-, and especially preferred is *-CO—O-L^{b2}- in which L^{b2} is a single bond or —CH₂—.

Examples of *-CO—O-L^{b2}- include *-CO—O— and *-CO—O—CH₂—. Examples of *-CO—O-L^{b4}-CO—O-L^{b3}- include *-CO—O—CH₂—CO—O—, *-CO—O—(CH₂)₂—CO—O—, *-CO—O—(CH₂)₃—CO—O—, *-CO—O—(CH₂)₄—CO—O— *-CO—O—(CH₂)₆—CO—O—, *-CO—O—(CH₂)₈—CO—O—, *-CO—O—CH₂—CH(CH₃)—CO—O— and *-CO—O—CH₂—C(CH₃)₂—CO—O—. Examples of *-L^{b5}-O—CO— include *-CH₂—O—CO—, *-(CH₂)₂—O—CO—, *-(CH₂)₃—O—CO—, *-(CH₂)₄—O—CO—, *-(CH₂)₆—O—CO— and *-(CH₂)₈—O—CO—. Examples of *-L^{b7}-O-L^{b6}- include *-CH₂—O—CH₂—. Examples of *-CO—O-L^{b8}-O— include *-CO—O—CH₂—O—, *-CO—O—(CH₂)₂—O—, *-CO—O—(CH₂)₃—O—, *-CO—O—(CH₂)₄—O— and *-CO—O—(CH₂)₆—O—. Examples of *-CO—O-L^{b10}-O-L^{b9}-CO—O— include the followings.

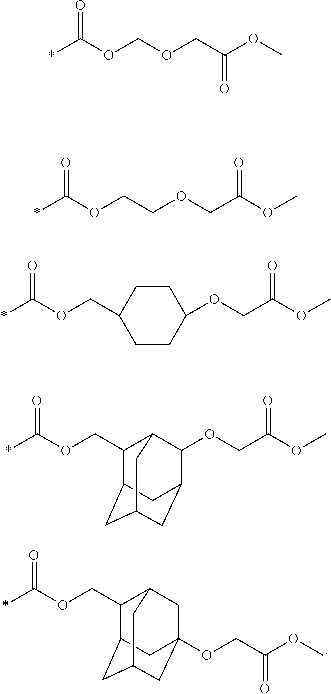

Examples of the substituent in Y include a halogen atom, a hydroxyl group, an oxo group, a glycidyloxy group, a C2-C4 acyl group, a C1-C12 alkoxy group, a C2-C7 alkoxycarbonyl group, a C1-C12 aliphatic hydrocarbon group, a C1-C12 hydroxy-containing aliphatic hydrocarbon group, a C3-C16 saturated cyclic hydrocarbon group, a C6-C18 aromatic hydrocarbon group, a C7-C21 aralkyl group and —(CH₂)ⱼ₂—O—CO—R^{b1}— in which R^{b1} represents a C1-C16 aliphatic hydrocarbon group, a C3-C16 saturated cyclic hydrocarbon group or a C6-C18 aromatic hydrocarbon group and j2 represents an integer of 0 to 4. Examples of the halogen atom include a fluorine atom, a chlorine atom, a bromine atom and an iodine atom. Examples of the acyl group include an acetyl group and a propionyl group, and examples of the alkoxy group include a methoxy group, an ethoxy group, a propoxy group, an isopropoxy group and a butoxy group. Examples of the alkoxycarbonyl group include a methoxycarbonyl group, an ethoxycarbonyl group, a propoxycarbonyl group, an isopropoxycarbonyl group and a butoxycarbonyl group. Examples of the aliphatic hydrocarbon group include the same as described above. Examples of the hydroxyl-containing aliphatic hydrocarbon group include a hydroxymethyl group. Examples of the C3-C16 saturated cyclic hydrocarbon group include the same as described above, and examples of the aromatic hydrocarbon group include a phenyl group, a naphthyl group, an anthryl group, a p-methylphenyl group, a p-tert-butylphenyl group and a p-adamantylphenyl group. Examples of the aralkyl group include a benzyl group, a phenethyl group, a phenylpropyl group, a trityl group, a naphthylmethyl group and a naphthylethyl group.

Examples of the C1-C36 aliphatic hydrocarbon group represented by Y include a methyl group, an ethyl group, a propyl group, an isopropyl group, a butyl group, an isobutyl group, a sec-butyl group, a tert-butyl group, a pentyl group, a neopentyl group, a 1-methylbutyl group, a 2-methylbutyl group, a 1,2-dimethylpropyl group, a 1-ethylpropyl group, a hexyl group, a 1-methylpentyl group, a heptyl group, an octyl group, a 2-ethylhexyl group, a nonyl group, a decyl group, an undecyl group and a dodecyl group, and a C1-C6 alkyl group is preferable. Examples of the C3-C36 saturated cyclic hydrocarbon group represented by Y include the groups represented by the formulae (Y1) to (Y26):

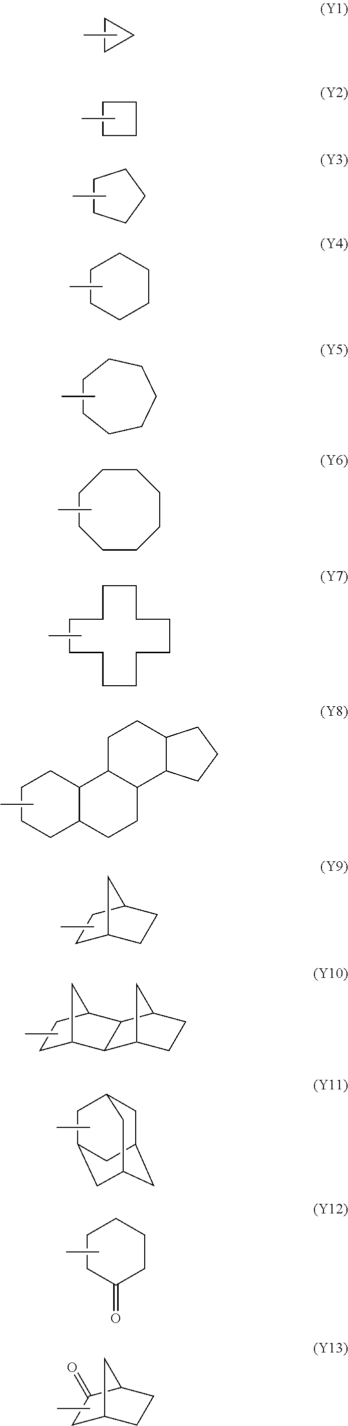

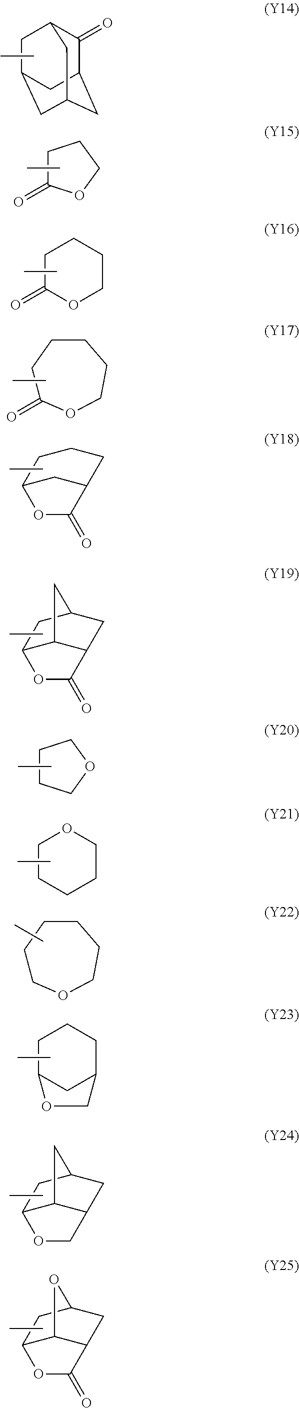

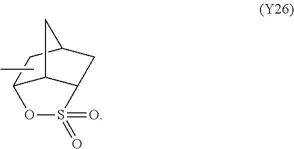

Among them, preferred are the groups represented by the formulae (Y1) to (Y19), and more preferred are the groups represented by the formulae (Y11), (Y14), (Y15) and (Y19). The groups represented by the formulae (Y11) and (Y14) are especially preferable.

Examples of Y having one or more substituents include the followings:

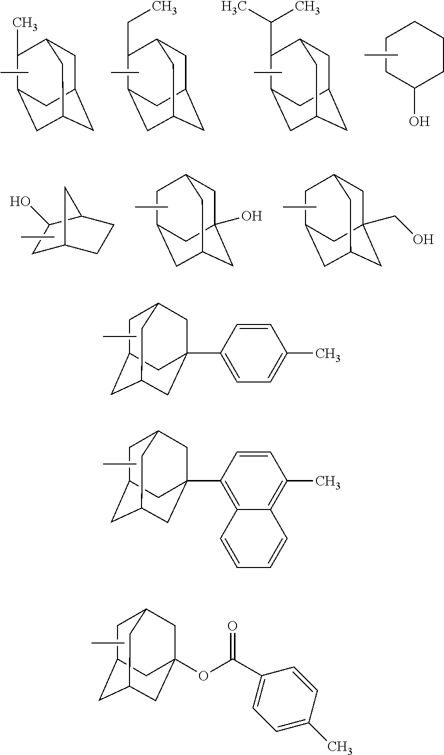

Y is preferably an adamantyl group which can have one or more substituents, and is more preferably an adamantyl group or an oxoadamantyl group.

Among the sulfonic acid anions of the salt represented by the formula (B1), preferred is a sulfonic acid anion in which L^{b1} is *-CO—O-L^{b2}-, and more preferred are anions represented by the formulae (b1-1-1) to (b1-1-9).

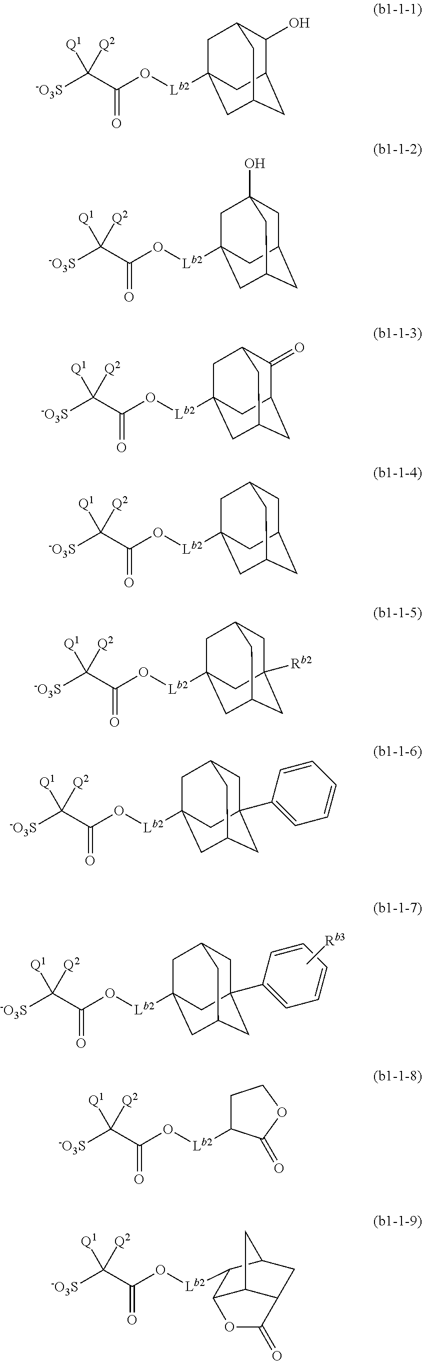

wherein Q¹, Q² and L^{b2} are the same as defined above, and R^{b2} and R^{b3} each independently represent a C1-C4 aliphatic hydrocarbon group, preferably a methyl group.

Examples of the anions of the salt represented by the formula (B1) include the followings.

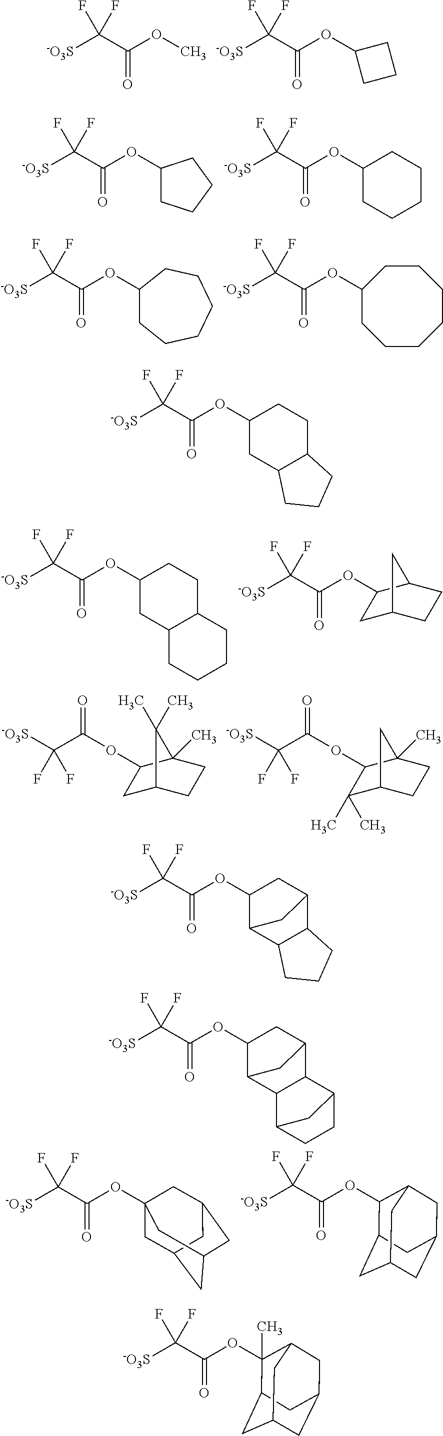

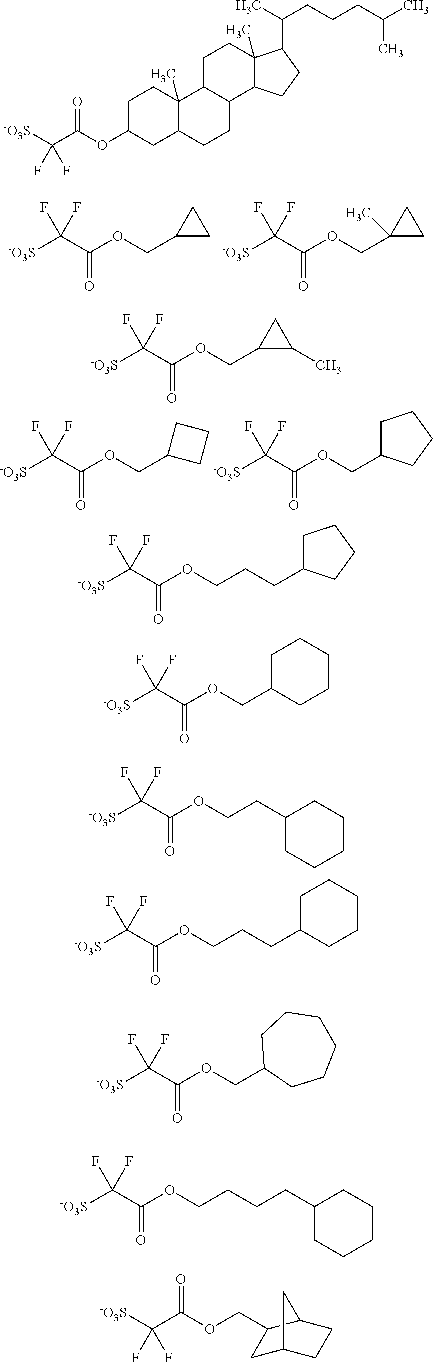

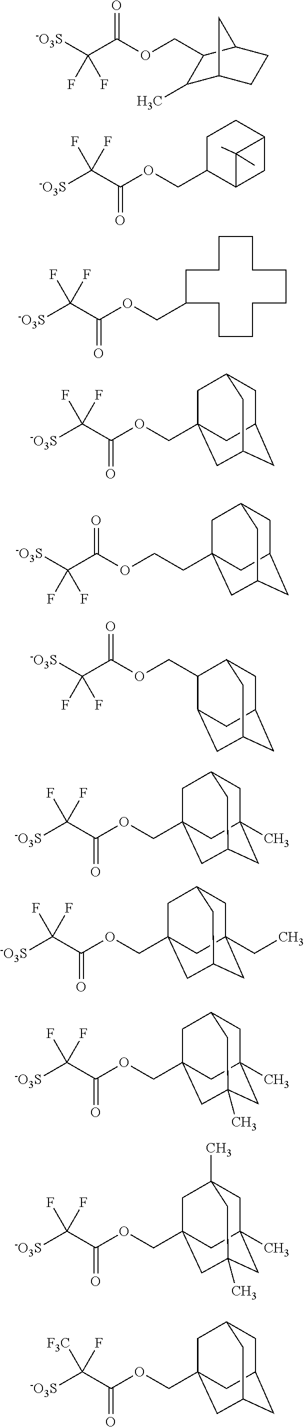

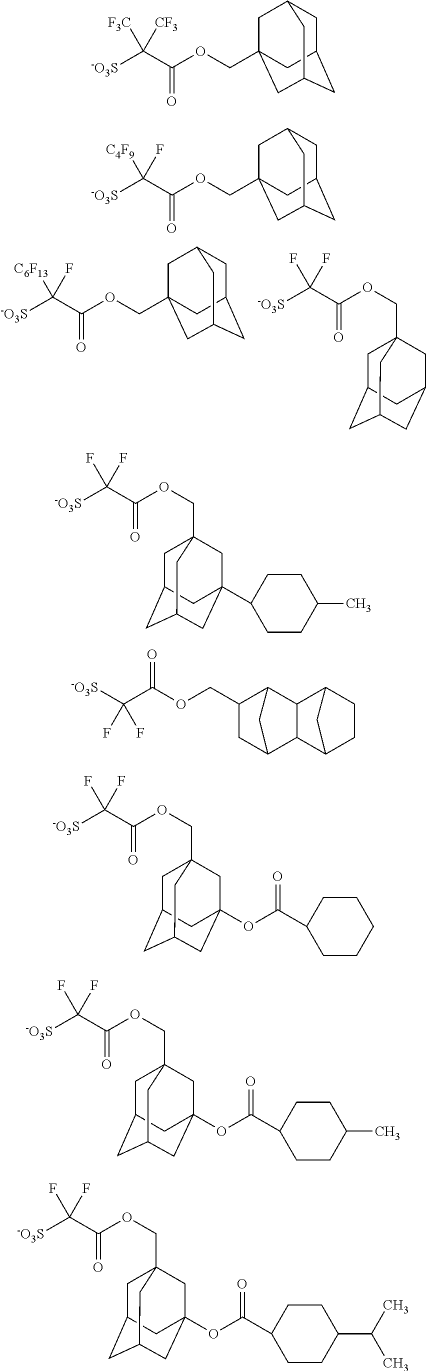

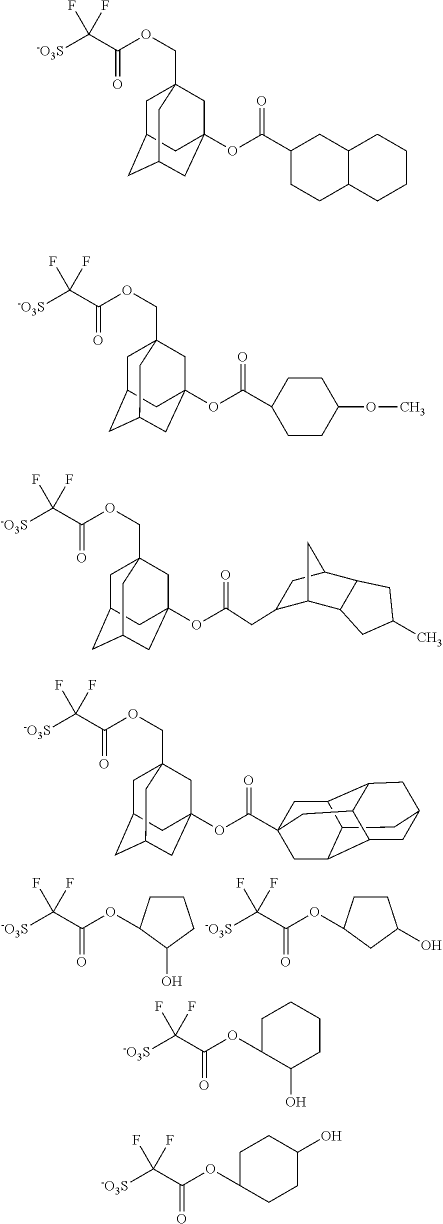

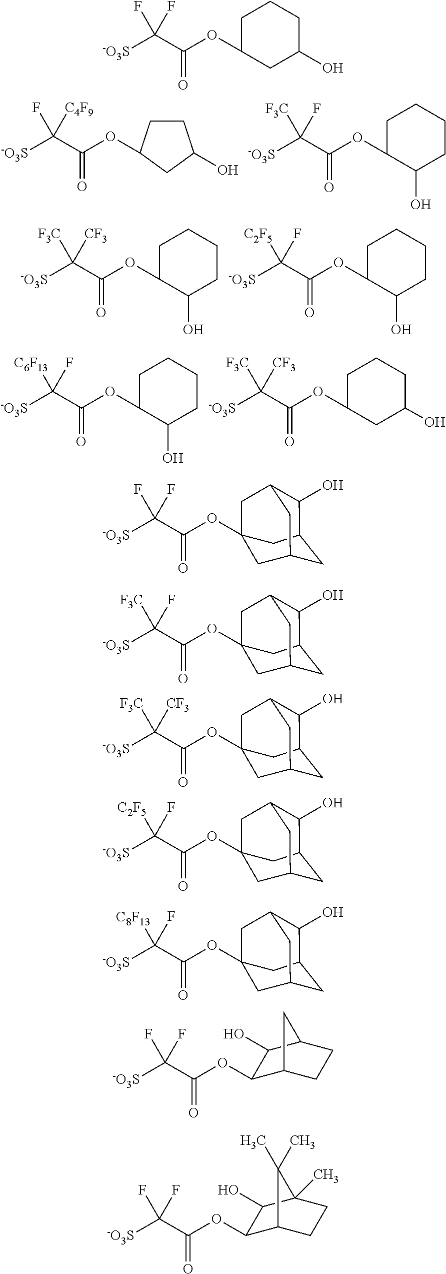

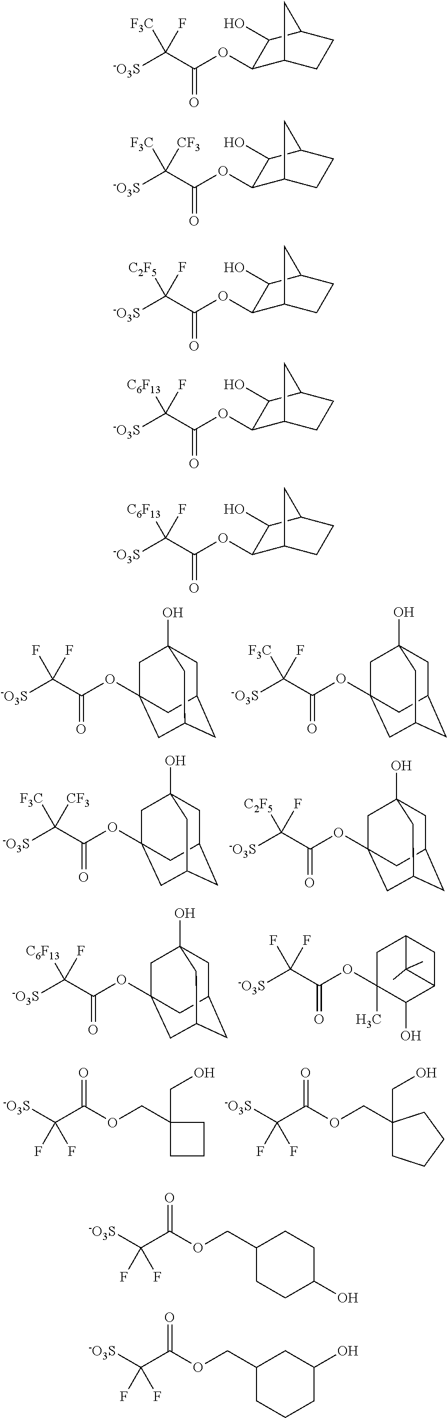

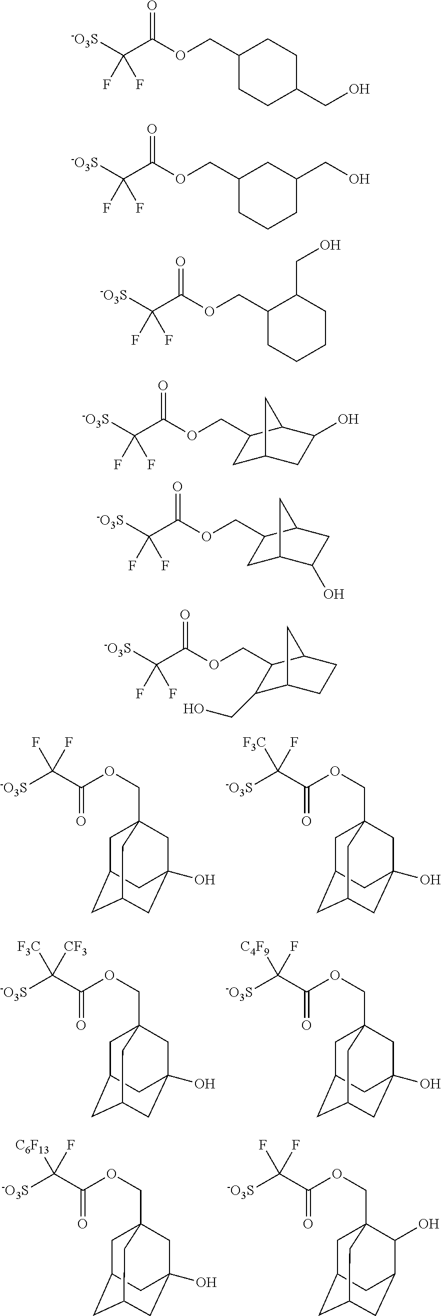

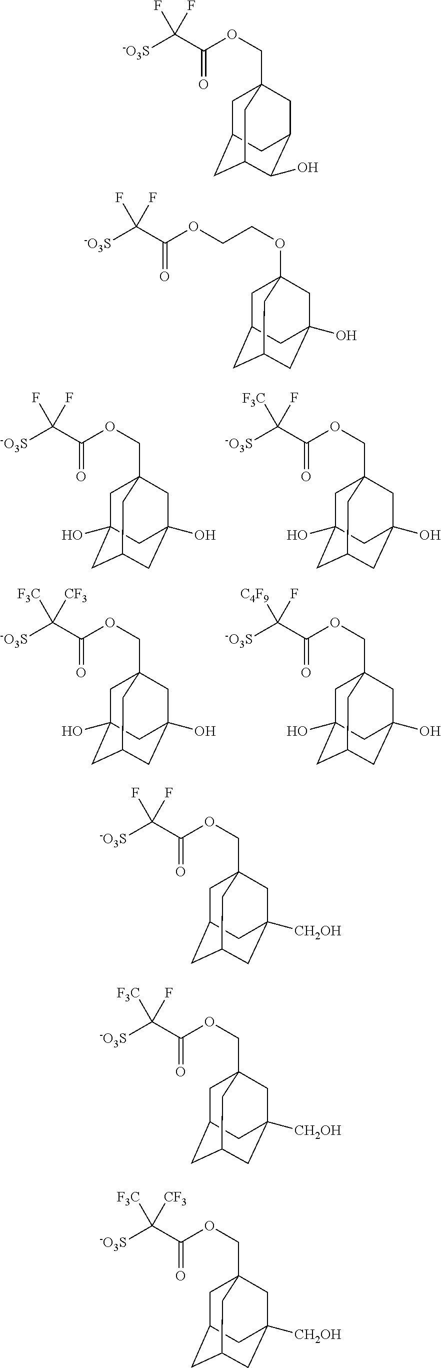

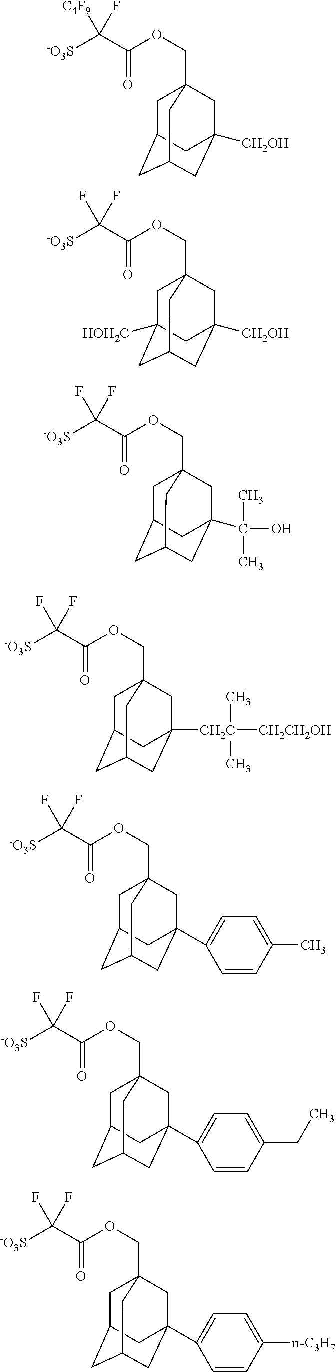

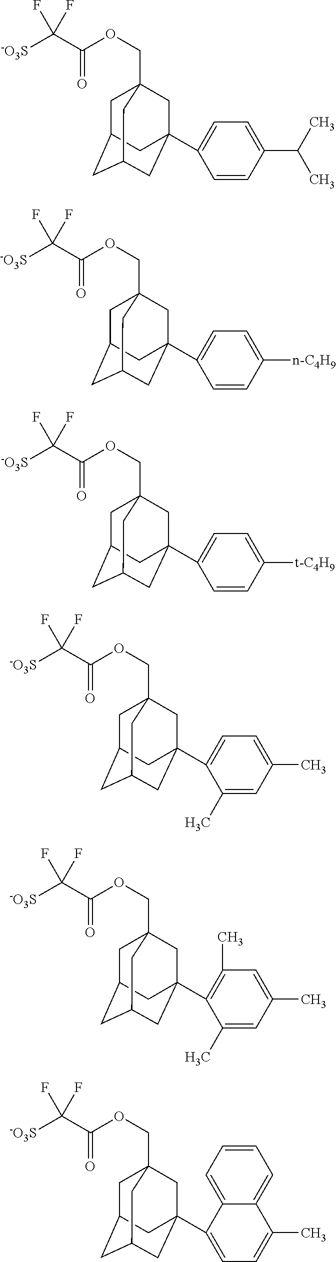

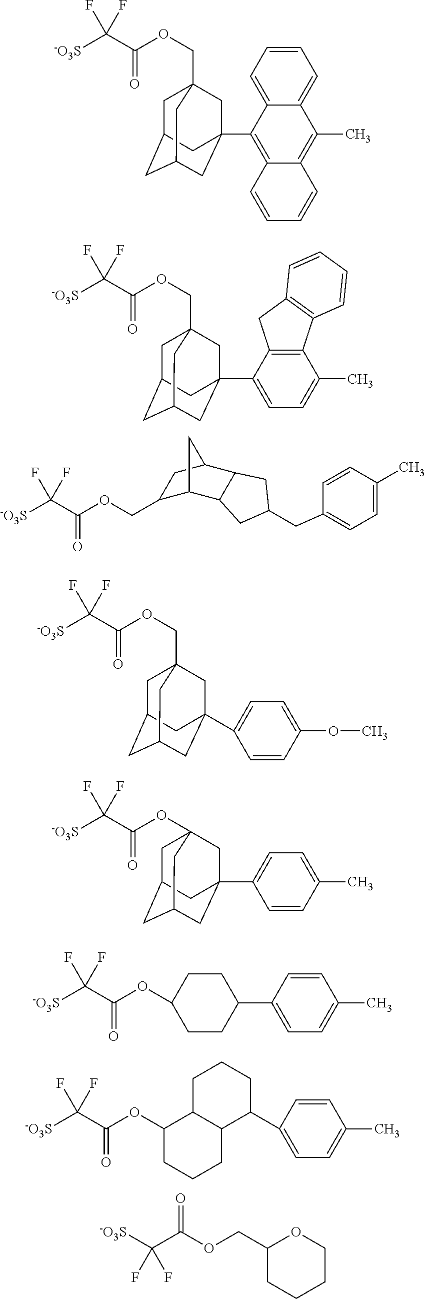

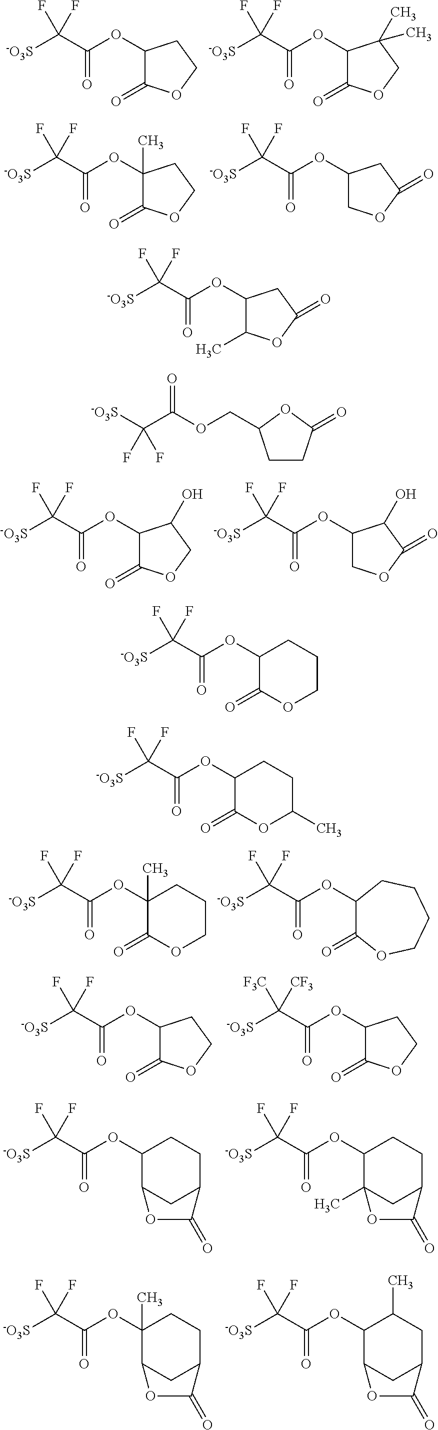

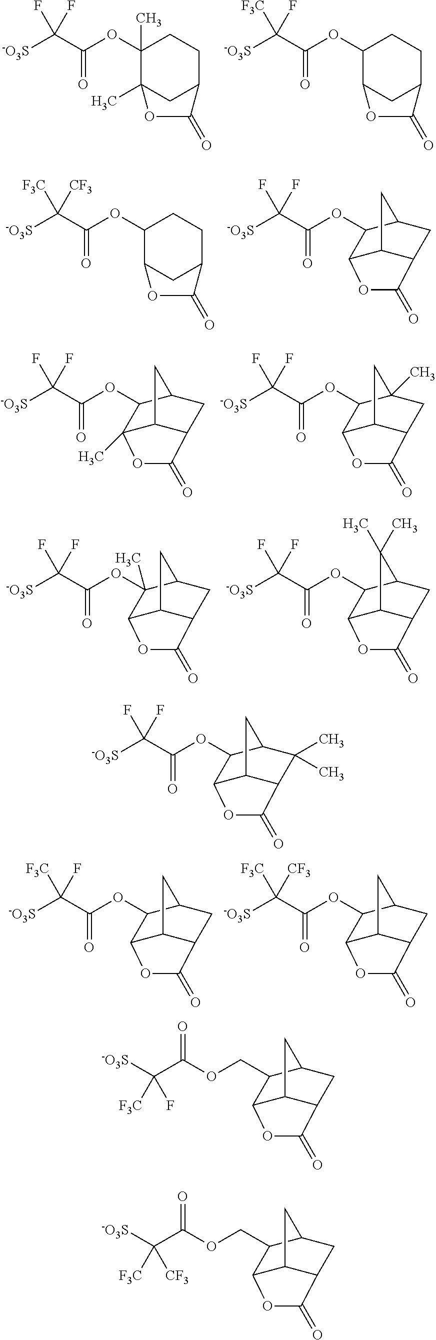

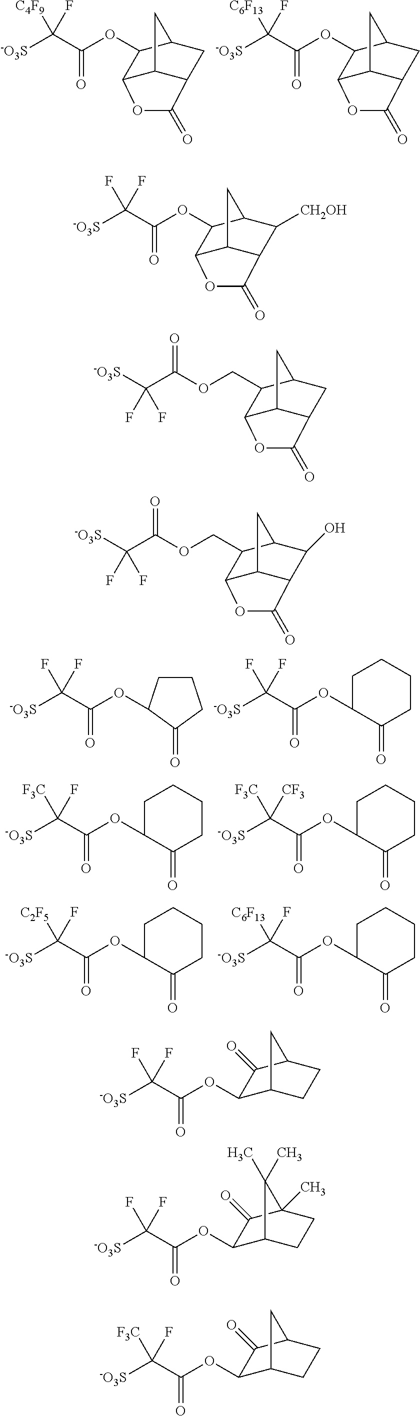

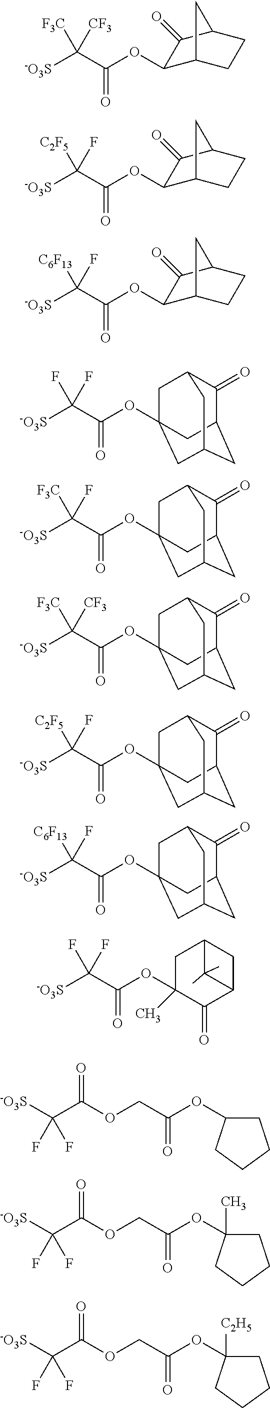

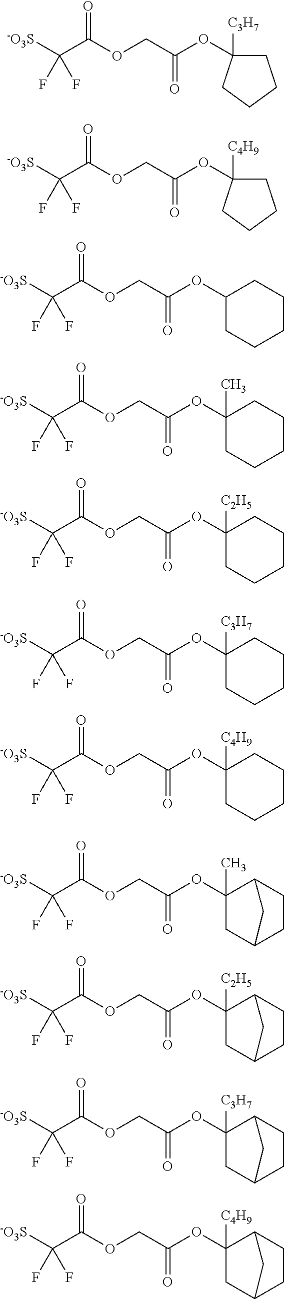

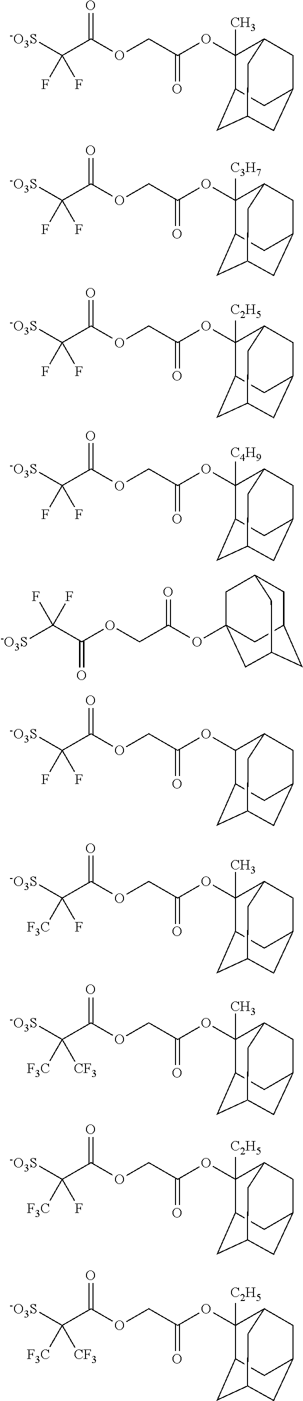

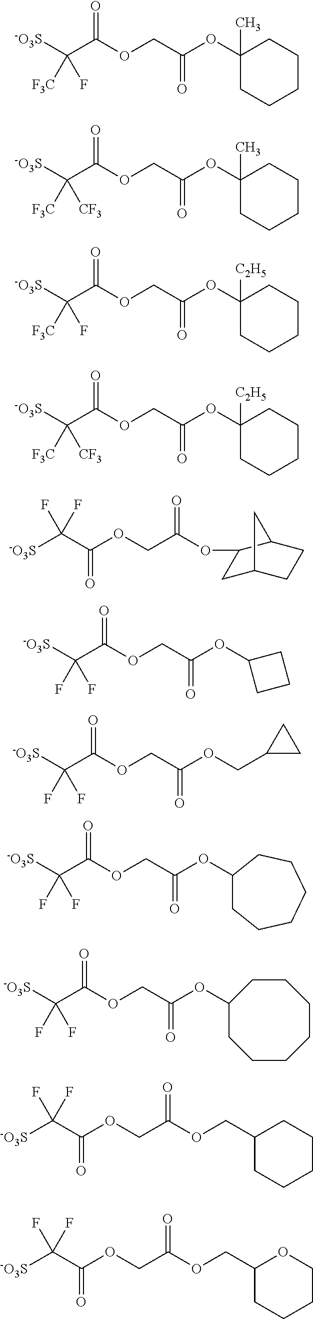

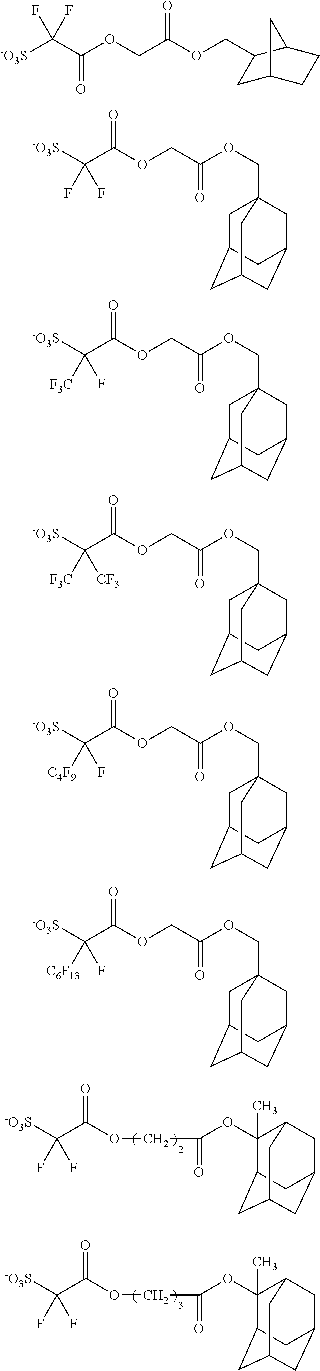

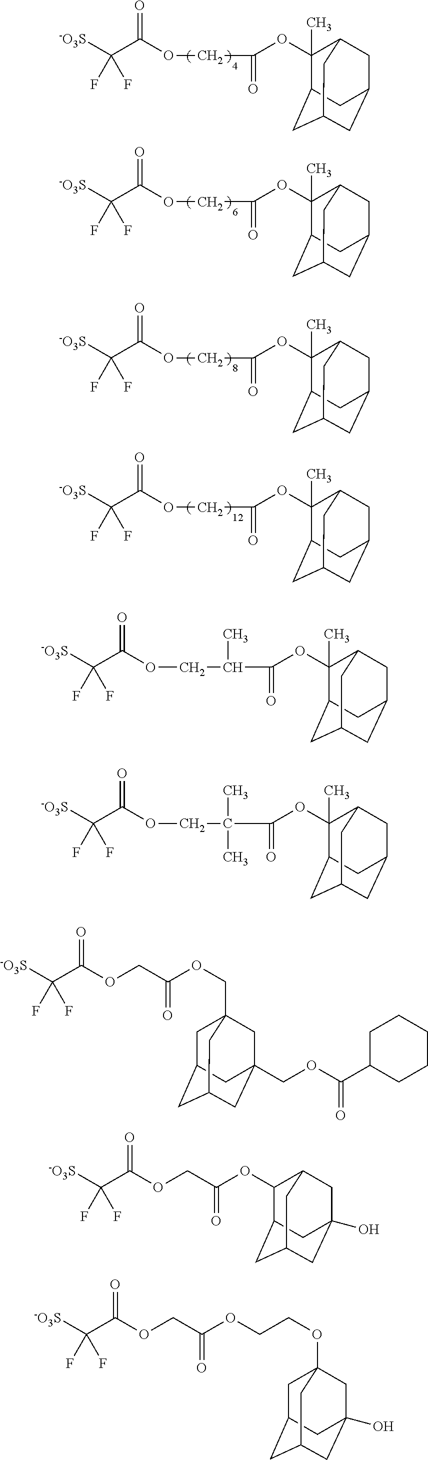

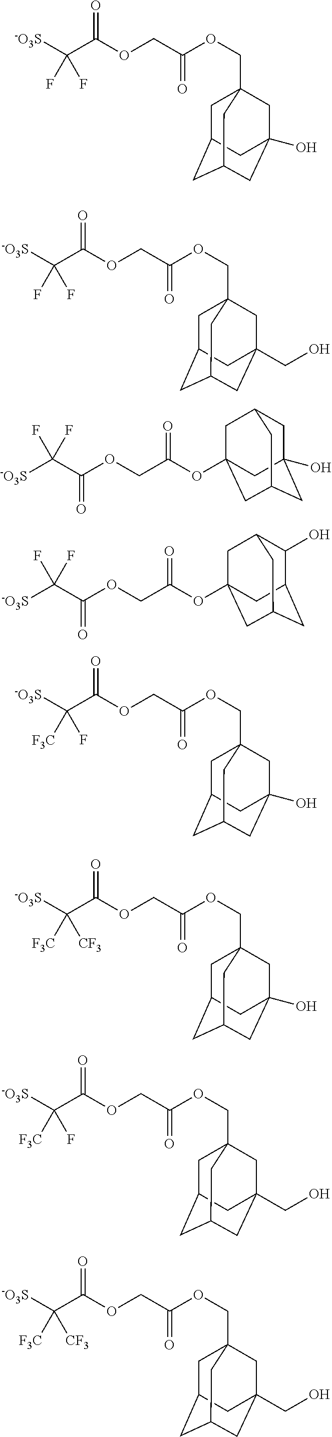

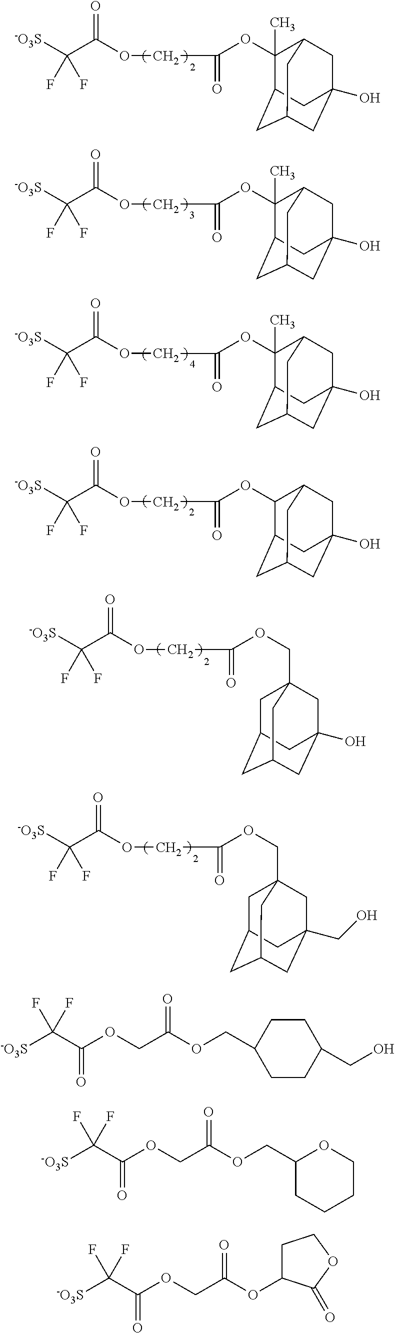

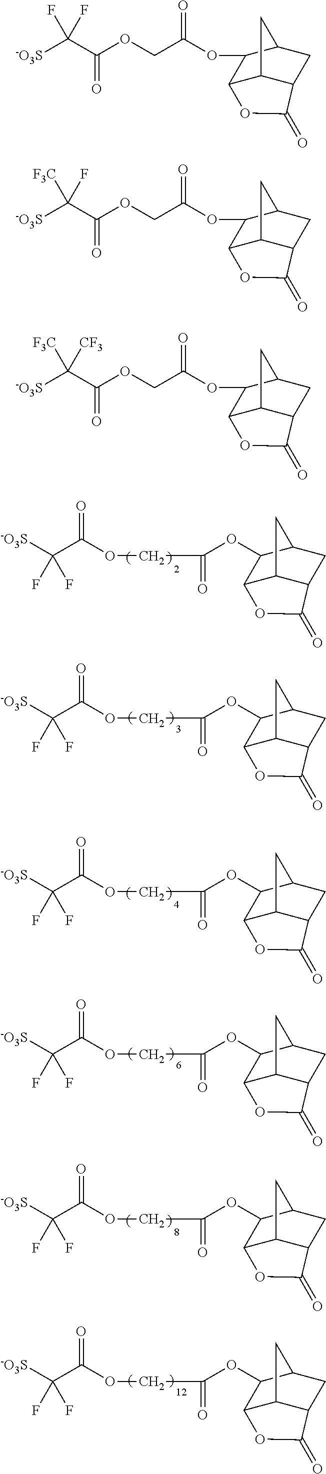

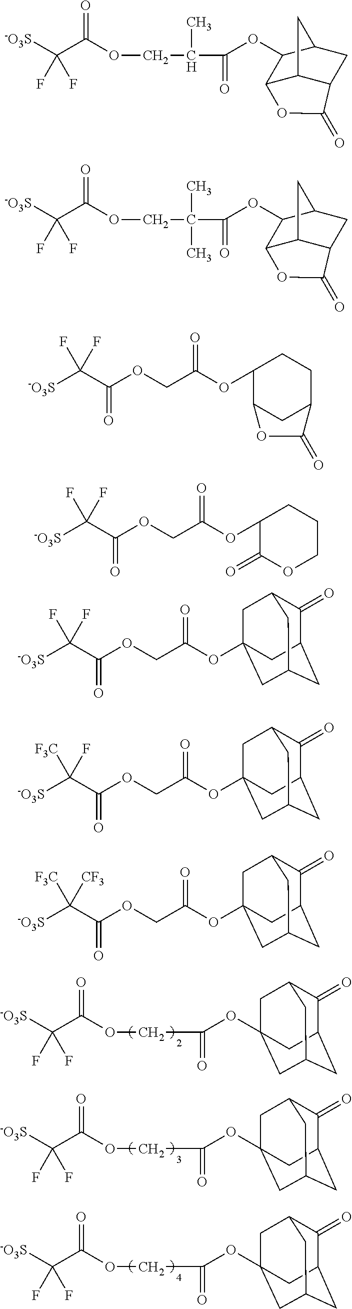

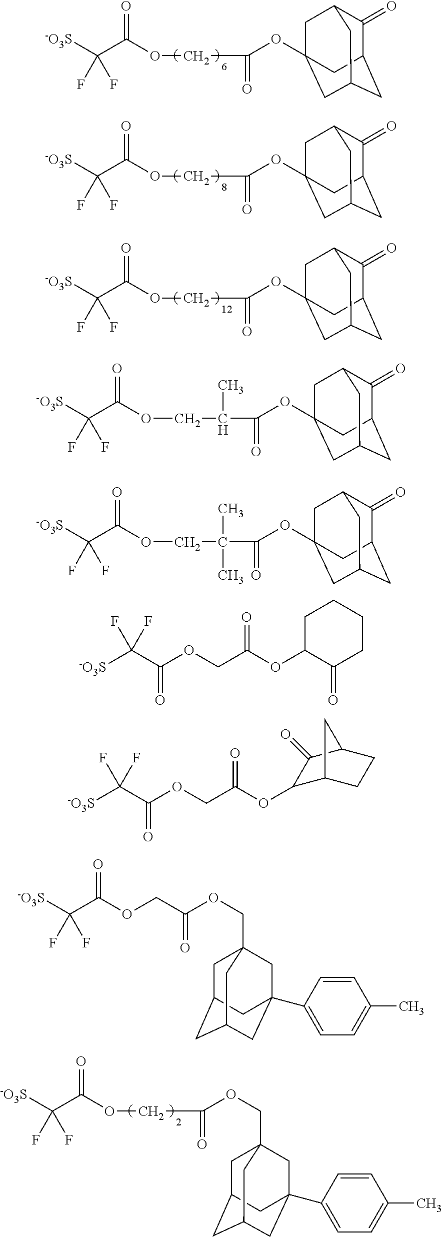

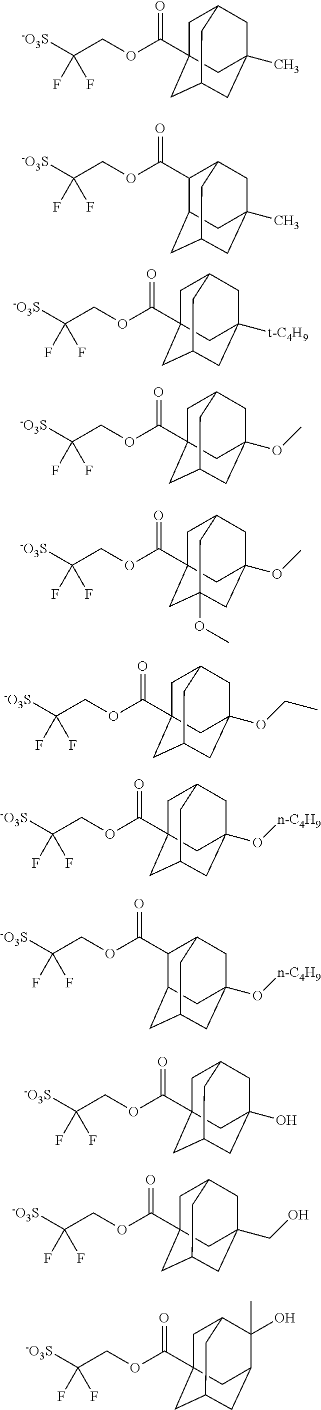

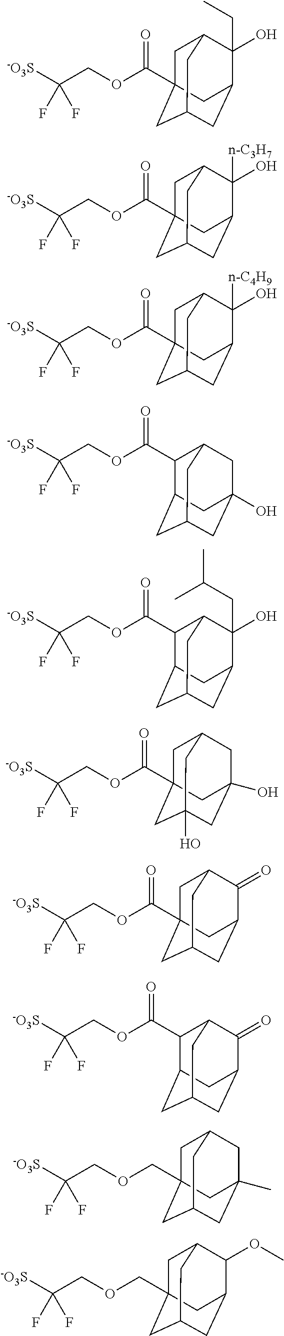

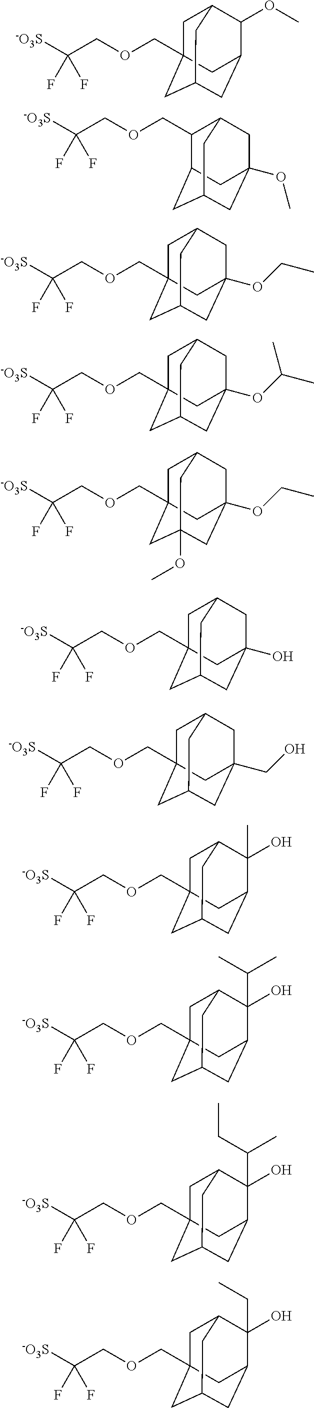

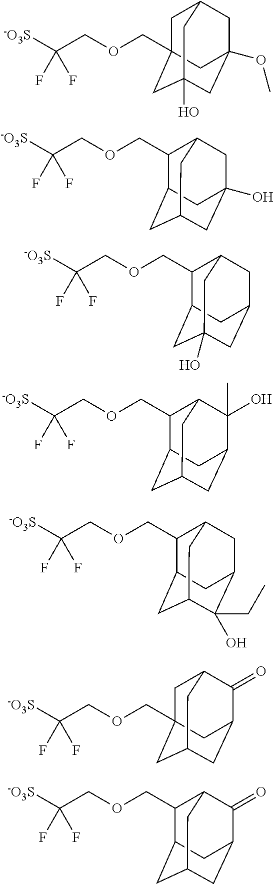

Among them, preferred are the following sulfonic anions.

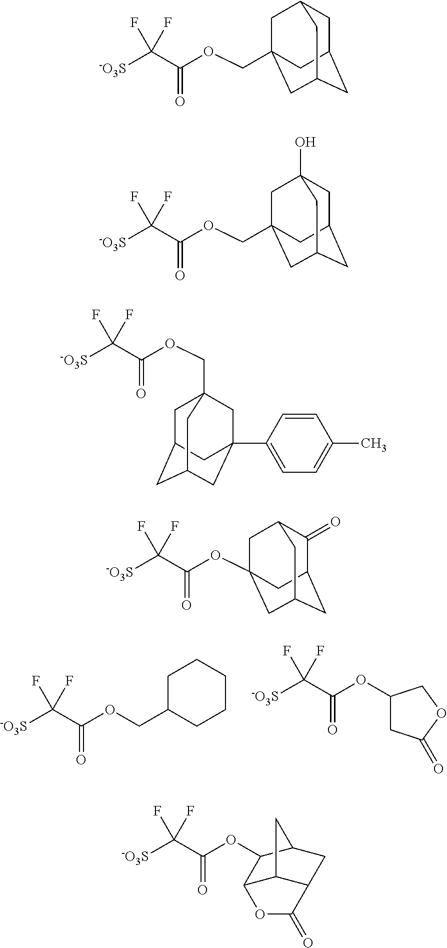

Examples of the organic counter ion represented by Z⁺ in the salt represented by the formula (B1) include an onium cation such as a sulfonium cation, an iodonium cation, an ammonium cation, a benzothiazolium cation and a phosphonium cation, and a sulfonium cation and an iodonium cation are preferable, and an arylsulfonium cation is more preferable.

Preferable examples of the cation part represented by Z⁺ include the cations represented by the formulae (b2-1) to (b2-4):

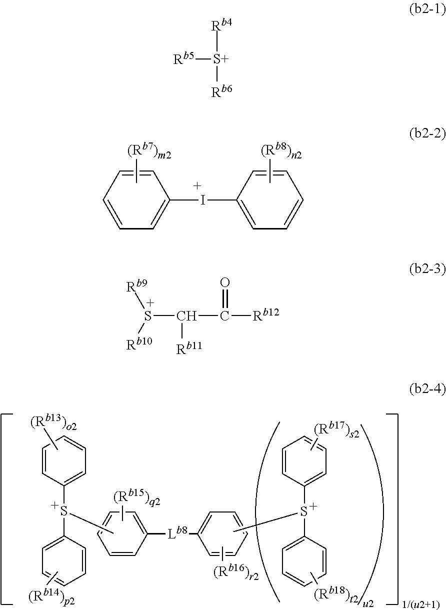

wherein R^{b4}, R^{b5} and R^{b6} each independently represent a C1-C30 aliphatic hydrocarbon group which can have one or more substituents selected from the group consisting of a hydroxyl group, a C1-C12 alkoxy group and a C6-C18 aromatic hydrocarbon group, a C3-C36 saturated cyclic hydrocarbon group which can have one or more substituents selected from the group consisting of a halogen atom, a C2-C4 acyl group and a glycidyloxy group, or a C6-C18 aromatic hydrocarbon group which can have one or more substituents selected from the group consisting of a halogen atom, a hydroxyl group, a C1-C36 aliphatic hydrocarbon group, a C3-C36 saturated cyclic hydrocarbon group or a C1-C12 alkoxy group,
R^{b7} and R^{b8} are independently in each occurrence a hydroxyl group, a C1-C12 aliphatic hydrocarbon group or a C1-C12 alkoxy group, m2 and n2 independently represents an integer of 0 to 5,
R^{b9} and R^{b10} each independently represent a C1-C36 aliphatic hydrocarbon group or a C3-C36 saturated cyclic hydrocarbon group, or R^{b9} and R^{b10} are bonded to form a C2-C11 divalent acyclic hydrocarbon group which forms a ring together with the adjacent S⁺, and one or more —CH₂— in the divalent acyclic hydrocarbon group may be replaced by —CO—, —O— or —S—,
and
R^{b11} represents a hydrogen atom, a C1-C36 aliphatic hydrocarbon group, a C3-C36 saturated cyclic hydrocarbon group or a C6-C18 aromatic hydrocarbon group, R^{b12} represents a C1-C12 aliphatic hydrocarbon group, a C3-C18 saturated cyclic hydrocarbon group or a C6-C18 aromatic hydrocarbon group and the aromatic hydrocarbon group can have one or more substituents selected from the group consisting of a C1-C12 aliphatic hydrocarbon group, a C1-C12 alkoxy group, a C3-C18 saturated cyclic hydrocarbon group and an acyloxy group, or R^{b11} and R^{b12} are bonded each other to form a C1-C10 divalent acyclic hydrocarbon group which forms a 2-oxocycloalkyl group together with the adjacent —CHCO—, and one or more —CH₂— in the divalent acyclic hydrocarbon group may be replaced by —CO—, —O— or —S—, and
R^{b13}, R^{b14}, R^{b15}, R^{b16}, R^{b17} and R^{b18} each independently represent a hydroxyl group, a C1-C12 aliphatic hydrocarbon group or a C1-C12 alkoxy group, L^{b11} represents —S— or —O— and o2, p2, s2 and t2 each independently represents an integer of 0 to 5, q2 and r2 each independently represents an integer of 0 to 4, and u2 represents 0 or 1.

The aliphatic hydrocarbon group represented by R^{b9} to R^{b11} has preferably 1 to 12 carbon atoms. The saturated cyclic hydrocarbon group represented by R^{b9} to R^{b11} has preferably 3 to 36 carbon atoms and more preferably 4 to 12 carbon atoms.

Examples of the aliphatic hydrocarbon group and the aromatic hydrocarbon group include the same as described above. Preferable examples of the aliphatic hydrocarbon group include a methyl group, an ethyl group, a propyl group, an isopropyl group, a butyl group, a sec-butyl group, a tert-butyl group, a pentyl group, a hexyl group, an octyl group and a 2-ethylhexyl group. A C4-C12 cyclic aliphatic hydrocarbon group is preferable. Preferable examples of the cyclic aliphatic hydrocarbon group include a cyclopropyl group, a cyclobutyl group, a cyclopentyl group, a cyclohexyl group, a cycloheptyl group, a cyclodecyl group, a 2-alkyl-a-adamantyl group, a 1-(1-adamantyl)-1-alkyl group and an isobornyl group. Preferable examples of the aromatic group include a phenyl group, a 4-methylphenyl group, a 4-ethylphenyl group, a 4-tert-butylphenyl group, a 4-cyclohexylphenyl group, a 4-methoxyphenyl group, a biphenyl group and a naphthyl group. Examples of the aliphatic hydrocarbon group having an aromatic hydrocarbon group include a benzyl group. Examples of the alkoxy group include a methoxy group, an ethoxy group, a propoxy group, an isopropoxy group, a butoxy group, a sec-butoxy group, a tert-butoxy group, a pentyloxy group, a hexyloxy group, a heptyloxy group, an octyloxy group, a 2-ethylhexyloxy group, a nonyloxy group, a decyloxy group, an undecyloxy group and a dodecyloxy group.

Examples of the C3-C12 divalent acyclic hydrocarbon group formed by bonding R^{b9} and R^{b10} include a trimethylene group, a tetramethylene group and a pentamethylene group. Examples of the ring group formed together with the adjacent S⁺ and the divalent acyclic hydrocarbon group include a thiolan-1-ium ring (tetrahydrothiphenium ring), a thian-1-ium ring and a 1,4-oxathian-4-iumring. A C3-C7 divalent a cyclic hydrocarbon group is preferable.

Examples of the C1-C10 divalent acyclic hydrocarbon group formed by bonding R^{b11} and R^{b12} include a methylene group, an ethylene group, a trimethylene group, a tetramethylene group and a pentamethylene group and examples of the ring group include the followings.

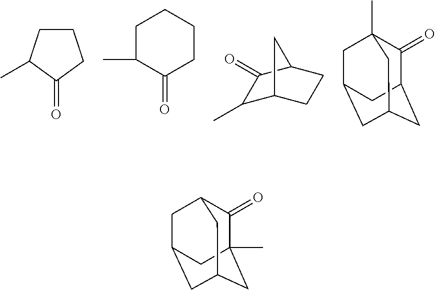

A C1-C5 divalent acyclic hydrocarbon group is preferable.

Among the above-mentioned cations, preferred is the cation represented by the formula (b2-1), and more preferred is the cation represented by the formula (b2-1-1). A triphenylsulfonium cation is especially preferable.

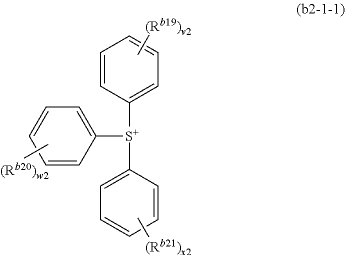

wherein R^{b19}, R^{b20} and R^{b21} are independently in each occurrence a halogen atom, a hydroxyl group, a C1-C36 aliphatic hydrocarbon group, a C3-C36 saturated cyclic hydrocarbon group or a C1-C12 alkoxy group, and one or more hydrogen atoms of the aliphatic hydrocarbon group can be replaced by a hydroxyl group, a C1-C12 alkoxy group or a C6-C18 aromatic hydrocarbon group, and one or more hydrogen atoms of the saturated cyclic hydrocarbon group can be replaced by a halogen atom, a glycidyloxy group or a C2-C4 acyl group, and v2, w2 and x2 independently each represent an integer of 0 to 5.

The aliphatic hydrocarbon group has preferably 1 to 12 carbon atoms, and the saturated cyclic hydrocarbon group has preferably 4 to 36 carbon atoms, and v2, w2 and x2 independently each preferably represent 0 or 1.

It is preferred that R^{b19}, R^{b20} and R^{b21} are independently in each occurrence a halogen atom, a hydroxyl group, a C1-C12 alkyl group or a C1-C12 alkoxy group and v2, w2 and x2 independently each represent an integer of 0 to 5, and it is more preferred that R^{b19}, R^{b20} and R^{b21} are independently in each occurrence a fluorine atom, a hydroxyl group, a C1-C12 alkyl group or a C1-C12 alkoxy group, and v2, w2 and x2 independently each preferably represent 0 or 1.

Examples of the cation represented by the formula (b2-1) include the followings.

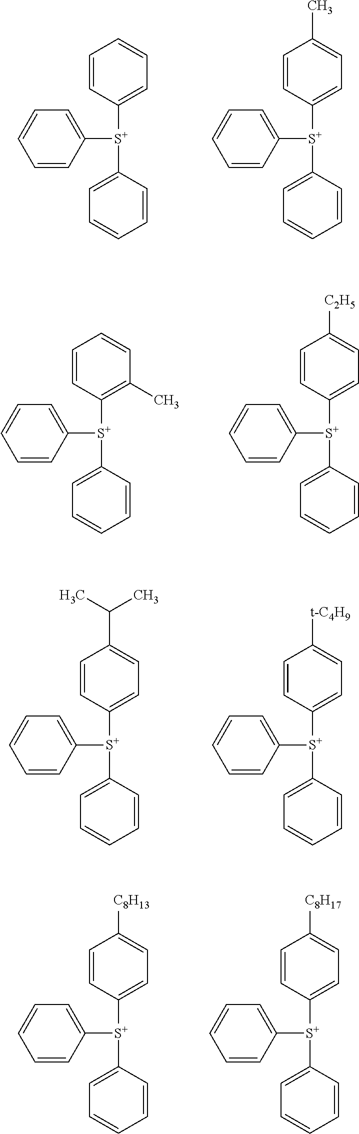

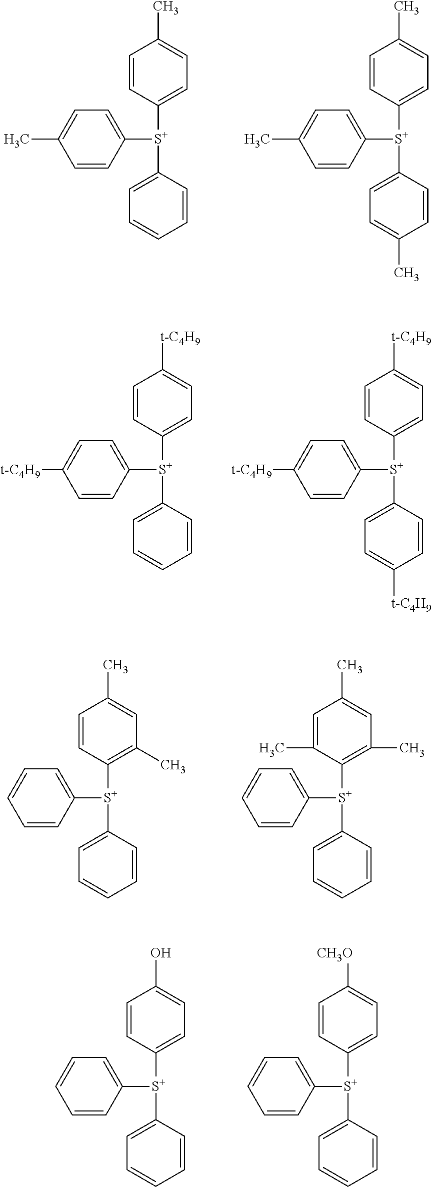

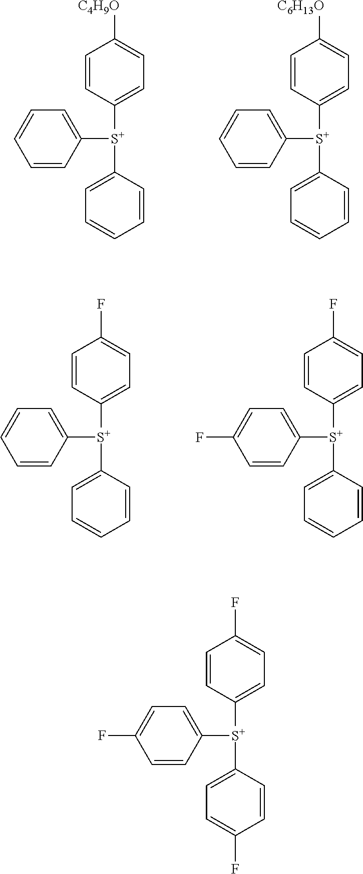

Examples of the cation represented by the formula (b2-2) include the followings.

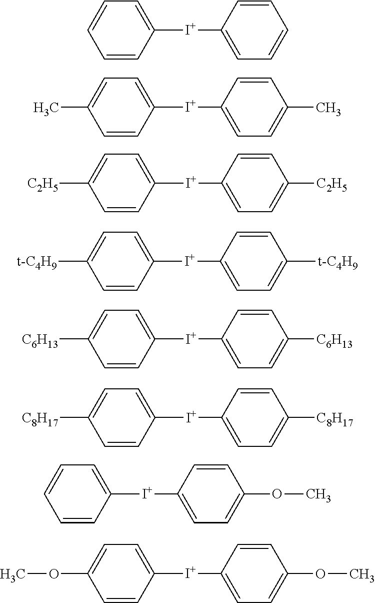

Examples of the cation represented by the formula (b2-3) include the followings.

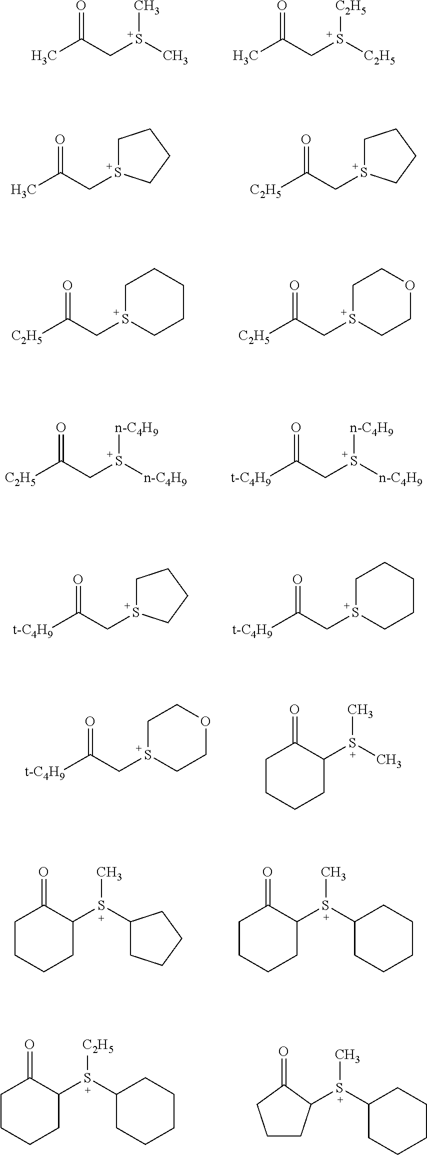

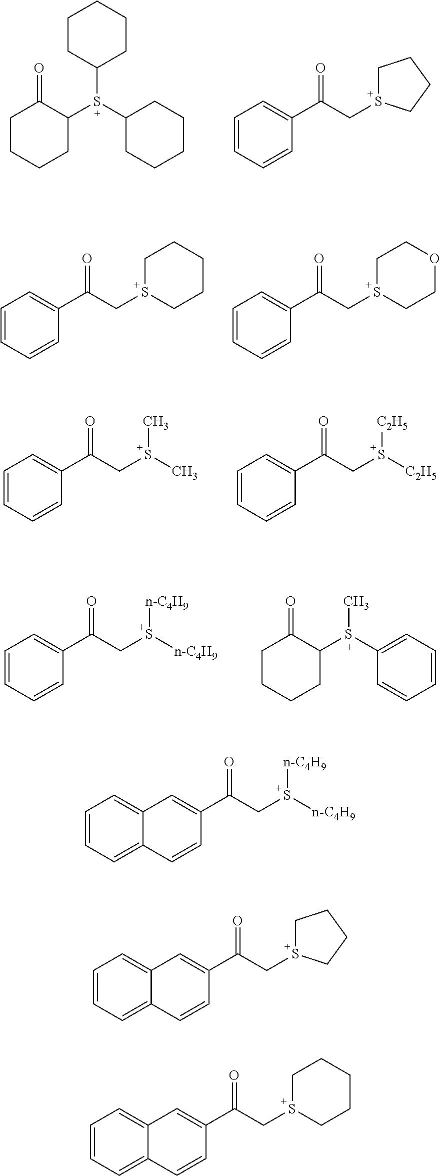

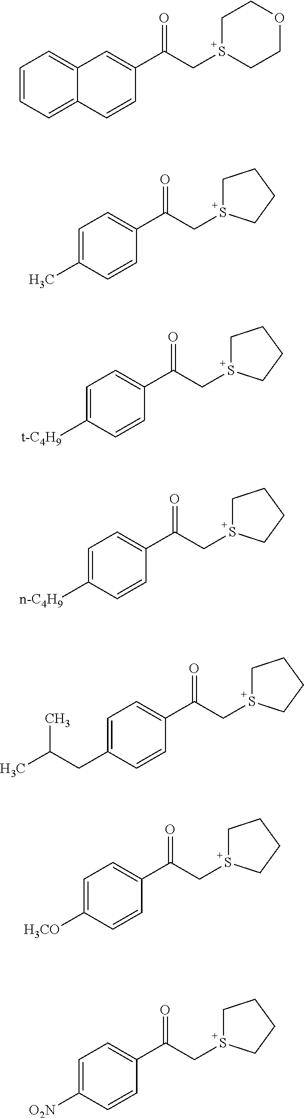

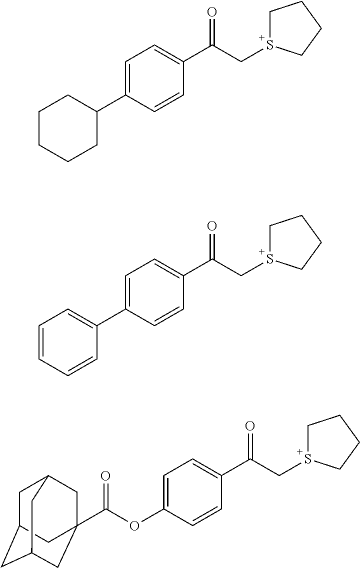

Examples of the cation represented by the formula (b2-4) include the followings.

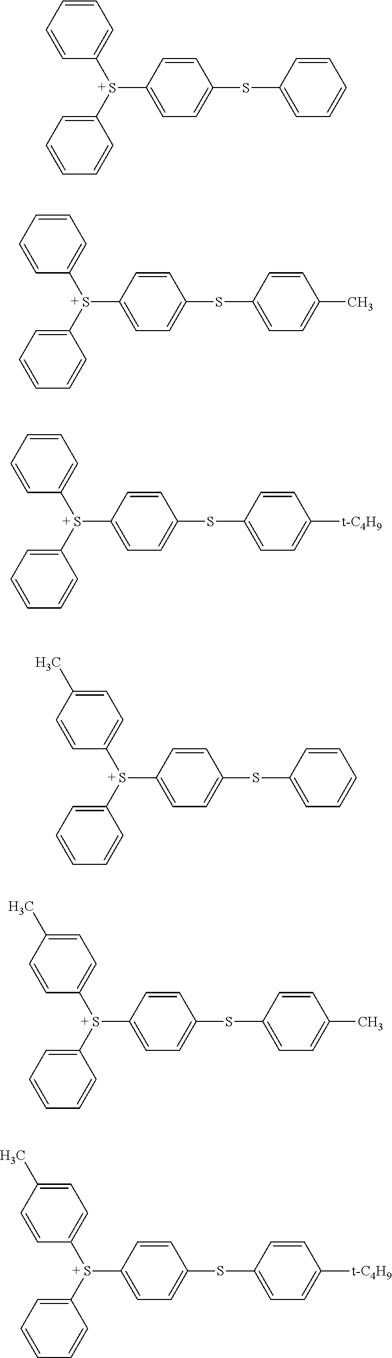

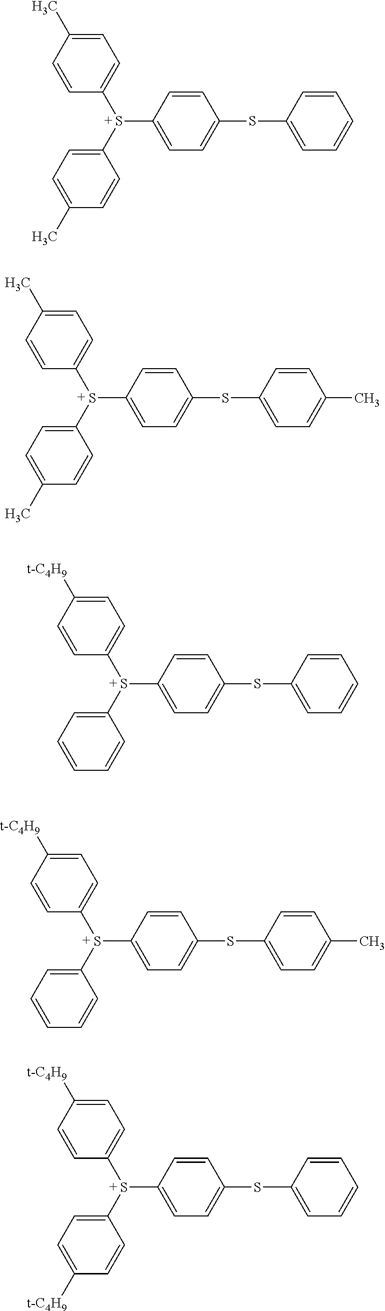

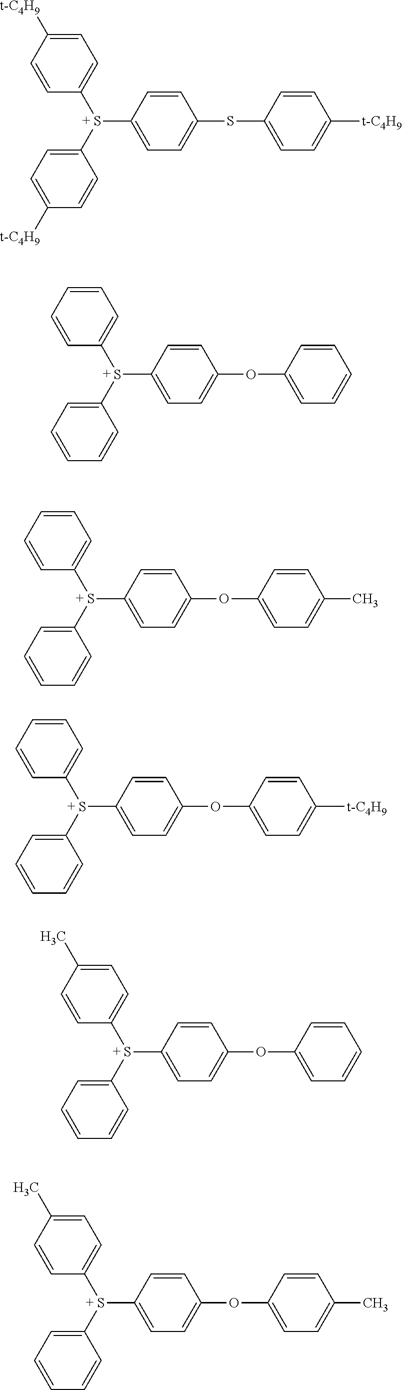

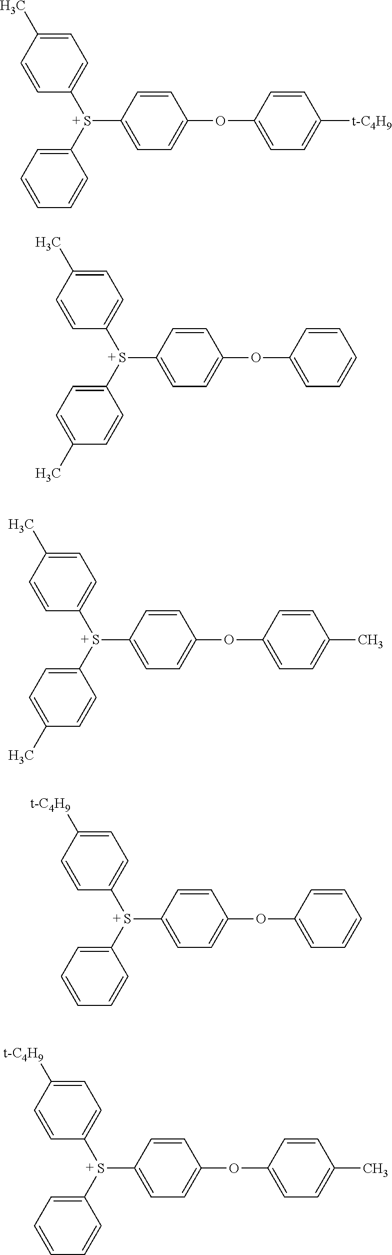

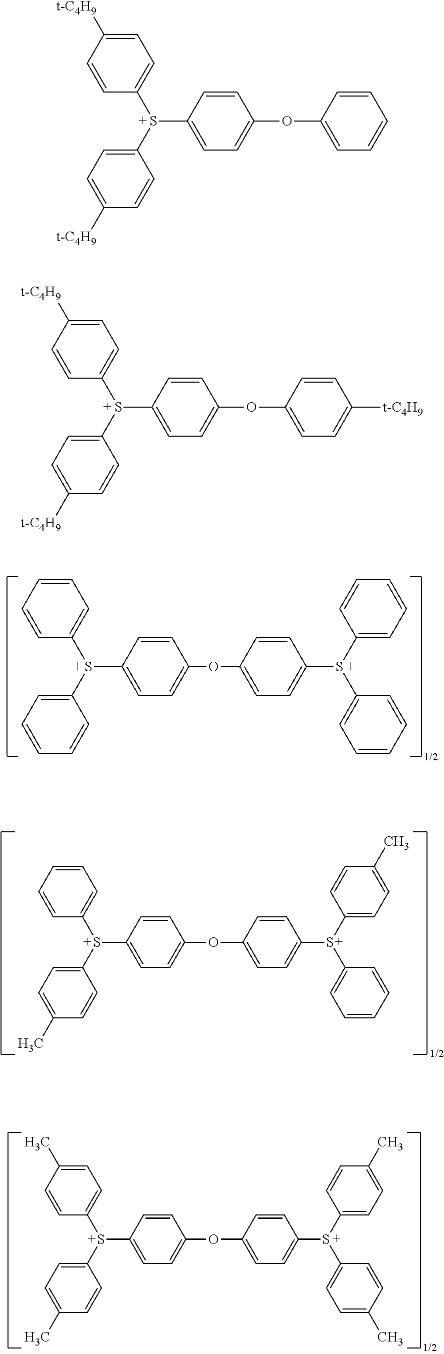

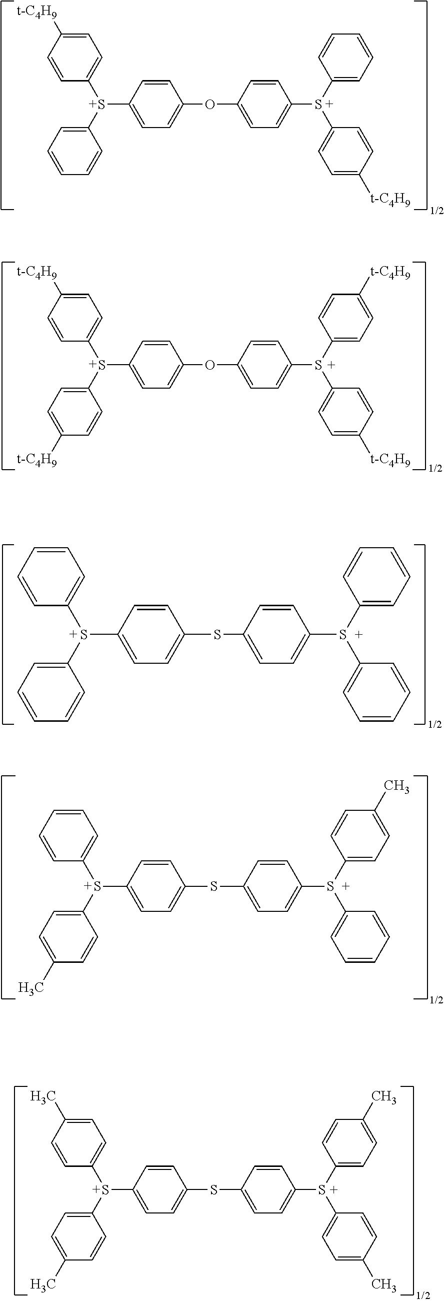

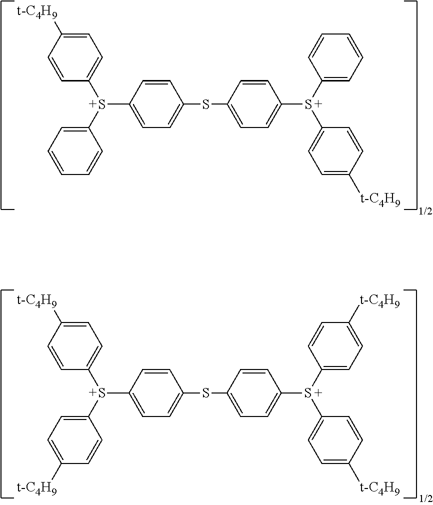

Examples of the salt represented by the formula (B1) include a salt wherein the anion part is any one of the above-mentioned anion parts and the cation part is any one of the above-mentioned cation parts. Preferable examples of the salt include a combination of any one of anions represented by the formulae (b1-1-1) to (b1-1-9) and the cation represented by the formulae (b2-1-1), and a combination of any one of anions represented by the formulae (b1-1-3) to (b1-1-5) and the cation represented by the formulae (b2-3).

The salt represented by the formulae (B1-1) to (B1-17) are preferable, and the salt represented by the formulae (B1-1), (B1-2), (B1-6), (B1-11), (B1-12), (B1-13) and (B1-14) are more preferable.

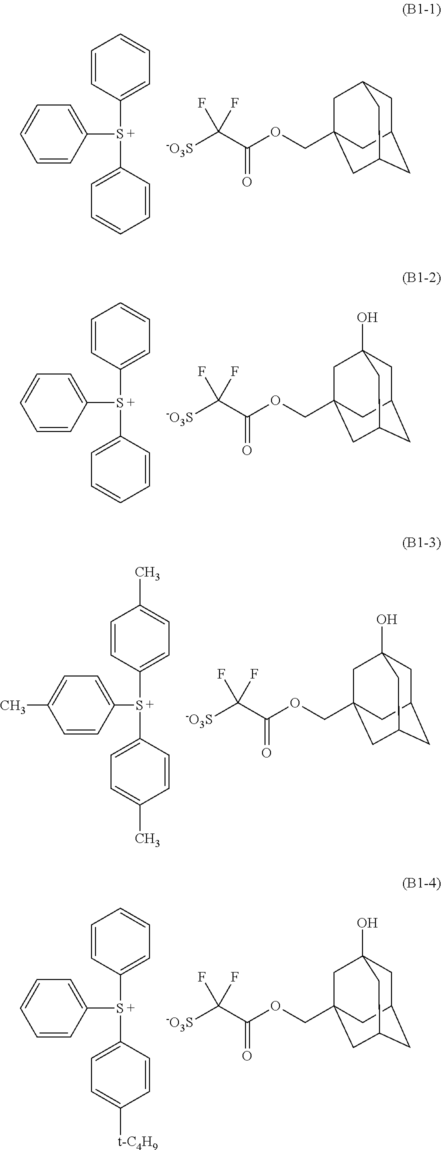

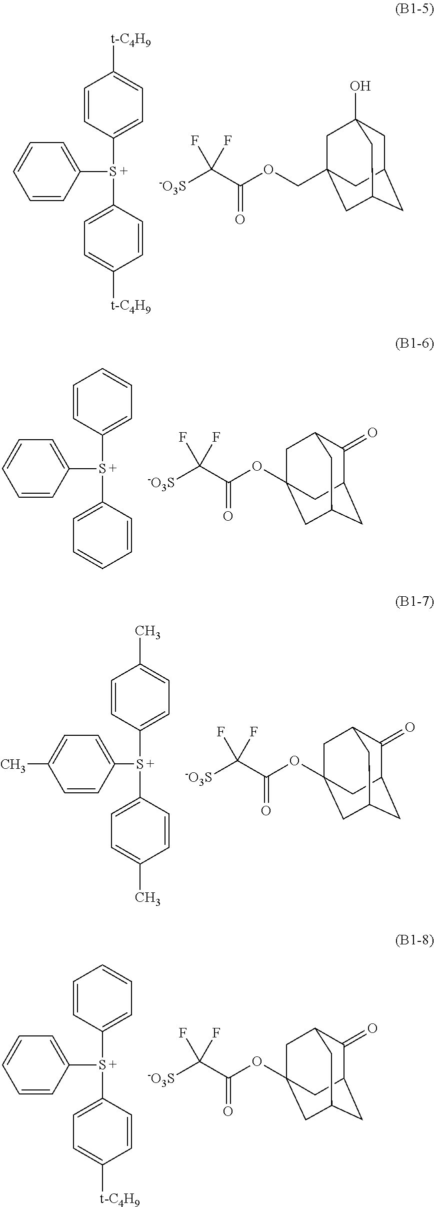

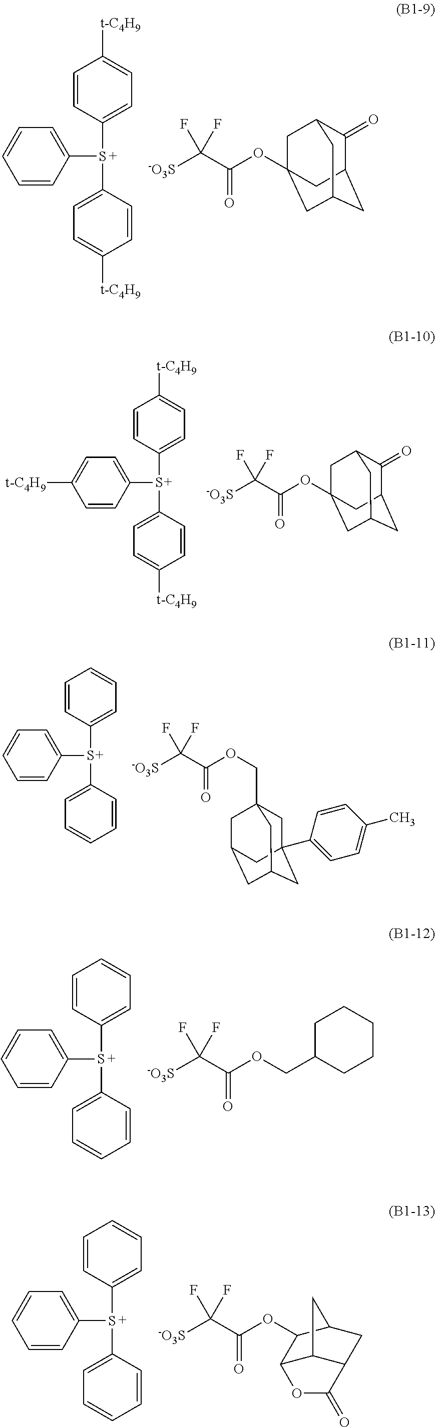

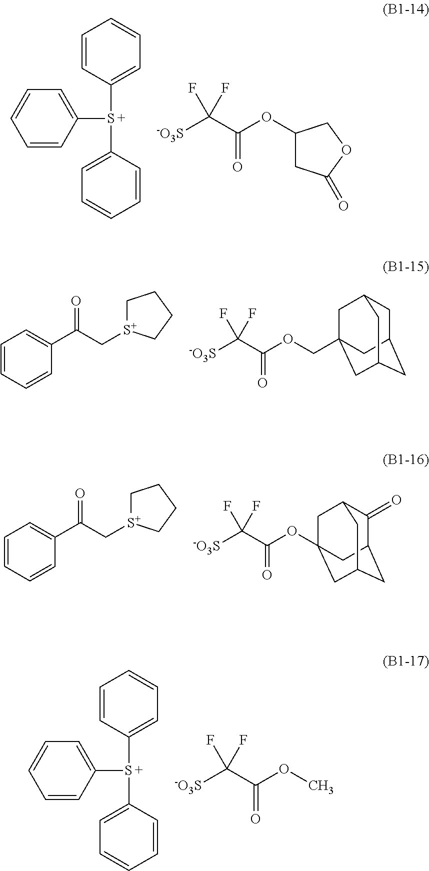

Two or more kinds of the photoacid generator can be used in combination.

The content of the photoacid generator in the first photoresist composition is usually 1 part by weight or more and preferably 3 parts by weight or more per 100 parts by weight of the resin component, and 30 parts by weight or less and preferably 25 parts by weight or less per 100 parts by weight of the resin component.

Next, Component (C) will be illustrated.

Component (c) is a cross-linking agent. The cross-linking agent is not limited, and the cross-linking agent can be suitably selected from the cross-linking agents used in the art.

Examples of the cross-linking agent include urea-type cross-linking agents, alkylene urea-type cross-linking agents and glycoluril-type cross-linking agent, and glycoluril-type cross-linking agents are preferred.

Examples of the urea-type cross-linking agent include bis(methoxymethyl)urea, bis(ethoxymethyl)urea, bis(propoxymethyl)urea, and bis(butoxymethyl)urea. Among these, preferred is bis(methoxymethyl)urea. The urea-type cross-linking agent can be produced by reacting urea with formaldehyde or by reacting urea, formaldehyde and a lower alcohol.

Examples of the alkylene urea-type cross-linking group include a compounds represented by the formula (XIX):

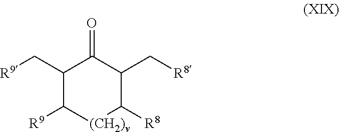

wherein R⁸ and R⁹ independently represent a hydroxyl group or a lower alkoxy group, R^{8′} and R^{9′} independently represent a hydrogen atom, a hydroxyl group or a lower alkoxy group, and v is an integer of 0 to 2.

R^{8′} and R^{9′} may be the same, or may be different from each other, and R^{8′} and R^{9′} are preferably the same. R⁸ and R⁹ may be the same, or may be different from each other, and R⁸ and R⁹ are preferably the same.

Examples of the lower alkoxy group include a C1-C4 alkoxy group such as a methyl group, an ethyl group, a propyl group and a butyl group.

It is preferred that v is 0 or 1.

A compound represented by the formula (XIX) in which v is 0 or 1 is preferable.

The compound represented by the formula (XIX) can be obtained by a condensation reaction of alkylene urea and formalin followed by a reaction of the resulting product and a lower alcohol.

Specific examples of an alkylene urea-type cross-linking agent include ethylene urea-type cross-linking agents such as mono-hydroxymethylated ethylene urea, di-hydroxymethylated ethylene urea, mono-methoxymethylated ethylene urea, di-methoxymethylated ethylene urea, mono-ethoxymethylated ethylene urea, di-ethoxymethylated ethylene urea, mono-propoxymethylated ethylene urea, di-propoxymethylated ethylene urea, mono-butoxymethylated ethylene urea and di-butoxymethylated ethylene urea;

propylene urea-type cross-linking agents such as mono-hydroxymethylated propylene urea, di-hydroxymethylated propylene urea, mono-methoxymethylated propylene urea, di-methoxymethylated propylene urea, mono-ethoxymethylated propylene urea, di-ethoxymethylated propylene urea, mono-propoxymethylated propylene urea, di-propoxymethylated propylene urea, and mono-butoxymethylated propylene urea and di-butoxymethylated propylene urea; 1,3-di(methoxymethyl)-4,5-dihydroxy-2-imidazolidinone and 1,3-di(methoxymethyl)-4,5-dimethoxy-2-imidazolidinone.

Examples of glycoluril-type cross-linking agents include a glycoluril compound in which the N-position is substituted with either or both a hydroxyalkyl group and/or a C1-C4 alkyl group having a C1-C4 alkoxy group. The glycoluril compound can be obtained by subjecting a glycoluril and formalin to a condensation reaction followed by reacting the product of this reaction with a C1-C4 alcohol.

Specific examples of glycoluril-type cross-linking agents include mono-, di-, tri- or tetra-hydroxymethylated glycoluril, mono-, di-, tri- and/or tetra-methoxymethylated glycoluril, mono-, di-, tri- and/or tetra-ethoxymethylated glycoluril, mono-, di-, tri- and/or tetra-propoxymethylated glycoluril, and mono-, di-, tri- and/or tetra-butoxymethylated glycoluril.

The cross-linking agent may be used singly or two or more kinds thereof may be used in combination.

The content of the cross-linking agent is preferably 0.5 to 30 parts by weight per 100 parts by weight of the Component (a), and more preferably 0.5 to 10 parts by weight, and still more preferably 1 to 5 parts by weight. When the content of the cross-linking agent is within this range, the formation of cross-linking is sufficiently promoted and a good photoresist pattern can be obtained. Furthermore, when the content of the cross-linking agent is within this range, the storage stability of the photoresist coating liquid is superior and deterioration over time of its sensitivity can be suppressed.

In the first photoresist composition, performance deterioration caused by inactivation of acid which occurs due to post exposure delay can be diminished by adding an organic base compound, particularly a nitrogen-containing organic base compound as a quencher. The content of the basic compound is usually 0.01 to 1% by weight based on solid component.

The basic compound is preferably a basic nitrogen-containing organic compound, and examples thereof include an amine compound such as an aliphatic amine and an aromatic amine and an ammonium salt. Examples of the aliphatic amine include a primary amine, a secondary amine and a tertiary amine. Examples of the aromatic amine include an aromatic amine in which aromatic ring has one or more amino groups such as aniline and a heteroaromatic amine such as pyridine. Preferable examples thereof include an aromatic amine represented by the formula (C2):

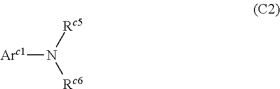

wherein Ar^{c1} represents an aromatic hydrocarbon group, and R^{c5} and R^{c6} each independently represent a hydrogen atom, an aliphatic hydrocarbon group, a saturated cyclic hydrocarbon group or an aromatic hydrocarbon group, and the aliphatic hydrocarbon group, the saturated cyclic hydrocarbon group and the aromatic hydrocarbon group can have one or more substituents selected from the group consisting of a hydroxyl group, an amino group, an amino group having one or two C1-C4 alkyl groups and a C1-C6 alkoxy group. The aliphatic hydrocarbon group is preferably an alkyl group and the saturated cyclic hydrocarbon group is preferably a cycloalkyl group. The aliphatic hydrocarbon group preferably has 1 to 6 carbon atoms. The saturated cyclic hydrocarbon group preferably has 5 to 10 carbon atoms. The aromatic hydrocarbon group preferably has 6 to 10 carbon atoms.

As the aromatic amine represented by the formula (C2), an amine represented by the formula (C2-1):

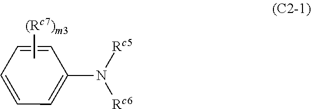

wherein R^{c5} and R^{c6} are the same as defined above, and R^{c7} is independently in each occurrence an aliphatic hydrocarbon group, an alkoxy group, a saturated cyclic hydrocarbon group or an aromatic hydrocarbon group, and the aliphatic hydrocarbon group, the alkoxy group, the saturated cyclic hydrocarbon group and the aromatic hydrocarbon group can have one or more substituents selected from the group consisting of a hydroxyl group, an amino group, an amino group having one or two C1-C4 alkyl groups and a C1-C6 alkoxy group, and m3 represents an integer of 0 to 3, is preferable. The aliphatic hydrocarbon group is preferably an alkyl group and the saturated cyclic hydrocarbon group is preferably a cycloalkyl group. The aliphatic hydrocarbon group preferably has 1 to 6 carbon atoms. The saturated cyclic hydrocarbon group preferably has 5 to 10 carbon atoms. The aromatic hydrocarbon group preferably has 6 to 10 carbon atoms. The alkoxy group preferably has 1 to 6 carbon atoms.

Examples of the aromatic amine represented by the formula (C2) include 1-naphthylamine, 2-naphthylamine, aniline, diisopropylaniline, 2-methylaniline, 3-methylaniline, 4-methylaniline, 4-nitroaniline, N-methylaniline, N,N-dimethylaniline, and diphenylamine, and among them, preferred is diisopropylaniline and more preferred is 2,6-diisopropylaniline. Examples of the ammonium salt represented by the formula (C2-2) include tetramethylammonium hydroxide and tetrabutylammonium hydroxide.

Other examples of the basic compound include amines represented by the formulae (C3) to (C11):

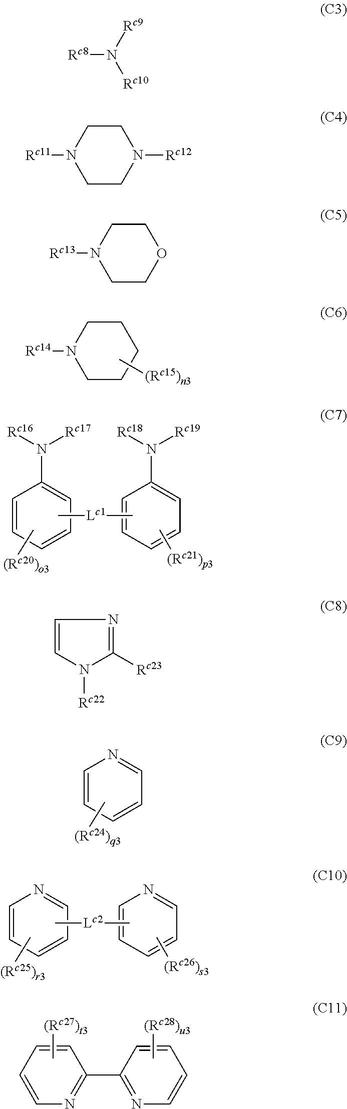

wherein R^{cb}, R^{c20}, R^{c21}, and R^{c23} to R^{c28} each independently represent an aliphatic hydrocarbon group, an alkoxy group, a saturated cyclic hydrocarbon group or an aromatic hydrocarbon group, and the aliphatic hydrocarbon group, the alkoxy group, the saturated cyclic hydrocarbon group and the aromatic hydrocarbon group can have one or more substituents selected from the group consisting of a hydroxyl group, an amino group, an amino group having one or two C1-C4 alkyl groups and a C1-C6 alkoxy group,
R^{c9}, R^{c10}, R^{c11} to R^{c14}, R^{c16} to R^{c19}, and R^{c22} each independently represents a hydrogen atom, an aliphatic hydrocarbon group, a saturated cyclic hydrocarbon group or an aromatic hydrocarbon group, and the aliphatic hydrocarbon group, the saturated cyclic hydrocarbon group and the aromatic hydrocarbon group can have one or more substituents selected from the group consisting of a hydroxyl group, an amino group, an amino group having one or two C1-C4 alkyl groups and a C1-C6 alkoxy group,
R^{c15} is independently in each occurrence an aliphatic hydrocarbon group, a saturated cyclic hydrocarbon group or an alkanoyl group, L^{c1} and L^{c2} each independently represents a divalent aliphatic hydrocarbon group, —CO—, —C(═NH)—, —C(═NR^{c3})—, —S—, —S—S— or a combination thereof and R^{c3} represents a C1-C4 alkyl group, O3 to u3 each independently represents an integer of 0 to 3 and n3 represents an integer of 0 to 8.

The aliphatic hydrocarbon group has preferably 1 to 6 carbon atoms, and the saturated cyclic hydrocarbon group has preferably 3 to 6 carbon atoms, and the alkanoyl group has preferably 2 to 6 carbon atoms, and the divalent aliphatic hydrocarbon group has preferably 1 to 6 carbon atoms. The divalent aliphatic hydrocarbon group is preferably an alkylene group.

Examples of the amine represented by the formula (C3) include hexylamine, heptylamine, octylamine, nonylamine, decylamine, dibutylamine, dipentylamine, dihexylamine, diheptylamine, dioctylamine, dinonylamine, didecylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methyldihexylamine, methyldicyclohexylamine, methyldiheptylamine, methyldioctylamine, methyldinonylamine, methyldidecylamine, ethyldibutylamine, ethydipentylamine, ethyldihexylamine, ethydiheptylamine, ethyldioctylamine, ethyldinonylamine, ethyldidecylamine, dicyclohexylmethylamine, tris[2-(2-methoxyethoxy)ethyl]amine, triisopropanolamine, ethylenediamine, tetramethylenediamine, hexamethylenediamine, 4,4′-diamino-1,2-diphenylethane, 4,4′-diamino-3,3′-dimethyldiphenylmethane and 4,4′-diamino-3,3′-diethyldiphenylmethane.

Examples of the amine represented by the formula (C4) include piperazine. Examples of the amine represented by the formula (C5) include morpholine. Examples of the amine represented by the formula (C6) include piperidine and hindered amine compounds having a piperidine skeleton as disclosed in JP 11-52575 A. Examples of the amine represented by the formula (C7) include 2,2′-methylenebisaniline. Examples of the amine represented by the formula (C8) include imidazole and 4-methylimidazole. Examples of the amine represented by the formula (C9) include pyridine and 4-methylpyridine. Examples of the amine represented by the formula (C10) include di-2-pyridyl ketone, 1,2-di(2-pyridyl)ethane, 1,2-di(4-pyridyl)ethane, 1,3-di(4-pyridyl)propane, 1,2-bis(2-pyridyl)ethene, 1,2-bis(4-pyridyl)ethene, 1,2-di(4-pyridyloxy)ethane, 4,4′-dipyridyl sulfide, 4,4′-dipyridyl disulfide, 2,2′-dipyridylamine and 2,2′-dipicolylamine. Examples of the amine represented by the formula (C11) include bipyridine.

The first photoresist composition of the present invention usually contains one or more solvents. Examples of the solvent include a glycol ether ester such as ethyl cellosolve acetate, methyl cellosolve acetate and propylene glycol monomethyl ether acetate; a glycol ether such as propylene glycol monomethyl ether; an acyclic ester such as ethyl lactate, butyl acetate, amyl acetate and ethyl pyruvate; a ketone such as acetone, methyl isobutyl ketone, 2-heptanone and cyclohexanone; and a cyclic ester such as γ-butyrolactone.

The amount of the solvent is usually 90% by weight or more, preferably 92% by weight or more preferably 94% by weight or more based on total amount of the photoresist composition of the present invention. The amount of the solvent is usually 99.9% by weight or less based on total amount of the photoresist composition of the present invention. The photoresist composition containing a solvent can be preferably used for producing a thin layer photoresist pattern. The first photoresist composition may contain two or more kinds of the solvents.

The first photoresist composition can contain, if necessary, a small amount of various additives such as a sensitizer, a dissolution inhibitor, a surfactant, a stabilizer, a dye and a thermal acid generator as long as the effect of the present invention is not prevented. Herein, “thermal acid generator” means a compound which is stable at temperature lower the temperature of baking the photoresist pattern obtained from the photoresist composition containing the thermal acid generator and is decomposed at temperature at the temperature of baking the photoresist pattern obtained from the photoresist composition containing the thermal acid generator or higher to generate an acid. Known thermal acid generators can be used, and examples thereof include benzoin tosylate, nitorobenzyl tosylate such as 4-nitorobenzyl tosylate and alkyl esters of organic sulfonic acids. The content thereof is usually 0.5 to 30 parts by weight relative to 100 parts by weight of the resin, and preferably 0.5 to 15 parts by weight and more preferably 1 to 10 parts by weight.

Next, the second photoresist composition will be illustrated.

The second photoresist composition used in the present invention comprises the following two components;

Component (d): a resin

Component (e): at least one photoacid generator selected from the group consisting of a photoacid generator represented by the formula (I):

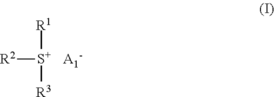

wherein R¹ and R² independently a C1-C12 alkyl group or a C6-C18 aromatic hydrocarbon group which can have one or more substituents, R³ represents a C1-C12 alkyl group, or R² and R³ are bonded each other to form a C3-C12 divalent acyclic hydrocarbon group which forms a ring together with S and one or more —CH₂— in the C3-C12 divalent acyclic hydrocarbon group can be replaced by —O—, and A₁⁻ represents an organic anion, and a photoacid generator represented by the formula (II):

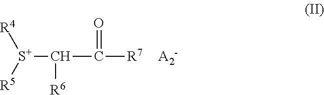

wherein R⁴ and R⁵ independently a C1-C12 alkyl group, a C3-C18 saturated cyclic hydrocarbon group or a C6-C18 aromatic hydrocarbon group, or R⁴ and R⁵ are bonded each other to form a C3-C12 divalent acyclic hydrocarbon group which forms a ring together with S and one or more —CH₂— in the C3-C12 divalent acyclic hydrocarbon group can be replaced by —O—, R⁶ represents a hydrogen atom, R⁷ represents a C1-C12 alkyl group, a C3-C18 saturated cyclic hydrocarbon group or a C6-C18 aromatic hydrocarbon group which can have one or more substituents, or R⁶ and R⁷ are bonded each other to form a C1-C10 divalent acyclic hydrocarbon group which forms a 2-oxocycloalkyl group together with —CHCO— to which R⁶ and R⁷ are bonded, and A₂⁻ represents an organic anion.

Examples of Component (d) include the same as Component (a) of the first photoresist composition.

The second photoresist composition used in the present invention usually includes 80% by weight or more of the resin based on sum of solid component.

In the formulae (I) and (II), examples of C1-C12 alkyl group include a methyl group, an ethyl group, a propyl group, an isopropyl group, a butyl group, a tert-butyl group, a pentyl group, a hexyl group, a heptyl group, an octyl group, a 2-ethylhexyl group, a nonyl group, a decyl group, an undecyl group and a dodecyl group, and a C1-C4 alkyl group is preferable, and a C1-C2 alkyl group is more preferable and a methyl group is especially preferable. Examples of the C6-C18 aromatic hydrocarbon group include a phenyl group, a naphthyl group, an anthryl group, a p-methylphenyl group, a p-tert-butylphenyl group and a p-adamantylphenyl group. Examples of the C3-C18 saturated cyclic hydrocarbon group include a cycloprpypl group, a cyclobutyl group, a cyclopentyl group, a cyclohexyl group, a cycloheptyl group, a cyclooctyl group, a cyclononyl group, a cyclodecyl group, a norbornyl group, a 1-adamantyl group, a 2-adamantyl group, an isobornyl group and the following.

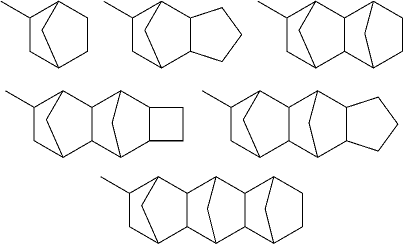

Examples of the substituents of the C6-C18 aromatic hydrocarbon group represented by R¹ and R² include a C1-C12 alkyl group and a C1-C12 alkoxy group.

Examples of the ring formed by combining a C3-C12 divalent acyclic hydrocarbon group formed by bonding R² and R³ with S include the following.

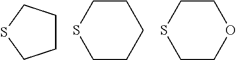

Examples of the ring formed by combining a C3-C12 divalent acyclic hydrocarbon group formed by bonding R⁴ and R⁵ with S include the following.

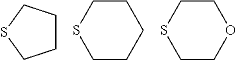

Examples of the substituents of the C6-C18 aromatic hydrocarbon group represented by R⁷ include a C1-C12 alkyl group, a C1-C12 alkoxy group, a C6-C18 aromatic hydrocarbon group, a C3-C18 saturated cyclic hydrocarbon group, a nitro group and —O—CO—R^{e} in which R^{e} represents a C1-C12 alkyl group, a C6-C18 aromatic hydrocarbon group or a C3-C18 saturated cyclic hydrocarbon group.

Examples of the 2-oxocycloalkyl group formed by combining a C1-C10 divalent acyclic hydrocarbon group formed by bonding R⁶ and R⁷ with —CHCO— to which R⁶ and R⁷ are bonded include the following.

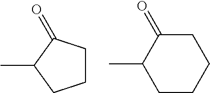

Examples of the organic anion represented by A₁⁻ and A₂⁻ include the same as those described in the photoacid generator contained in the first photoresist composition. Among them, preferred is an anion represented by the formula (III):

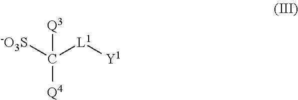

wherein Q³ and Q⁴ independently represent a fluorine atom or a C1-C6 perfluoroalkyl group, L¹ represents a single bond or a C1-C17 divalent saturated hydrocarbon group in which one or more —CH₂— can be replaced by —O— or —CO—, Y¹ represents a C3-C18 aliphatic hydrocarbon group which can have one or more substituents, a C3-C18 saturated cyclic hydrocarbon group which can have one or more substituents, and one or more —CH₂— in the aliphatic hydrocarbon group and the saturated cyclic hydrocarbon group can be replaced by —O—, —SO₂— or —CO—.

Examples of the C1-C6 perfluoroalkyl group include the same as described above, and Q³ and Q⁴ independently preferably represent a fluorine atom or a trifluoromethyl group, and Q³ and Q⁴ are more preferably fluorine atoms.

Examples of L¹ include the same as L^{b1} of the salt represented by the formula (B1), and L¹ is preferably *-CO—O-L^{b2}- in which L^{b2} is the same as defined above and * represents a binding position to —C (Q³)(Q⁴)-, and is more preferably *-CO—O-L^{b2}- in which L^{b2} is a single bond or —CH₂—.

Examples of Y¹ include the same as Y of the salt represented by the formula (B1), and a C3-C18 saturated cyclic hydrocarbon group having an oxo group is preferable, and the group represented by the formula (Y14) is more preferable.

Examples of the cations of the photoacid generator represented by the formula (I) include the following.

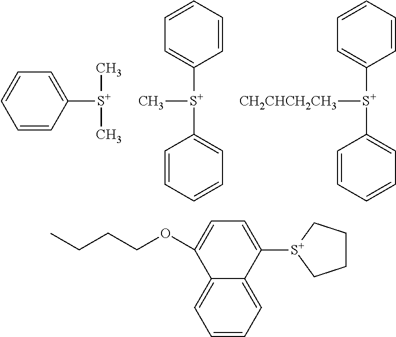

Examples of the cations of the photoacid generator represented by the formula (II) include the following.

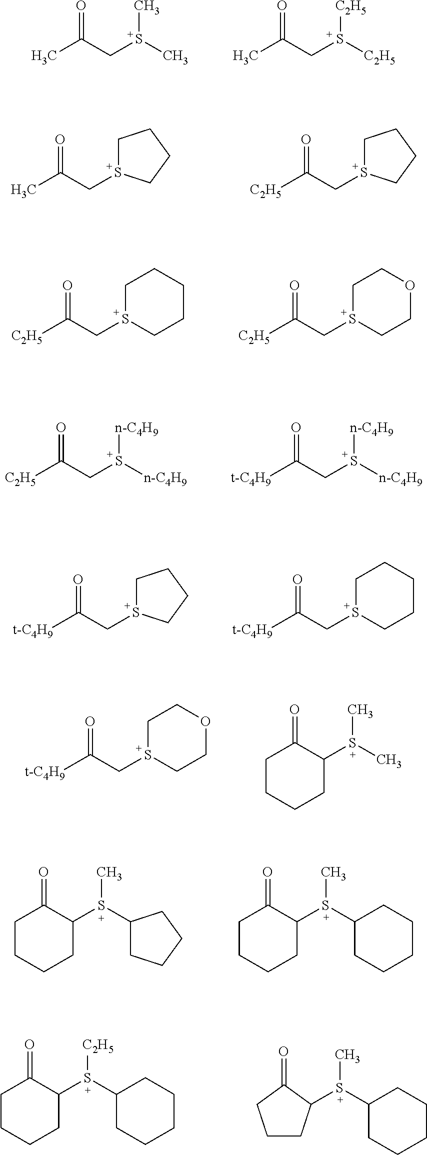

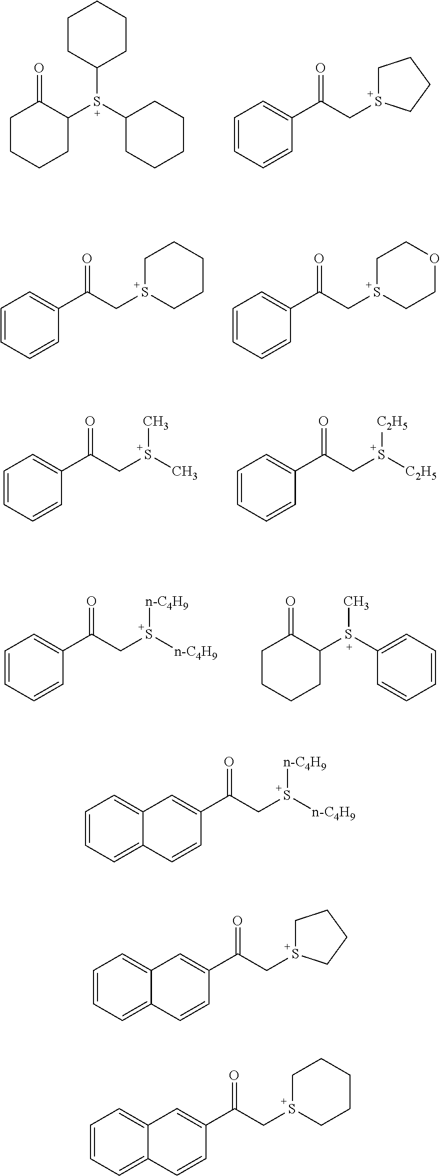

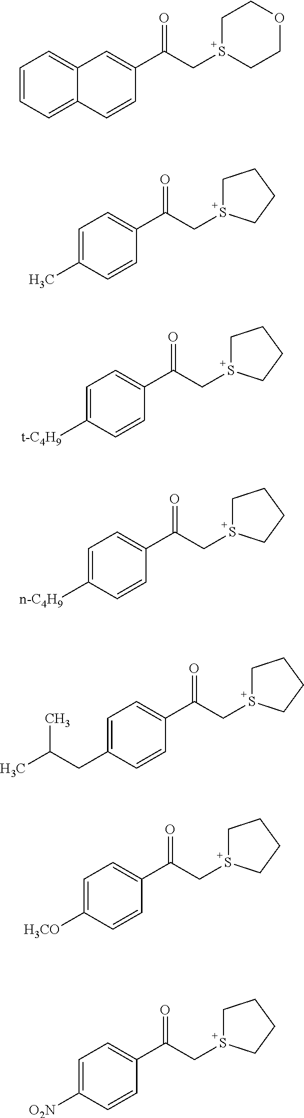

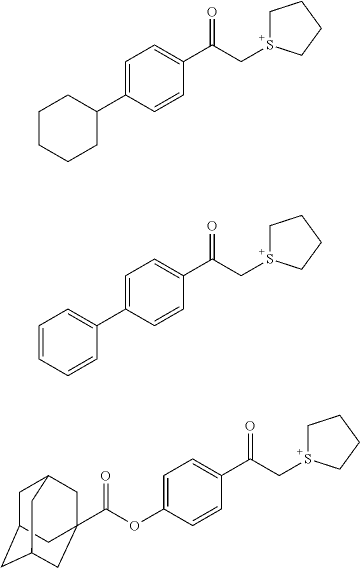

Examples of the photoacid generator represented by the formula (I) include the following.

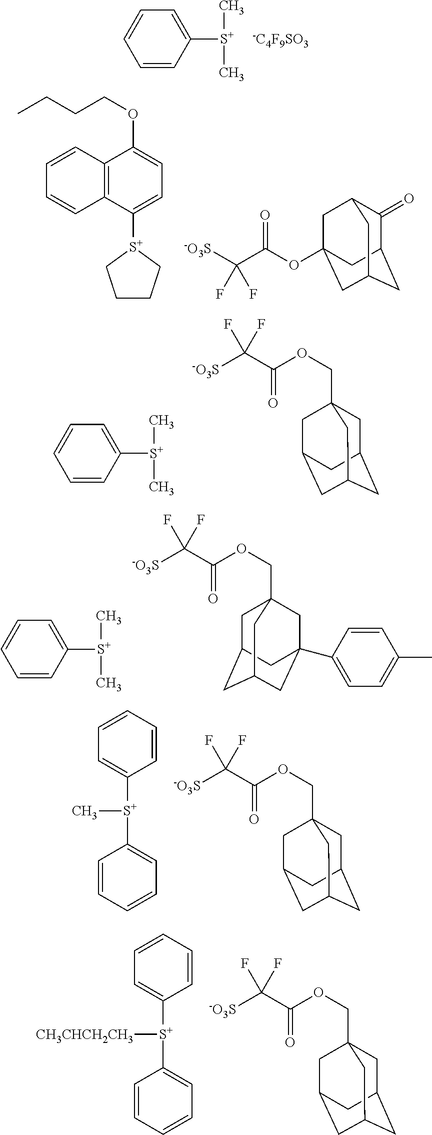

Examples of the photoacid generator represented by the formula (II) include the following.

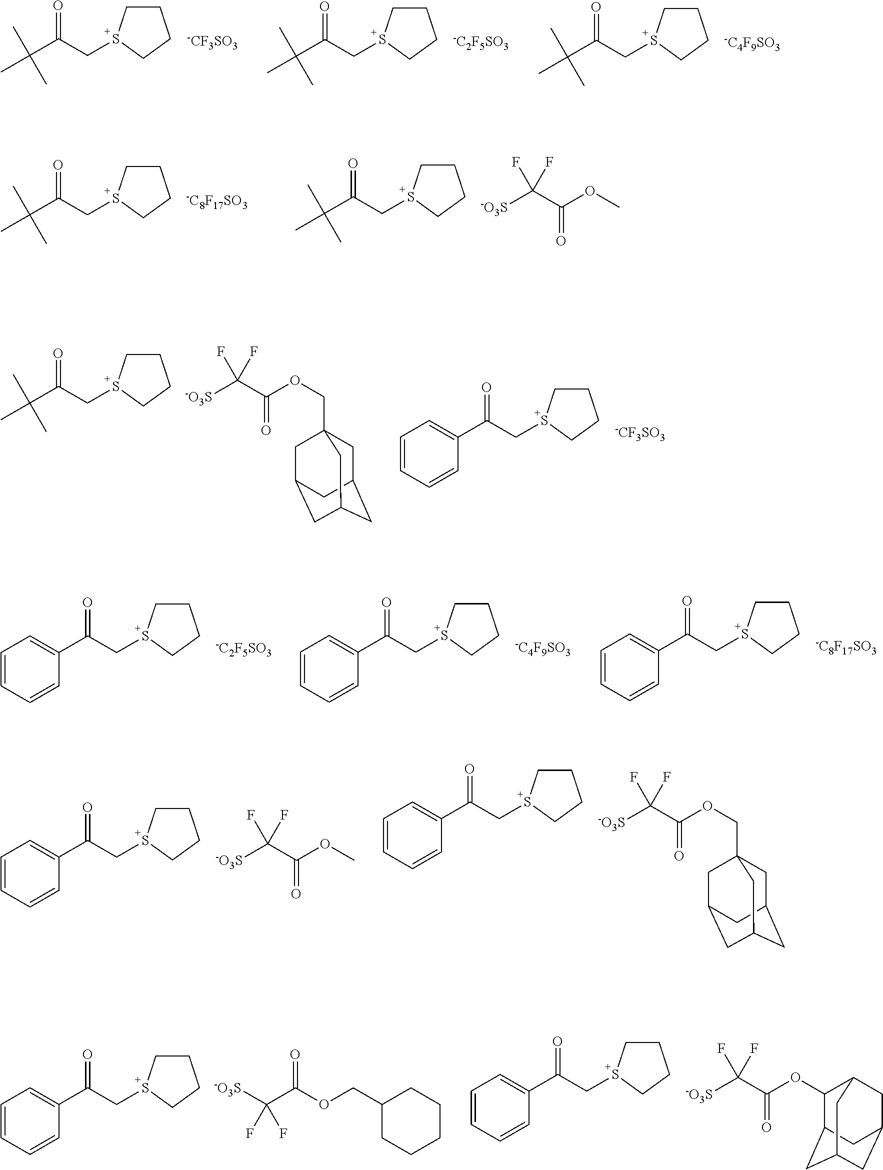

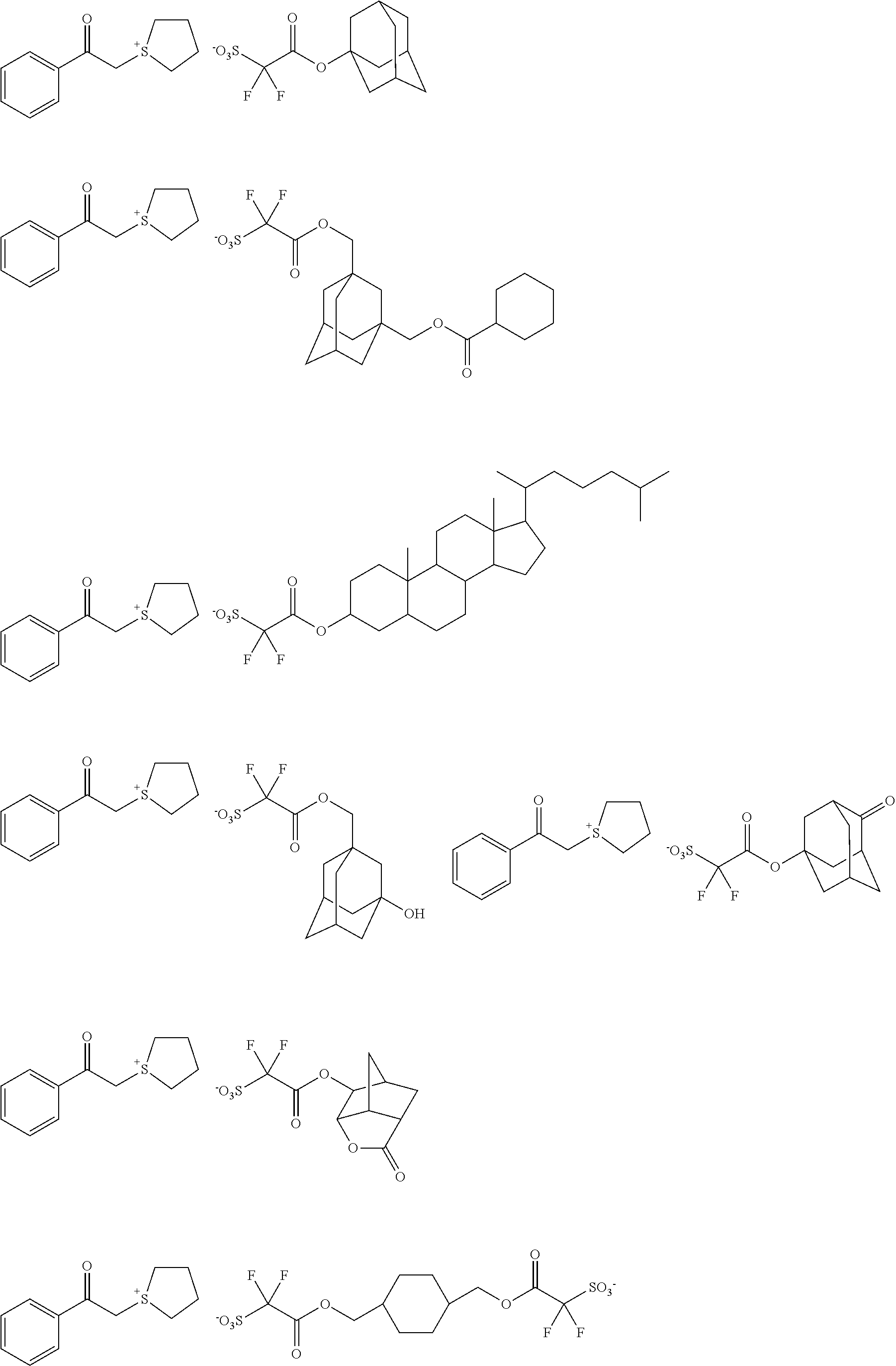

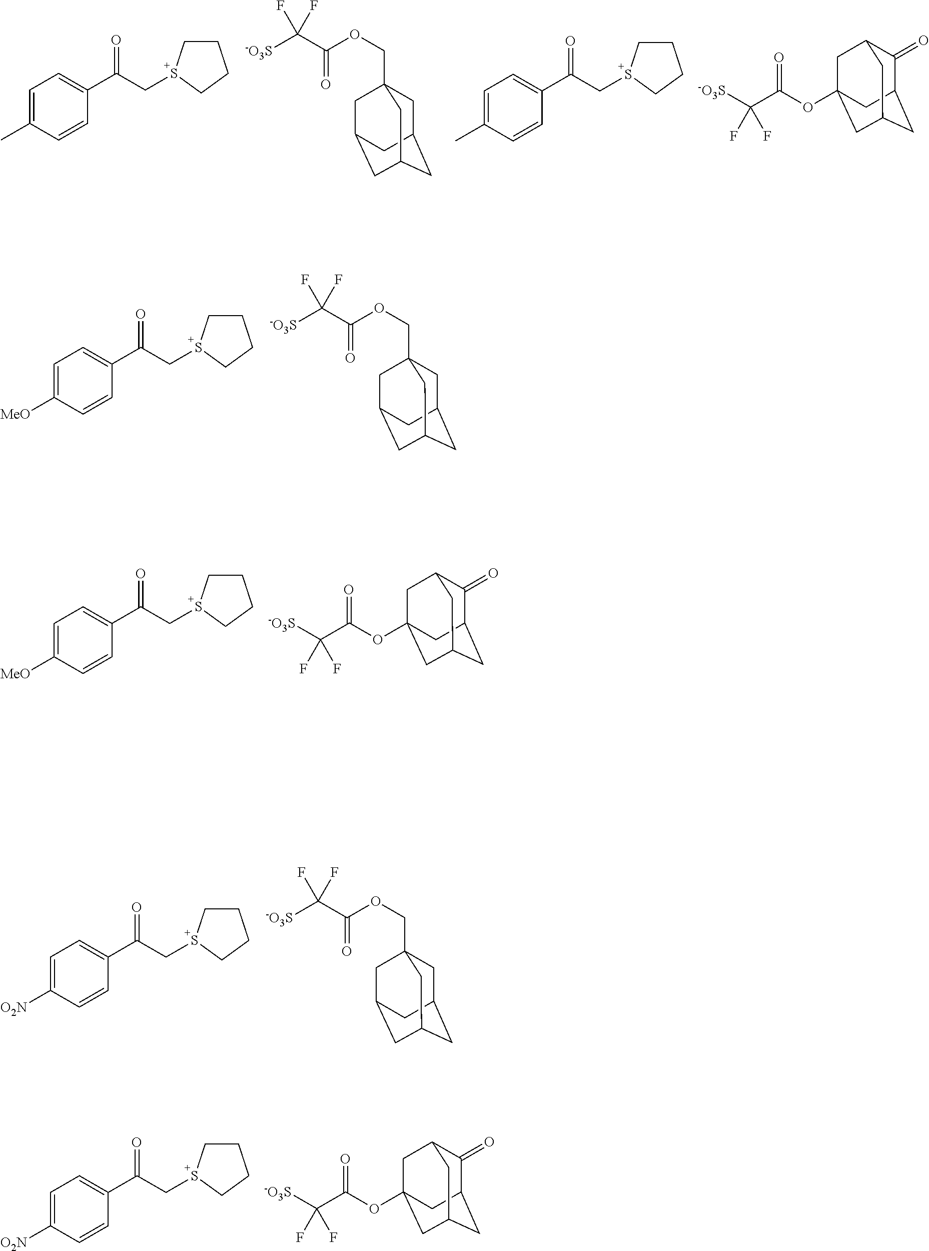

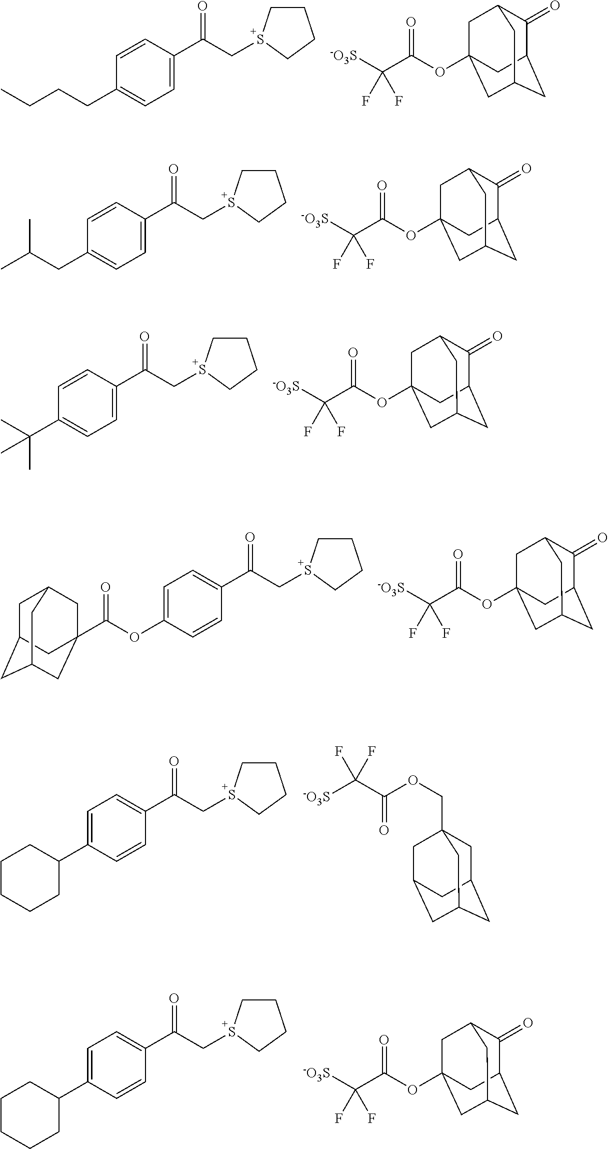

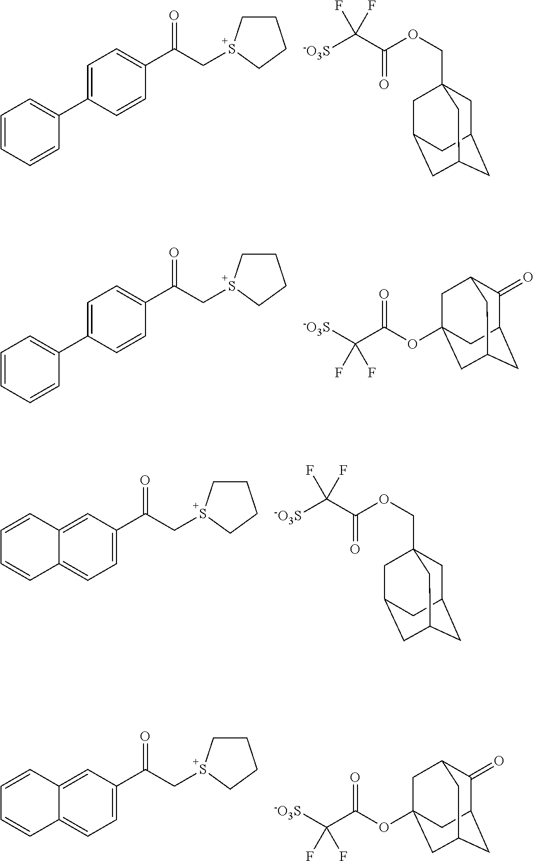

The photoacid generator represented by the formula (I) can be produced according to the method described in JP 2008-209917 A, and the photoacid generator represented by the formula (II) can be produced according to the method described in JP 2004-59882 A.

The second photoresist composition can contain other photoacid generators in addition to Component (e). Examples of the other photoacid generators include the photoacid generators described in the first photoresist composition. The ratio of Component (e) to the other photoacid generators (Component (e)/other photoacid generators) is usually 1/9 to 9/1 and preferably 1/9 to 5/5 and more preferably 2/8 to 5/5.

The content of Component (e) in the second photoresist composition is usually 1 part by weight or more and preferably 3 parts by weight or more per 100 parts by weight of the resin component, and 30 parts by weight or less and preferably 25 parts by weight or less per 100 parts by weight of the resin component.

The second photoresist composition may contain one or more basic compounds. Examples of the basic compounds include the same as those of the first photoresist composition. Preferred are the compounds represented by the formula (C2) and (C7) to (C11).

The content thereof in the second photoresist composition is usually 0.01 to 1% by weight based on solid component.

The second photoresist composition may contain one or more solvents, and examples thereof include the same as those in the first photoresist composition and the content thereof is also the same as that of the first photoresist composition.

The second photoresist composition may contain the above-mentioned additives.

The process for producing a photoresist pattern of the present invention comprises the following steps (A) to (D):

(A) a step of applying the above-mentioned first photoresist composition on a substrate to form a first photoresist film, exposing the first photoresist film to radiation followed by developing the first photoresist film exposed with an alkaline developer, thereby forming a first photoresist pattern,

(B) a step of making the first photoresist pattern inactive to radiation in the following step (C), making the first photoresist pattern insoluble in an alkaline developer or making the first photoresist pattern insoluble in the above-mentioned second photoresist composition used in the following step (C),

(C) a step of applying the second photoresist composition on the first photoresist pattern obtained in the step (B) to form the second photoresist film, exposing the second photoresist film to radiation, and

(D) a step of developing the second photoresist film exposed with an alkaline developer, thereby forming a second photoresist pattern.

In the step (A), the first photoresist composition is applied onto a substrate by a conventional process such as spin coating. Examples of the substrate include a semiconductor substrate such as a silicon wafer, a plastic substrate, a metallic substrate, a ceramic substrate and these substrates on which a insulating film or a conducting film is applied. An anti-reflective coating film can be formed on the substrate.

The step (A) preferably comprises the following steps (1a) to (5a):

(1a) a step of applying the first photoresist composition on a substrate followed by conducting drying, thereby forming a first photoresist film,

(2a) a step of baking the first photoresist film formed,

(3a) a step of exposing the first photoresist film baked to radiation,

(4a) a step of baking the first photoresist film exposed, and

(5a) a step of developing the first photoresist film baked in the step (4a) with an alkaline developer, thereby forming a first photoresist pattern.

In the step (A), while the film thickness of the first photoresist composition is not limited, it is preferably tens of nanometers to a few milimeters. After applying the first photoresist composition on the substrate, the first photoresist composition film formed is dried, thereby forming a first photoresist film. Examples of a drying process include natural drying, draught drying and drying under reduced pressure. The drying temperature is usually 10 to 120° C., and preferably 25 to 80° C., and the drying time is usually 10 to 3,600 seconds and preferably 30 to 1,800 seconds.

The first photoresist film formed is preferably baked. The baking is usually conducted using a heating device. The prebaking temperature is usually 80 to 160° C., and preferably 120 to 160° C., and the prebaking time is usually 30 to 600 seconds.

The first photoresist film baked is exposed to radiation. The exposure is usually conducted using a conventional exposure system such as KrF excimer laser exposure system (wave length: 248 nm), ArF excimer laser dry exposure system (wave length: 193 nm), ArF excimer laser liquid immersion exposure system (wave length: 193 nm), F₂ laser exposure system (wave length: 157 nm) and a system radiating a harmonic laser belonging to far-ultraviolet region or vacuum ultraviolet region by converting a laser from a solid-state laser source by wavelength conversion.

The first photoresist film exposed is preferably baked. The baking is usually conducted using a heating device. The baking temperature is usually 70 to 140° C., and the baking time is usually 30 to 600 seconds.

The first photoresist film baked is developed with an alkaline developer, thereby forming a first photoresist pattern. As the alkaline developer, any one of various alkaline aqueous solution used in the art is used. Generally, an aqueous solution of tetramethylammonium hydroxide or (2-hydroxyethyl)trimethylammonium hydroxide (commonly known as “choline”) is used.

In the step (B), the first photoresist pattern formed in the step (A) is made inactive to radiation in the following step (C), made the first photoresist pattern formed insoluble in an alkaline developer or made the first photoresist pattern formed insoluble in the second photoresist composition used in the following step (C).

Herein, “the first photoresist pattern is inactive to radiation” means the resin component in the first photoresist composition is not photosensitive even though the first photoresist pattern is exposed to irradiation, and therefore, the first photoresist pattern does not become to be soluble in an alkali aqueous solution.

The step (B) is usually conducted by exposure of the first photoresist pattern, baking of the first photoresist pattern, ultraviolet curing of the first photoresist pattern or a combination thereof.

Exposure of the first photoresist pattern is usually conducted by exposing the first photoresist pattern to irradiation at twice to twenty times as much exposure amount as the most suitable exposure amount in the exposure of the first photoresist film in the step (A).

Baking of the first photoresist pattern is usually conducted using a heating device. The heating device may be the same as that used in the step (A) and may be different from that used in the step (A). A hotplate or an oven is usually used as the heating device, and a hotplate is preferable. The baking temperature is usually higher than that of the baking of the first photoresist film exposed.

Ultraviolet curing of the first photoresist pattern is usually conducted using Ar₂ lamp, KrCl lamp, Kr₂ lamp, XeCl lamp or Xe₂ lamp.

The step (B) preferably comprises the following step (6a):

(6a) a step of baking the first photoresist pattern.

The baking temperature in the step (6a) is usually 120 to 250° C., and the baking time is usually 30 to 600 seconds.

In the step (C), the second photoresist composition is applied on the first photoresist pattern obtained in the step (B) to form a second photoresist film, exposing the second photoresist film to radiation.

The step (C) preferably comprises the following steps (7a) to (10a):

(7a) a step of applying the second photoresist composition on the first photoresist pattern obtained in the step (B) followed by conducting drying, thereby forming a second photoresist film,

(8a) a step of baking the second photoresist film formed,

(9a) a step of exposing the second photoresist film baked to radiation, and

(10a) a step of baking the second photoresist film exposed.

The conditions of applying the second photoresist composition, drying, baking of the second photoresist film formed, exposing the second photoresist film baked and baking the second photoresist film exposed are the same as those described in the step (A), respectively.

In the step (D), the second photoresist film exposed in the step (C) is developed with an alkaline developer, thereby forming a second photoresist pattern. As the alkaline developer, the same as described as the alkaline developer used in the step (A) is usually used. This step is usually conducted according to the same manner as described in the step (A).

It should be construed that embodiments disclosed here are examples in all aspects and not restrictive. It is intended that the scope of the present invention is determined not by the above descriptions but by appended Claims, and includes all variations of the equivalent meanings and ranges to the Claims.

The present invention will be described more specifically by Examples, which are not construed to limit the scope of the present invention. The “%” and “part(s)” used to represent the content of any compound and the amount of any material to be used in the following Examples are on a weight basis unless otherwise specifically noted. The weight-average molecular weight (Mw) and the number-average molecular weight (Mn) of resins used in the following examples is a value found by gel permeation chromatography and the analysis condition is as followed.

### <Gel Permeation Chromatography Analysis Condition>

Apparatus: HLC-8120GPC Type, manufactured by TOSOH CORPORATION
Column: Three Columns of TSKgel Multipore HXL-M with a guard column, manufactured by TOSOH CORPORATION
Eluting Solvent: tetrahydrofuran
Flow rate: 1.0 mL/minute
Detector: RI detector

### Column Temperature: 40° C.

Injection amount: 100
Standard reference material: standard polystyrene

In Resin Synthesis Examples, the following Monomer (A), Monomer (B), Monomer (C), Monomer (D), Monomer (E), Monomer (F), Monomer (G) and Monomer (H) were used.

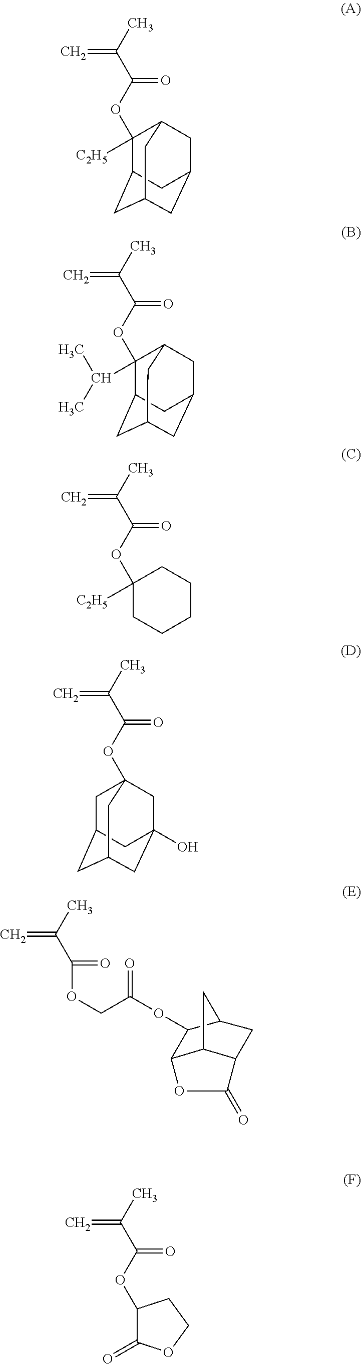

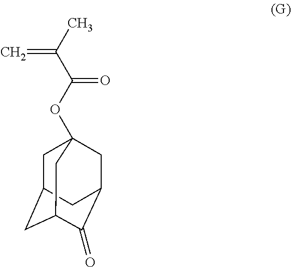

### Resin Synthesis Example 1

Into a four-necked flask equipped with a condenser and a thermometer, 23.66 parts of 1,4-dioxane was added, and then a nitrogen gas was blown into it for 30 minutes to substitute a gas in the flask to a nitrogen gas. After heating it up to 73° C. under nitrogen, a solution obtained by mixing 15.00 parts of Monomer (A), 2.59 parts of Monomer (C), 8.03 parts of Monomer (D), 13.81 parts of Monomer (F), 0.31 part of 2,2′-azobisisobutyronitrile, 1.41 part of 2,2′-azobis(2,4-dimethylvaleronitrile) and 35.49 parts of 1,4-dioxane was added dropwise thereto over 2 hours at 73° C. The resultant mixture was heated at 73° C. for 5 hours. The reaction mixture was cooled down to room temperature and diluted with 43.38 parts of 1,4-dioxane. The resultant mixture was pored into a mixed solution of 410 parts of methanol and 103 parts of ion-exchanged water with stirring to cause precipitation. The precipitate was isolated and then, mixed with 256 parts of methanol followed by filtration to obtain the precipitate. This operation wherein the precipitate was mixed with 256 parts of methanol followed by filtration to obtain the precipitate was repeated three times. The obtained precipitate was dried under reduced pressure to obtain 29.6 parts of a resin having a Mw of 8.5×10³ and degree of dispersion (Mw/Mn) of 1.79. The yield thereof was 75%. This resin had the following structural units represented by the formulae (AA), (CC), (DD) and (FF). This is called as resin A1.

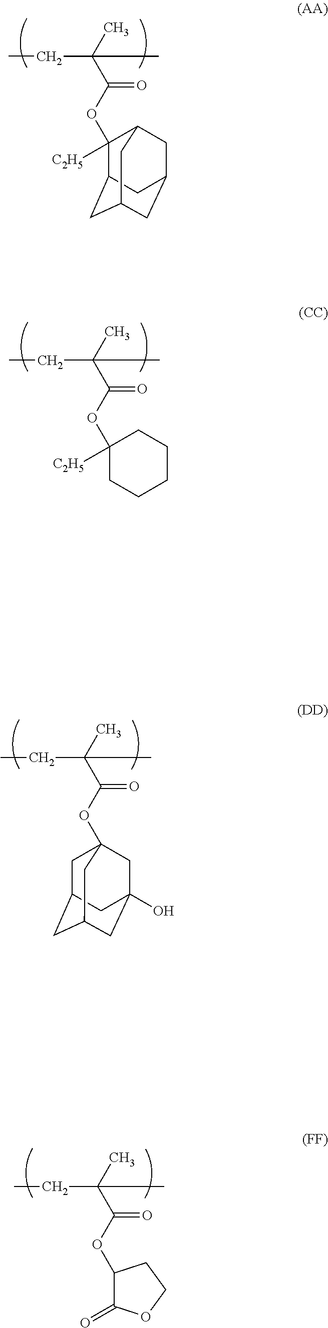

### Resin Synthesis Example 2

Into a four-necked flask equipped with a condenser and a thermometer, 27.78 parts of 1,4-dioxane was added, and then a nitrogen gas was blown into it for 30 minutes to substitute a gas in the flask to a nitrogen gas. After heating it up to 73° C. under nitrogen, a solution obtained by mixing 15.00 parts of Monomer (B), 5.61 parts of Monomer (C), 2.89 parts of Monomer (D), 12.02 parts of Monomer (E), 10.77 parts of Monomer (F), 0.34 part of 2,2′-azobisisobutyronitrile, 1.52 part of 2,2′-azobis(2,4-dimethylvaleronitrile) and 63.85 parts of 1,4-dioxane was added dropwise thereto over 2 hours at 73° C. The resultant mixture was heated at 73° C. for 5 hours. The reaction mixture was cooled down to room temperature and diluted with 50.92 parts of 1,4-dioxane. The resultant mixture was pored into a mixed solution of 481 parts of methanol and 120 parts of ion-exchanged water with stirring to cause precipitation. The precipitate was isolated and then, mixed with 301 parts of methanol followed by filtration to obtain the precipitate. This operation wherein the precipitate was mixed with 301 parts of methanol followed by filtration to obtain the precipitate was repeated three times. The obtained precipitate was dried under reduced pressure to obtain 37 parts of a resin having a Mw of 7.90×10³ and degree of dispersion (Mw/Mn) of 1.96. The yield thereof was 80%. This resin had the following structural units represented by the formulae (BB), (CC), (DD), (EE) and (FF). This is called as resin A2.

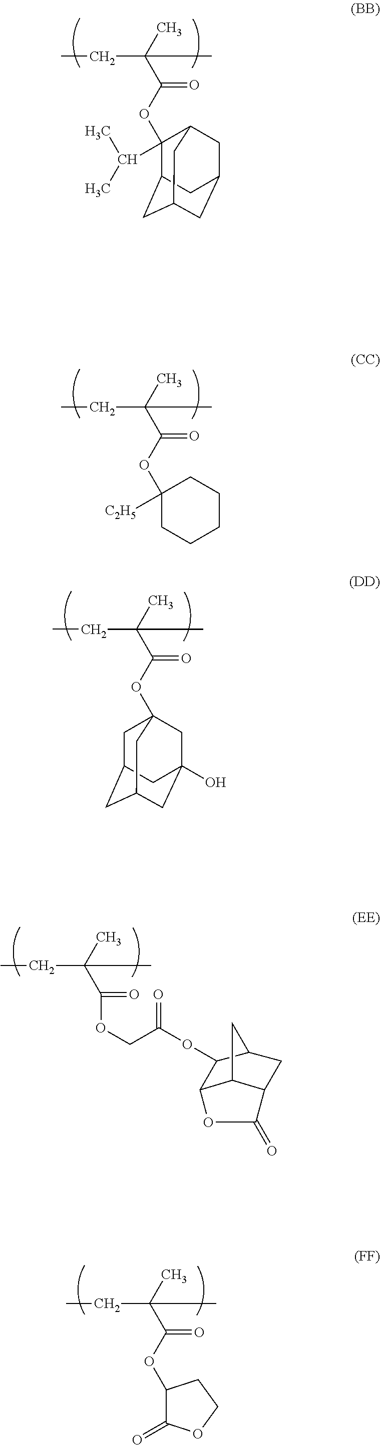

### Resin Synthesis Example 3

Into a four-necked flask equipped with a condenser and a thermometer, 24.36 parts of methyl isobutyl ketone was added, and then a nitrogen gas was blown into it for 30 minutes to substitute a gas in the flask to a nitrogen gas. After heating it up to 72° C. under nitrogen, a solution obtained by mixing 16.2 parts of Monomer (A), 11.56 parts of Monomer (D), 8.32 parts of Monomer (F), 0.27 part of 2,2′-azobisisobutyronitrile, 1.22 part of 2,2′-azobis (2,4-dimethylvaleronitrile) and 29.77 parts of methyl isobutyl ketone was added dropwise thereto over 2 hours at 72° C. The resultant mixture was heated at 72° C. for 5 hours. The reaction mixture was cooled and diluted with 39.69 parts of methyl isobutyl ketone. The resultant mixture was pored into 469 parts of methanol with stirring to cause precipitation. The precipitate was isolated and washed three times with 235 parts of methanol. The obtained precipitate was dried under reduced pressure to obtain 22.7 parts of a resin having a Mw of 1.0×10⁴ and degree of dispersion (Mw/Mn) of 1.40. The yield thereof was 63%. This resin had the following structural units represented by the formulae (AA), (DD) and (FF). This is called as resin A3.

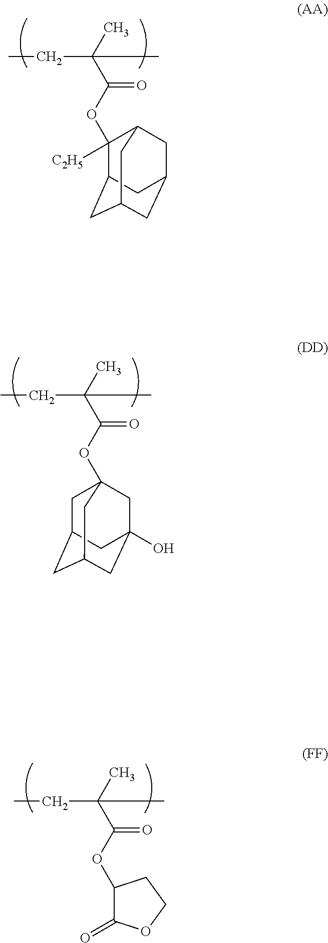

### Resin Synthesis Example 4

Into a four-necked flask equipped with a condenser and a thermometer, 24.11 parts of 1,4-dioxane was added, and then a nitrogen gas was blown into it for 30 minutes to substitute a gas in the flask to a nitrogen gas. After heating it up to 69° C. under nitrogen, a solution obtained by mixing 9.65 parts of Monomer (A), 3.05 parts of Monomer (C), 8.72 parts of Monomer (D), 4.55 parts of Monomer (G), 14.22 parts of Monomer (F), 0.26 part of 2,2′-azobisisobutyronitrile, 1.16 part of 2,2′-azobis(2,4-dimethylvaleronitrile) and 36.17 parts of 1,4-dioxane was added dropwise thereto over 1 hour at 69° C. The resultant mixture was heated at 69° C. for 5 hours. The reaction mixture was cooled and diluted with 44.21 parts of 1,4-dioxane. The resultant mixture was pored into 522 parts of methanol with stirring to cause precipitation. The precipitate was isolated and then, washed three times with 261 parts of methanol. The obtained precipitate was dried under reduced pressure to obtain 26.1 parts of a resin having a Mw of 1.5×10⁴ and degree of dispersion (Mw/Mn) of 1.53. The yield thereof was 65%. This resin had the following structural units represented by the formulae (AA), (CC), (DD), (GG) and (FF). This is called as resin A4.

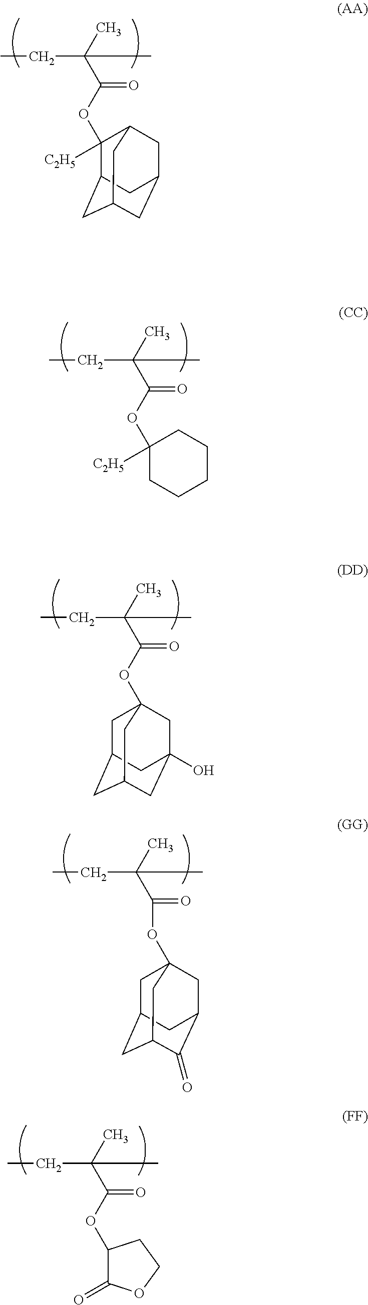

### Photoacid Generator Synthesis Example 1

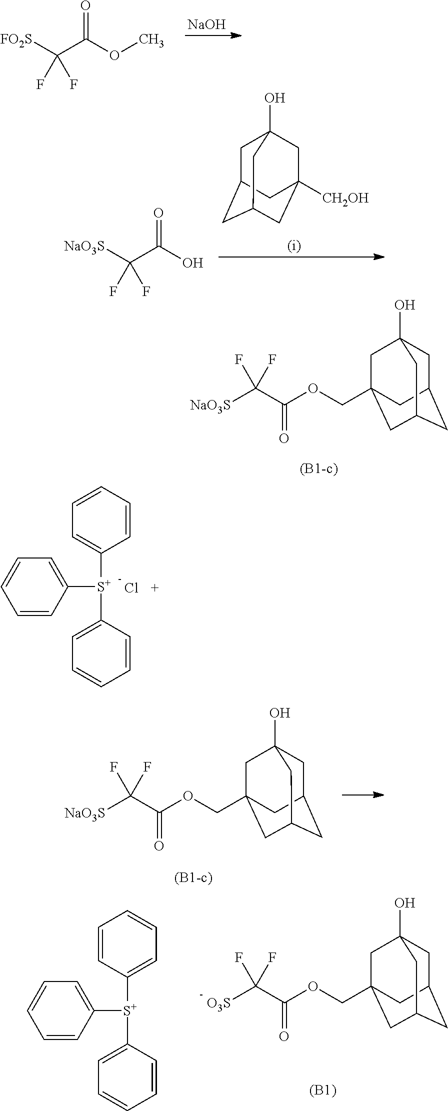

(1) Into a mixture of 100 parts of methyl difluoro(fluorosulfonyl)acetate and 150 parts of ion-exchanged water, 230 parts of 30% aqueous sodium hydroxide solution was added dropwise in an ice bath. The resultant mixture was heated and refluxed at 100° C. for 3 hours. After cooling down to room temperature, the cooled mixture was neutralized with 88 parts of concentrated hydrochloric acid and the solution obtained was concentrated to obtain 164.4 parts of sodium salt of difluorosulfoacetic acid (containing inorganic salt, purity: 62.7%).
(2) To a mixture of 1.9 parts of sodium salt of difluorosulfoacetic acid (purity: 62.7%) and 9.5 parts of N,N-dimethylformamide, 1.0 part of 1,1-carbonyldiimidazole was added and the resultant solution was stirred for 2 hours. The solution was added to the solution prepared by mixing 1.1 parts of the compound represented by the above-mentioned formula (I), 5.5 parts of N,N-dimethylformamide and 0.2 part of sodium hydride and stirring for 2 hours. The resultant solution was stirred for 15 hours to obtain the solution containing the salt represented by the above-mentioned formula (B1-c).
(3) To the solution containing the salt represented by the above-mentioned formula (B1-c), 17.2 parts of chloroform and 2.9 parts of 14.8% aqueous triphenylsulfonium chloride solution were added. The resultant mixture was stirred for 15 hours, and then separated to an organic layer and an aqueous layer. The aqueous layer was extracted with 6.5 parts of chloroform to obtain a chloroform layer. The chloroform layer and the organic layer were mixed and washed with ion-exchanged water. The organic layer obtained was concentrated. The residue obtained was mixed with 5.0 parts of tert-butyl methyl ether and the mixture obtained was filtrated to obtain 0.2 part of the salt represented by the above-mentioned formula (B1) in the form of a white solid, which is called as photoacid generator B1.

### Photoacid Generator Synthesis Example 2

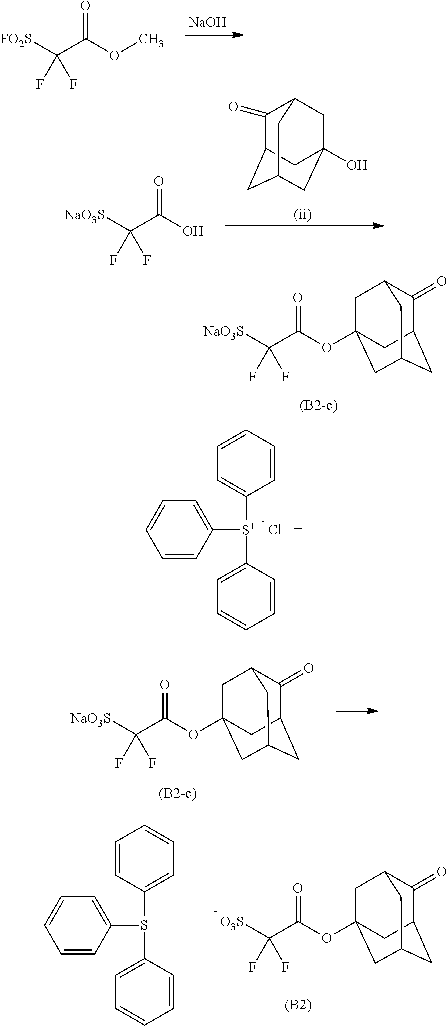

(1) Into a mixture of 100 parts of methyl difluoro(fluorosulfonyl)acetate and 250 parts of ion-exchanged water, 230 parts of 30% aqueous sodium hydroxide solution was added dropwise in an ice bath. The resultant mixture was heated and refluxed at 100° C. for 3 hours. After cooling down to room temperature, the cooled mixture was neutralized with 88 parts of concentrated hydrochloric acid and the solution obtained was concentrated to obtain 164.8 parts of sodium salt of difluorosulfoacetic acid (containing inorganic salt, purity: 62.6%).
(2) To a mixture of 5.0 parts of sodium salt of difluorosulfoacetic acid (purity: 62.8%), 2.6 parts of the compound represented by the above-mentioned formula (II) and 100 parts of ethylbenzene, 0.8 part of concentrated sulfuric acid was added. The resultant mixture was refluxed for 30 hours. The reaction mixture was cooled and filtrated. The solids obtained were washed with tert-butyl methyl ether to obtain 5.5 parts of the salt represented by the above-mentioned formula (B2-c). The purity thereof measured with ¹H-NMR analysis was 35.6%.
(3) To a mixture of 5.4 parts of the salt represented by the above-mentioned formula (B2-c), 16 parts of acetonitrile and 16 parts of ion-exchanged water, a solution of 1.7 parts of triphenylsulfonium chloride, 5 parts of acetonitrile and 5 parts of ion-exchanged water was added. The resultant mixture was stirred for 15 hours, and then concentrated. The residue was extracted with 142 parts of chloroform to obtain a chloroform layer. The chloroform layer was washed with ion-exchanged water followed by concentration. The residue was mixed with 24 parts of tert-butyl methyl ether and the mixture obtained was filtrated to obtain 1.7 parts of the salt represented by the above-mentioned formula (B2) in the form of a white solid, which is called as photoacid generator B2.

### Examples 1 to 12 and Comparative Example 1

### Resin

A1: resin A1
A2: resin A2
A3: resin A3
A4: resin A4

### <Photoacid Generator>

B1: photoacid generator B1
B2: photoacid generator B2

### B3:

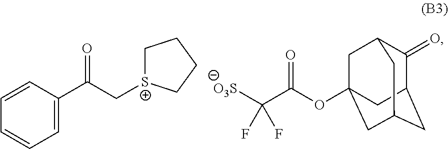

which was prepared according to the method described in JP 2008-165218 A. B4:

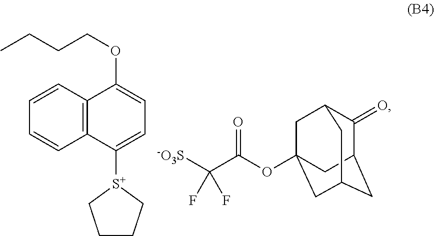

which was prepared according to the method described in JP 2004-59882 A. B5:

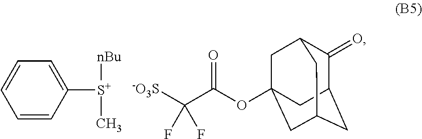

which was prepared according to the method described in JP 2008-209917 A. B6:

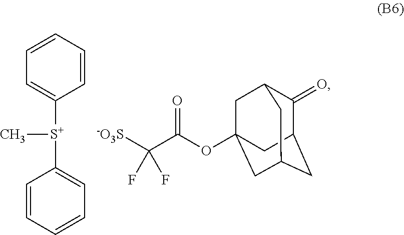

which was prepared according to the method described in JP 2008-209917 A.

### <Basic Compound>

C1: tetrabutylammonium hydroxide
C2: 2,6-diisopropylaniline
C3: tri(methoxyethoxyethyl)amine
C4: 2,6-lutidine

### <Cross-Linking Agent>

D1: compound represented by the following formula:

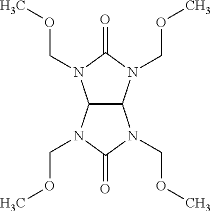

D2: CGPS 352 (trade name) available from Ciba Japan

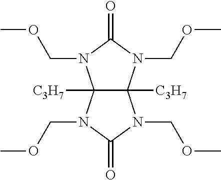

### <Thermal Acid Generator>

### F1:

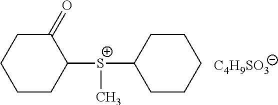

### <Solvent>

| | | |
|---|---|---|
| E1: | propylene glycol monomethyl ether | 20 parts |
| | 2-heptanone | 35 parts |
| | propylene glycol monomethyl ether acetate | 300 parts |
| | γ-butyrolactone | 3 parts |

The following components were mixed and dissolved, further, filtrated through a fluorine resin filter having pore diameter of 0.2 μm, to prepare photoresist compositions and a coating composition.

Resin (kind and amount are described in Table 1)

Photoacid generator (kind and amount are described in Table 1)

Cross-linking agent (kind and amount are described in Table 1)

Basic compound (kind and amount are described in Table 2)

Solvent (kind is described in Table 2)

Thermal acid generator (kind and amount are described in Table 2)

TABLE 1

| | | | Cross-linking |
|---|---|---|---|
| | Resin | | agent |
| | (kind/amount | Photoacid generator | (kind/amount |
| | (part)) | (kind/amount (part)) | (part)) |
| Composition 1 | A2/10 | B1/1.2 | — |
| | | B3/0.3 | |
| Composition 2 | A1/10 | B1/0.9 | — |
| | | B4/0.69 | |
| Composition 3 | A1/10 | B1/0.9 | — |
| | | B5/0.57 | |
| Composition 4 | A1/10 | B1/0.9 | — |
| | | B6/0.59 | |
| Composition 5 | A1/10 | B1/0.9 | — |
| | | B3/0.6 | |
| Composition H1 | A1/10 | B1/1.2 | — |
| Composition S1 | A3/10 | B2/0.6 | D1/0.2 |
| Composition S2 | A4/10 | B1/0.85 | D2/0.235 |

TABLE 2

| | Basic compound | | Thermal acid generator |
|---|---|---|---|
| | (kind/amount (part)) | Solvent | (kind/amount (part)) |
| Composition 1 | C2/0.1 | E1 | — |
| Composition 2 | C2/0.11 | E1 | — |
| Composition 3 | C2/0.11 | E1 | — |
| Composition 4 | C2/0.11 | E1 | — |
| Composition 5 | C2/0.11 | E1 | — |
| Composition H1 | C2/0.125 | E1 | — |
| Composition S1 | C1/0.01 | E1 | F1/0.6 |
| | C4/0.105 | | |
| Composition S2 | C3/0.11 | E1 | — |

Silicon wafers were each coated with “ARC-29A-8”, which is an organic anti-reflective coating composition available from Brewer Co., and then baked at 205° C. for 60 seconds on a hotplate, to form a 78 nm-thick organic anti-reflective coating. Each of the first photoresist compositions shown in Table 3 was spin-coated over the anti-reflective coating so that the thickness of the resulting film became 750 A after drying.

Each of the silicon wafers thus coated with the first photoresist composition was baked on a hotplate at a temperature shown in a column of “PB” in Table 3 for 60 seconds.

Using an ArF excimer stepper (“XT: 1900Gi” manufactured by ASML, NA=1.35, 35° Dipole, Y-polarization, σ OUTER=0.96, σ INNER=0.82), each of wafers thus formed with the respective photoresist film was subjected to line and space pattern exposure using a mask having line and space pattern (1:1) of which line width was 40 nm with the exposure amount shown in column of “Exposure Amount” in Table 3.

After the exposure, each wafer was subjected to a baking on a hotplate at a temperature shown in a column of “PEB” in Table 3 for 60 seconds.

After baking, each wafer was subjected to a paddle development for 60 seconds with an aqueous solution of 2.38 wt % tetramethylammonium hydroxide to obtain the first photoresist pattern.

After the development, the obtained first photoresist pattern on the organic anti-reflective coating substrate was subjected to a baking on a hotplate under the condition shown in a column of “Baking Condition” in Table 3. The obtained pattern was observed with a scanning electron microscope, and good line and space pattern was formed.

TABLE 3

| | | | | Exposure | |
|---|---|---|---|---|---|
| | First | PB | PEB | Amount | Baking |
| No. | Composition | (° C.) | (° C.) | (mJ/cm²) | Condition |
| Ex. 1 | Composition | 120 | 120 | 16.3 | 180° C. |
| | S2 | | | | 120 sec. |
| Ex. 2 | Composition | 120 | 120 | 16.3 | 180° C. |
| | S2 | | | | 120 sec. |
| Ex. 3 | Composition | 120 | 120 | 16.4 | 180° C. |
| | S2 | | | | 120 sec. |
| Ex. 4 | Composition | 120 | 120 | 15.7 | 180° C. |
| | S2 | | | | 120 sec. |
| Ex. 5 | Composition | 120 | 120 | 15.9 | 180° C. |
| | S2 | | | | 120 sec. |
| Ex. 6 | Composition | 120 | 120 | 15.6 | 180° C. |
| | S2 | | | | 120 sec. |
| Ex. 7 | Composition | 120 | 120 | 16.9 | 180° C. |
| | S2 | | | | 120 sec. |
| Ex. 8 | Composition | 120 | 115 | 31.0 | 180° C. |
| | S1 | | | | 120 sec. |
| Ex. 9 | Composition | 120 | 120 | 15.7 | 180° C. |
| | S2 | | | | 120 sec. |
| Ex. 10 | Composition | 120 | 120 | 15.9 | 180° C. |
| | S2 | | | | 120 sec. |
| Ex. 11 | Composition | 120 | 120 | 15.6 | 180° C. |
| | S2 | | | | 120 sec. |
| Ex. 12 | Composition | 120 | 120 | 15.9 | 180° C. |
| | S2 | | | | 120 sec. |
| Comp. | Composition | 120 | 115 | 30.0 | 180° C. |
| Ex. 1 | S1 | | | | 120 sec. |

On each of the first photoresist patterns on the silicon wafers obtained, each of the second photoresist compositions shown in Table 4 was spin-coated so that the thickness of the resulting film became 500 A after drying.

Each of the silicon wafers thus coated with the second photoresist composition was baked on a hotplate at a temperature shown in a column of “PB” in Table 4 for 60 seconds.

Using an ArF excimer stepper (“XT: 1900Gi” manufactured by ASML, NA=1.35, 35° Dipole, Y-polarization, σ OUTER=0.96, σ INNER=0.82), each of wafers thus formed with the respective photoresist film was subjected to line and space pattern exposure using a mask having line and space pattern (1:1) of which line width was 40 nm with the exposure amount shown in column of “Exposure Amount” in Table 4. This exposure was conducted after rotating the wafer 90 degrees, and therefore, the second photoresist pattern (line and space pattern) was formed in a direction perpendicular to the first phtooresist pattern (line and space pattern).

After the exposure, each wafer was subjected to a baking on a hotplate at a temperature shown in a column of “PEB” in Table 4 for 60 seconds.

After baking, each wafer was subjected to a paddle development for 60 seconds with an aqueous solution of 2.38 wt % tetramethylammonium hydroxide to obtain a lattice-shaped pattern formed from the first photoresist pattern and the second photoresist pattern.

TABLE 4

| | Second | PB | PEB | Exposure Amount |
|---|---|---|---|---|
| No. | Composition | (° C.) | (° C.) | (mJ/cm²) |
| Ex. 1 | Composition 1 | 100 | 85 | 28 |
| Ex. 2 | Composition 1 | 120 | 85 | 26 |
| Ex. 3 | Composition 1 | 140 | 85 | 19 |
| Ex. 4 | Composition 2 | 145 | 100 | 13 |
| Ex. 5 | Composition 3 | 145 | 100 | 15 |
| Ex. 6 | Composition 4 | 145 | 100 | 13 |
| Ex. 7 | Composition 5 | 145 | 100 | 21 |
| Ex. 8 | Composition 5 | 150 | 95 | 21 |
| Ex. 9 | Composition 2 | 100 | 100 | 33 |
| Ex. 10 | Composition 3 | 100 | 100 | 33 |
| Ex. 11 | Composition 4 | 100 | 100 | 25 |
| Ex. 12 | Composition 5 | 100 | 100 | 41 |
| Comp. | Composition H1 | 100 | 100 | 31 |
| Ex. 1 | | | | |

The obtained patterns were observed with the scanning electron microscope.

From the observation with the scanning electron microscope, the second line patterns were formed on the first line patterns in good shapes. The shapes of the first photoresist patterns were maintained and they were also good, and as the result, good lattice-shaped pattern was formed.

In Examples 1 to 7, no expansion of the lines of the first photoresist patterns after second lithography step using the second photoresist composition was observed. In Comparative Example 1, the development of the second photoresist patterns was not satisfied, and the remarkable decrease of the film thickness was observed, and therefore, the good photoresist pattern was not obtained.

According to the present invention, a good photoresist pattern is provided.

What is claimed is:

1. A process for producing a photoresist pattern comprising the following steps (A) to (D):
(A) a step of applying a first photoresist composition comprising a resin comprising a structural unit having an acid-labile group in its side chain, an acid generator and a cross-linking agent on a substrate to form a first photoresist film, exposing the first photoresist film to radiation followed by developing the first photoresist film exposed with an alkaline developer, thereby forming a first photoresist pattern,
(B) a step of making the first photoresist pattern inactive to radiation in the following step (C), making the first photoresist pattern insoluble in an alkaline developer or making the first photoresist pattern insoluble in a second photoresist composition used in the following step (C),
(C) a step of applying a second photoresist composition comprising a resin comprising a structural unit having an acid-labile group in its side chain and
at least one acid generator selected from the group consisting of a photoacid generator represented by the formula (I): 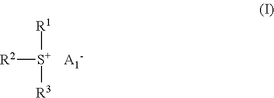
wherein R¹ and R² independently a C1-C12 alkyl group or a C6-C18 aromatic hydrocarbon group which can have one or more substituents, R³ represents a C1-C12 alkyl group, or R² and R³ are bonded each other to form a C3-C12 divalent acyclic hydrocarbon group which forms a ring together with S and one or more —CH₂— in the C3-C12 divalent acyclic hydrocarbon group can be replaced by —O—, and A₁⁻ represents an organic anion, and a photoacid generator represented by the formula (II): 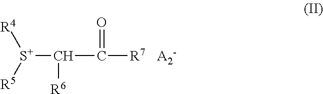
wherein R⁴ and R⁵ independently a C1-C12 alkyl group, a C3-C18 saturated cyclic hydrocarbon group or a C6-C18 aromatic hydrocarbon group, or R⁴ and R⁵ are bonded each other to form a C3-C12 divalent acyclic hydrocarbon group which forms a ring together with S and one or more —CH₂— in the C3-C12 divalent acyclic hydrocarbon group can be replaced by —O—, R⁶ represents a hydrogen atom, R⁷ represents a C1-C12 alkyl group, a C3-C18 saturated cyclic hydrocarbon group or a C6-C18 aromatic hydrocarbon group which can have one or more substituents, or R⁶ and R⁷ are bonded each other to form a C1-C10 divalent acyclic hydrocarbon group which forms a 2-oxocycloalkyl group together with —CHCO— to which R⁶ and R⁷ are bonded, and A₂⁻ represents an organic anion,
on the first photoresist pattern obtained in the step (B) to form the second photoresist film, exposing the second photoresist film to radiation, and
(D) a step of developing the second photoresist film exposed with an alkaline developer, thereby forming a second photoresist pattern.

2. The process according to claim 1, wherein the step (A) comprises the following steps (1a) to (5a):
(1a) a step of applying a first photoresist composition comprising a resin comprising a structural unit having an acid-labile group in its side chain and being itself insoluble or poorly soluble in an alkali aqueous solution but becoming soluble in an alkali aqueous solution by the action of an acid, an acid generator and a cross-linking agent on a substrate followed by conducting drying, thereby forming a first photoresist film,
(2a) a step of baking the first photoresist film formed,
(3a) a step of exposing the first photoresist film baked to radiation,
(4a) a step of baking the first photoresist film exposed, and
(5a) a step of developing the first photoresist film baked in the step (4a) with an alkaline developer, thereby forming a first photoresist pattern.

3. The process according to claim 1, wherein the step (B) comprises the following step (6a):
(6a) a step of baking the first photoresist pattern.

4. The process according to claim 1, wherein the step (C) comprises the following steps (7a) to (10a):
(7a) a step of applying a second photoresist composition comprising a resin comprising a structural unit having an acid-labile group in its side chain and being itself insoluble or poorly soluble in an alkali aqueous solution but becoming soluble in an alkali aqueous solution by the action of an acid, and at least one acid generator selected from the group consisting of a photoacid generator represented by the formula (I) and a photoacid generator represented by the formula (II) on the first photoresist pattern obtained in the step (B) followed by conducting drying, thereby forming a second photoresist film,
(8a) a step of baking the second photoresist film formed,
(9a) a step of exposing the second photoresist film baked radiation, and
(10a) a step of baking the second photoresist film exposed.

5. The process according to claim 1, wherein A₁⁻ and A₂⁻ independently represent an anion represented by the formula (III): 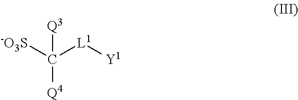
wherein Q³ and Q⁴ independently represent a fluorine atom or a C1-C6 perfluoroalkyl group, L¹ represents a single bond or a C1-C17 divalent saturated hydrocarbon group in which one or more —CH₂— can be replaced by —O— or —CO—, Y¹ represents a C1-C18 aliphatic hydrocarbon group which can have one or more substituents, a C3-C18 saturated cyclic hydrocarbon group which can have one or more substituents, and one or more —CH₂— in the aliphatic hydrocarbon group and the saturated cyclic hydrocarbon group can be replaced by —O—, —SO₂— or —CO—.
